(19) United States
(12) Patent Application Publication
(10) Pub. No.: US 2024/0260475 A1
(43) Pub. Date: Aug. 1, 2024

(54) VIBRATION APPARATUS AND APPARATUS INCLUDING THE SAME

(71) Applicant: LG Display Co., Ltd., Seoul (KR)

(72) Inventors: YuSeon KHO, Gyeonggi-do (KR); Wansoo LEE, Gyeonggi-do (KR); Chiwan KIM, Gyeonggi-do (KR); Sung-Eui SHIN, Gyeonggi-do (KR); Minji KIM, Gyeonggi-do (KR); Sungwook KO, Gyeonggi-do (KR); Saewon KANG, Gyeonggi-do (KR)

(73) Assignee: LG Display Co., Ltd., Seoul (KR)

(21) Appl. No.: 18/523,351

(22) Filed: Nov. 29, 2023

(30) Foreign Application Priority Data
Jan. 27, 2023 (KR) 10-2023-0010690

(51) Int. Cl. H10N 30/20; H10N 30/03; H10N 30/071; H10N 30/098; H10N 30/87

(52) U.S. Cl. CPC H10N 30/20; H10N 30/03; H10N 30/071; H10N 30/098; H10N 30/875

(57) ABSTRACT

Aspects of the present disclosure is directed to a vibration apparatus and an apparatus including the same, having directivity. In one example, a vibration apparatus includes a vibration part; a first electrode at a first surface of the vibration part; and a second electrode at a second surface different from the first surface of the vibration part, wherein the vibration part includes a piezoelectric portion and a supporting portion connected to the piezoelectric portion, and wherein a height of the supporting portion differs from a height of the piezoelectric portion.

### CROSS-REFERENCE TO RELATED APPLICATIONS

This application claims the benefit of and priority to Korean Patent Application No. 10-2023-0010690 filed on Jan. 27, 2023, the entire content of which is hereby incorporated by reference.

### BACKGROUND

### Field of the Disclosure

The present disclosure relates to a vibration apparatus and an apparatus including the same.

### Background

An apparatus can include a separate speaker or a sound generating device providing a sound. When a speaker is disposed in an apparatus, the speaker occupies a space, which can limit the design and spatial disposition of the apparatus are limited.

A speaker applied to an apparatus may be, for example, an actuator including a magnet and a coil. However, when an actuator is applied to the apparatus, a thickness thereof is thickened. Therefore, piezoelectric elements for realizing a thin thickness are attracting much attention.

Because piezoelectric elements have a fragile characteristic, the piezoelectric elements are easily damaged due to an external impact, hence undermining their reliability in reproducing sound. Moreover, piezoelectric elements have a problem of low orientation (or directivity).

### SUMMARY

To address one or more of the problems described above, aspects of the present disclosure are directed to a vibration apparatus with enhanced directivity.

An aspect of the present disclosure is directed to providing a vibration apparatus and an apparatus including the same having a directivity.

Another aspect of the present disclosure is directed to providing a vibration apparatus and an apparatus including the same, which may implement a sound pressure level characteristic and/or a sound characteristic which can be improved by adjusting a modulus of an adhesive member.

Additional features, advantages, and aspects of the present disclosure are set forth in part in the present disclosure and will also be apparent from the present disclosure or may be learned by practice of example embodiments described herein. Other features, advantages, and aspects of the present disclosure may be realized and attained by the structure particularly pointed out in the present disclosure, or derivable therefrom, and claims hereof as well as the appended drawings.

In one aspect, a vibration apparatus includes a vibration part; a first electrode at a first surface of the vibration part; and a second electrode at a second surface different from the first surface of the vibration part. The vibration part includes a piezoelectric portion and a supporting portion connected to the piezoelectric portion. A height of the supporting portion differs from a height of the piezoelectric portion.

In another aspect, the height of the supporting portion is higher than the height of the piezoelectric portion.

In another aspect, a width of the supporting portion differs from a width of the piezoelectric portion.

In another aspect, the width of the supporting portion is smaller than the width of the piezoelectric portion.

In another aspect, a shape of the supporting portion differs from a shape of the piezoelectric portion.

In another aspect, the shape of the supporting portion is one of a trapezoid shape, a convex shape, and a combination of a trapezoid shape and a convex shape.

In another aspect, the supporting portion is higher than one or more of a first surface of the piezoelectric portion and a second surface different from the first surface of the piezoelectric portion.

In another aspect, a shape of the supporting portion includes a trapezoid shape.

In another aspect, the first electrode is at a first surface of each of the piezoelectric portion and the supporting portion and is configured as one electrode.

In another aspect, the first electrode is at a first surface of each of the piezoelectric portion and the supporting portion and is configured with an individual electrode.

In another aspect, the second electrode is at a second surface different from the first surface of each of the piezoelectric portion and the supporting portion and is configured as one electrode.

In another aspect, a signal having a frequency different from a frequency of the first electrode is applied to the second electrode, or a signal having a phase that is different from a phase of the first electrode is applied to the second electrode.

In another aspect, the vibration apparatus further includes a first protection member at the first electrode; and a second protection member at the second electrode.

In another aspect, the vibration apparatus further includes a first adhesive member between the first electrode and the first protection member; and a second adhesive member between the second electrode and the second protection member.

In another aspect, the supporting portion includes a plurality of first supporting portions in parallel with the piezoelectric portion therebetween; and a plurality of second supporting portions in parallel with the piezoelectric portion therebetween.

In another aspect, a respective shape of each of the plurality of first supporting portions differs from a respective shape of each of the plurality of second supporting portions.

In another aspect, each of the plurality of first supporting portions includes a slope surface protruding from the piezoelectric portion, and each of the plurality of second supporting portions includes a curved surface protruding from the piezoelectric portion.

In another aspect, the vibration part includes a first region, a second region, and a third region between the first region and the second region, the plurality of first supporting portions are at one or two of the first region, the second region, and the third regions, and the plurality of second supporting portions are at one or two of the first region, the second region, and the third regions.

In another aspect, the supporting portion includes a flexible organic material.

In one aspect, an apparatus includes a passive vibration member; and one or more vibration generating components configured to vibrate the passive vibration member. The one or more vibration generating components include a vibration apparatus. The vibration apparatus includes a vibration part; a first electrode at a first surface of the vibration part; and a second electrode at a second surface different from the first surface of the vibration part, wherein the vibration part includes a piezoelectric portion and a supporting portion connected to the piezoelectric portion, and wherein a height of the supporting portion differs from a height of the piezoelectric portion.

In another aspect, the passive vibration member comprises one or more of metal, wood, rubber, plastic, glass, fiber, cloth, paper, a mirror, carbon, and leather.

In another aspect, the passive vibration member comprises one or more of a display panel including a pixel configured to display an image, a light emitting diode lighting panel, an organic light emitting lighting panel, an inorganic light emitting lighting panel, a screen panel on which an image is to be projected from a display apparatus, a lighting panel, a signage panel, a vehicular interior material, a vehicular glass window, a vehicular exterior material, a vehicular seat interior material, a building ceiling material, a building interior material, a building glass window, an aircraft interior material, an aircraft glass window, and a mirror.

In another aspect, the apparatus further includes a connection member between the passive vibration member and the vibration apparatus. A modulus of the connection member is between 1×10⁵ Pa and 5×10⁵ Pa.

In one aspect, an apparatus includes an exterior material; an interior material covering the exterior material; and one or more vibration generating components on at least one or more of the exterior material, the interior material, and a region between the exterior material and the interior material. The one or more vibration generating components include a vibration apparatus. The one or more of the interior material and the exterior material output sound based on a vibration of the one or more vibration generating components. The vibration apparatus includes a vibration part; a first electrode at a first surface of the vibration part; and a second electrode at a second surface different from the first surface of the vibration part, wherein the vibration part includes a piezoelectric portion and a supporting portion connected to the piezoelectric portion, and wherein a height of the supporting portion differs from a height of the piezoelectric portion.

In another aspect, the interior material comprises one or more of metal, wood, rubber, plastic, glass, fiber, cloth, paper, carbon, a mirror, and leather.

In another aspect, the interior material comprises at least one or more of a dashboard, a pillar interior material, a roof interior material, a door interior material, a seat interior material, a handle interior material, a floor interior material, a rear view mirror, an overhead console, a glove box, a sun visor, and a rear package interior material. The one or more vibration generating components are configured to vibrate at least one or more of the dashboard, the pillar interior material, the roof interior material, the door interior material, the seat interior material, the handle interior material, the floor interior material, the rear view mirror, the overhead console, the glove box, the sun visor, and the rear package interior material.

In another aspect, the apparatus further includes a glass window and a transparent vibration apparatus disposed at the glass window.

In another aspect, the glass window comprises at least one or more of a front glass window, a side glass window, a rear glass window, and a roof glass window; and the transparent vibration apparatus is configured to vibrate at least one or more of the front glass window, the side glass window, the rear glass window, and the roof glass window.

In another aspect, the apparatus further includes a connection member between the passive vibration member and the vibration apparatus. A modulus of the connection member is between 1×10⁵ Pa and 5×10⁵ Pa.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing description and the following description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this disclosure, illustrate aspects and embodiments of the disclosure and together with the description serve to explain principles of the disclosure.

FIG. 1 illustrates an apparatus according to an aspect of the present disclosure.

FIG. 2A is a plan view illustrating a vibration part according to an aspect of the present disclosure.

FIG. 2B is a cross-sectional view taken along line A-A′ illustrated in FIG. 2A according to an aspect of the present disclosure.

FIG. 2C is a lateral view illustrating a vibration part according to an aspect of the present disclosure.

FIG. 2D is a lateral view illustrating a vibration part according to an aspect of the present disclosure.

FIG. 3 illustrates a vibration part according to an aspect of the present disclosure.

FIG. 4A is a plan view illustrating a vibration part according to another aspect of the present disclosure.

FIG. 4B is a cross-sectional view taken along line B-B′ illustrated in FIG. 4A according to another aspect of the present disclosure.

FIG. 4C is a lateral view illustrating a vibration part according to another aspect of the present disclosure.

FIG. 4D is a lateral view illustrating a vibration part according to another aspect of the present disclosure.

FIG. 5 illustrates a vibration part according to another aspect of the present disclosure.

FIG. 6A is a plan view illustrating a vibration part according to another aspect of the present disclosure.

FIG. 6B is a cross-sectional view taken along line C-C′ illustrated in FIG. 6A according to another aspect of the present disclosure.

FIG. 6C is a lateral view illustrating a vibration part according to another aspect of the present disclosure.

FIG. 6D is a lateral view illustrating a vibration part according to another aspect of the present disclosure.

FIG. 7 illustrates a vibration part according to another aspect of the present disclosure.

FIG. 8A is a plan view illustrating a vibration part according to another aspect of the present disclosure.

FIG. 8B is a cross-sectional view taken along line D-D′ illustrated in FIG. 8A according to another aspect of the present disclosure.

FIG. 8C is a lateral view illustrating a vibration part according to another aspect of the present disclosure.

FIG. 8D is a lateral view illustrating a vibration part according to another aspect of the present disclosure.

FIG. 9A is a plan view illustrating a vibration part according to another aspect of the present disclosure.

FIG. 9B is another cross-sectional view taken along line A-A′ illustrated in FIG. 2A according to another aspect of the present disclosure.

FIG. 9C is a lateral view illustrating a vibration part according to another aspect of the present disclosure.

FIG. 10 illustrates a vibration part according to another aspect of the present disclosure.

FIG. 11A is a cross-sectional view taken along line A-A′ illustrated in FIG. 2A according to an aspect of the present disclosure.

FIG. 11B is another cross-sectional view taken along line A-A′ illustrated in FIG. 2A according to another aspect of the present disclosure.

FIG. 12A illustrates a vibration apparatus according to an experimental example.

FIG. 12B illustrates a vibration apparatus according to an aspect of the present disclosure.

FIG. 13 illustrates an apparatus according to an aspect of the present disclosure.

FIG. 14 is a cross-sectional view taken along line E-E′ illustrated in FIG. 13 according to an aspect of the present disclosure.

FIG. 15 illustrates an apparatus according to another aspect of the present disclosure.

FIG. 16 is a cross-sectional view taken along line F-F′ illustrated in FIG. 15 according to another aspect of the present disclosure.

FIG. 17 is a cross-sectional view taken along line F-F′ illustrated in FIG. 15 according to another aspect of the present disclosure.

FIG. 18 illustrates a vehicular apparatus according to an aspect of the present disclosure.

FIG. 19 illustrates a sound output characteristic of an apparatus according to an aspect of the present disclosure.

Throughout the drawings and the detailed description, unless otherwise described, the same drawing reference numerals should be understood to refer to the same elements, features, or structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, where a detailed description of well-known functions, structures or configurations may unnecessarily obscure aspects of the present disclosure, a detailed description thereof may have been omitted for brevity. Further, repetitive descriptions can be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the example embodiments set forth herein. Rather, these example embodiments are examples and are provided so that this disclosure may be thorough and complete to assist those skilled in the art to understand concepts presented herein without limiting the protected scope of the present disclosure.

Shapes (e.g., sizes, lengths, widths, heights, thicknesses, locations, radii, diameters, and areas), dimensions, ratios, angles, numbers, or the like disclosed herein, including those illustrated in the drawings are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

When a term like “comprise,” “have,” “include,” “contain,” “constitute,” “made of,” “formed of,” or the like is used with respect to one or more elements, one or more other elements may be added unless a term such as “only” or the like is used. The terms used in the present disclosure are merely used to describe example embodiments, and are not intended to limit the scope of the present disclosure. The terms of a singular form may include plural forms unless the context clearly indicates otherwise.

The word “exemplary” is used to mean serving as an example or illustration, unless otherwise specified. Embodiments are example embodiments. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e. g., a level, range, dimension, size, or the like) is construed to include an error or tolerance range even where no explicit description of such an error or tolerance range is provided. An error or tolerance range may be caused by various factors (e. g., process factors, internal or external impact, noise, or the like). In interpreting a numerical value, the value is interpreted as including an error range unless explicitly stated otherwise.

In describing a positional relationship where the positional relationship between two parts (e.g., layers, films, regions, components, sections, or the like) is described, for example, using “on,” “upon,” “on top of,” “over,” “under,” “above,” “below,” “beneath,” “near,” “close to,” “adjacent to,” “beside,” “next to,” “at or on a side of,” or the like, one or more other parts may be located between the two parts unless a more limiting term, such as “immediate(ly),” “direct(ly),” or “close(ly),” is used. For example, where a structure is described as being positioned “on,” “upon,” “on top of,” “over,” “under,” “above,” “below,” “beneath,” “near,” “close to,” “adjacent to,” “beside,” “next to,” “at or on a side of,” or the like another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” or the like refer to an arbitrary frame of reference.

Spatially relative terms, such as “below,” “beneath,” “lower,” “on,” “above,” “upper” and the like, can be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, can include all directions of “above” and “below.” Likewise, an exemplary term “above” or “on” can include both directions of “above” and “below.”

In describing a temporal relationship, where the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

The terms, such as “below,” “lower,” “above,” “upper” and the like, may be used herein to describe a relationship between element(s) as illustrated in the drawings. It will be understood that the terms are spatially relative and based on the orientation depicted in the drawings.

It is understood that, although the terms “first,” “second,” or the like may be used herein to describe various elements (e.g., layers, films, regions, components, sections, or the like), these elements should not be limited by these terms, for example, to any particular order, precedence, or number of elements. These terms are used only to distinguish one element from another. For example, a first element could be termed a second element, and, similarly, a second element could be termed a first element, without departing from the scope of the present disclosure. Furthermore, the first element, the second element, or the like may be arbitrarily named according to the convenience of those skilled in the art without departing from the scope of the present disclosure. For clarity, the functions or structures of these elements (e.g., the first element, the second element and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, region, component, section, or the like) is described as “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, or the like) “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

The phase that an element (e.g., layer, film, region, component, section, or the like) is “provided in,” “disposed in,” or the like in another element may be understood as that at least a portion of the element is provided in, disposed in, or the like in another element, or that the entirety of the element is provided in, disposed in, or the like in another element. The phase that an element (e.g., layer, film, region, component, section, or the like) “contacts,” “overlaps,” or the like with another element may be understood as that at least a portion of the element contacts, overlaps, or the like with a least a portion of another element, that the entirety of the element contacts, overlaps, or the like with a least a portion of another element, or that at least a portion of the element contacts, overlaps, or the like with the entirety of another element.

The terms such as a “line” or “direction” should not be interpreted only based on a geometrical relationship in which the respective lines or directions are parallel or perpendicular to each other. Such terms may mean a wider range of lines or directions within which the components of the present disclosure may operate functionally. For example, the terms “first direction,” “second direction,” and the like, such as a direction parallel or perpendicular to “x-axis,” “y-axis,” or “z-axis,” should not be interpreted only based on a geometrical relationship in which the respective directions are parallel or perpendicular to each other, and may be meant as directions having wider directivities within the range within which the components of the present disclosure may operate functionally.

The term “at least one” should be understood as including any and all combinations of one or more of the associated listed items. For example, each of the phrases of “at least one of a first item, a second item, or a third item” and “at least one of a first item, a second item, and a third item” may represent (i) a combination of items provided by two or more of the first item, the second item, and the third item or (ii) only one of the first item, the second item, or the third item.

The expression of a first element, a second elements, “and/of” a third element should be understood to encompass one of the first, second, and third elements, as well as any and all combinations of the first, second and third elements. By way of example, A, B and/or C encompass only A; only B; only C; any of A, B, and C (e.g., A, B, or C); or some combination of A, B, and C (e.g., A and B; A and C; or B and C); and all of A, B, and C. Furthermore, an expression “A/B” may be understood as A and/or B. For example, an expression “A/B” can refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, sections, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as different from one another. In another example, an expression “different from one another” may be understood as different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirety coupled to or combined with each other, and may be operated, linked, or driven together in various ways. Embodiments of the present disclosure may be implemented or carried out independently from each other, may be technically associated with each other, or may be implemented or carried out together in a co-dependent or related relationship. In one or more aspects, the components of each apparatus according to various embodiments of the present disclosure may be operatively coupled and configured.

Unless otherwise defined, the terms (including technical and scientific terms) used herein have the same meaning as commonly understood by one of ordinary skill in the art to which example embodiments belong. It should be further understood that terms, such as those defined in commonly used dictionaries, should be interpreted as having a meaning that is, for example, consistent with their meaning in the context of the relevant art and should not be interpreted in an idealized or overly formal sense, unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness. Thus, embodiments of the present disclosure are not limited to a scale, dimension, size, or thickness illustrated in the drawings.

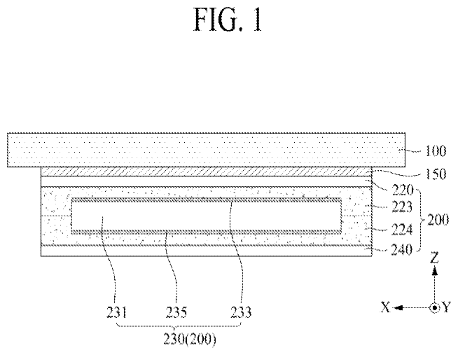

FIG. 1 illustrates an apparatus according to an aspect of the present disclosure.

With reference to FIG. 1, an apparatus according to an aspect of the present disclosure may include a vibration member 100 and a vibration apparatus 200.

The vibration member 100 may output a sound based on a vibration of the vibration apparatus 200. Accordingly, the vibration member 100 may be a vibration object, a vibration plate, a vibration panel, a sound plate, a sound output member, or sound output panel, and or the like, but embodiments of the present disclosure are not limited thereto.

The vibration member 100 may be configured to be transparent, semitransparent, or opaque. The vibration member 100 according to an aspect of the present disclosure may include a metal material or a nonmetal material (or a composite nonmetal material) having a material characteristic suitable for outputting a sound based on a vibration. The metal material of the vibration member 100 according to an aspect of the present disclosure may include any one or more materials of stainless steel, aluminum (Al), an Al alloy, a magnesium (Mg), a Mg alloy, and a magnesium-lithium (Mg—Li) alloy, but embodiments of the present disclosure are not limited thereto. The nonmetal material (or the composite nonmetal material) of the vibration member 100 may include one or more material of glass, plastic, carbon, fiber, leather, wood, cloth, rubber, and paper, or a combination thereof, but embodiments of the present disclosure are not limited thereto. For example, the paper may be cone paper for speakers. For example, the cone paper may be pulp or foamed plastic, or the like, but embodiments of the present disclosure are not limited thereto. For example, the vibration member 100 may be configured as styrene material, but embodiments of the present disclosure are not limited thereto. For example, the styrene material may be an ABS material. The ABS material may be acrylonitrile, butadiene, or styrene. For example, the ABS (acrylonitrile-butadiene-styrene) may be a material with impact resistance and rigidity.

The vibration member 100 according to an aspect of the present disclosure may implement or realize a signage panel such as an analog signage or a digital signage, or the like such as an advertising signboard, a poster, or a noticeboard, or the like. For example, when the vibration member 100 implements the signage panel, the analog signage may include signage content such as a sentence, a picture, and a sign, or the like. The signage content may be disposed at the vibration member 100 to be visible. For example, the signage content may be attached on one or more of a first surface (or a front surface) and a second surface (or a rear surface) different from (or opposite to) the first surface of the vibration member 100. For example, the signage content may be directly attached on one or more of a first surface (or a front surface) and a second surface (or a rear surface) different from (or opposite to) the first surface of the vibration member 100. For example, the signage content may be printed on a medium such as paper or the like, and the medium with the signage content printed thereon may be attached on one or more of the first surface and the second surface of the vibration member 100. For example, the signage content may be printed on a medium such as paper or the like, and the medium with the signage content printed thereon may be directly attached on one or more of the first surface and the second surface of the vibration member 100. For example, when the signage content is attached on the second surface of the vibration member 100, the vibration member 100 may be configured as a transparent material.

The vibration member 100 according to an aspect of the present disclosure may include a planar structure. For example, the vibration member 100 may include a plate-shaped structure having a tetragonal shape. For example, the vibration member 100 may include a plate-shaped structure having a polygonal shape including a rectangular shape or a square shape. For example, the vibration member 100 may include a plate structure having totally a same thickness, or may include a nonplanar structure, but embodiments of the present disclosure are not limited thereto.

The vibration member 100 may include a widthwise length parallel to a first direction X and a lengthwise length parallel to a second direction Y. For example, with respect to a same plane, the first direction X may be a first horizontal direction or a first horizontal length direction of the vibration member 100, and the second direction Y may be a second horizontal direction or a second horizontal length direction of the vibration member 100 which is orthogonal to the first direction X. For example, the vibration member 100 may have a rectangular shape where the widthwise length is relatively longer than the lengthwise length. However, embodiments of the present disclosure are limited thereto, the vibration member 100 may include a square shape where the widthwise length is a same as the lengthwise length.

The vibration apparatus 200 may be configured to autonomously vibrate (or displace or drive) based on an electrical signal (or a voice signal or a sound signal) applied thereto, or may vibrate (or displace or drive) the vibration member (or the vibration plate or the vibration object). For example, the vibration apparatus 200 may be a vibration structure, a vibrator, a vibration generating device, a vibration generator, a sounder, a sound device, a sound generating device, or a sound generator, and or the like, but embodiments of the present disclosure are not limited thereto.

The vibration apparatus 200 according to an aspect of the present disclosure may include a piezoelectric material or an electroactive material which have a piezoelectric characteristic. The vibration apparatus 200 may vibrate (or displace or drive) the vibration member 100 based on a vibration (or displacement or driving) of the piezoelectric material by an electrical signal (or a voice signal or a sound signal) applied to the piezoelectric material. For example, the vibration apparatus 200 may alternately repeat contraction and/or expansion based on a piezoelectric effect (or a piezoelectric characteristic) to vibrate (or displace or drive). For example, the vibration apparatus 200 may vibrate (or displace or drive) in a vertical direction (or a thickness direction) Z as contraction and/or expansion are alternately repeated by an inverse piezoelectric effect.

The vibration apparatus 200 according to an aspect of the present disclosure may be connected or coupled to the second surface of the vibration member 100 by an adhesive member 150. For example, the adhesive member 150 may be disposed between the vibration member 100 and the vibration apparatus 200. The vibration apparatus 200 may be disposed on one surface of the vibration member 100 and may transmit a vibration to the vibration member 100 through the adhesive member 150.

The adhesive member 150 according to an aspect of the present disclosure may include an adhesive layer (or a tacky layer) with suitable/sufficient attaching/adhesive force. For example, the adhesive member 150 may be an adhesive, a double-sided adhesive, a single-sided adhesive, a double-sided tape, a single-sided tape, a double-sided foam tape, a single-sided foam tape, a single-sided cushion tape, a double-sided cushion tape, a double-sided adhesive foam pad, a single-sided adhesive foam pad, or a tacky sheet, or the like, but embodiments of the present disclosure are limited thereto. For example, when the adhesive member 150 includes the tacky sheet (or the tacky layer), the adhesive member 150 may include only an adhesive layer or a tacky layer without a base member such as a plastic material or the like.

The adhesive layer (or a tacky layer) of the adhesive member 150 according to an aspect of the present disclosure may include epoxy, acrylic, silicone, or urethane, but embodiments of the present disclosure are limited thereto.

The adhesive layer (or a tacky layer) of the adhesive member 150 according to another aspect of the present disclosure may include a pressure sensitive adhesive (PSA), an optically cleared adhesive (OCA), or an optically cleared resin (OCR), but embodiments of the present disclosure are limited thereto.

The vibration apparatus 200 according to an aspect of the present disclosure may include a vibration device 230. The vibration apparatus 200 or the vibration device 230 may include a vibration part 231 (may also be referred to as a vibration component or a vibrator), a first electrode part (or a first electrode) 233, and a second electrode part (or a second electrode) 235.

The vibration part 231 may include a piezoelectric material or an electro active material having a piezoelectric effect. For example, the piezoelectric material may have a characteristic where pressure or twisting is applied to a crystalline structure by an external force, a potential difference occurs due to dielectric polarization caused by a relative position change of a positive (+) ion and a negative (−) ion, and a vibration is generated by an electric field based on a voltage applied thereto. The vibration part 231 may be a vibration layer, a piezoelectric layer, a piezoelectric material layer, an electro active layer, a vibration portion, a piezoelectric material portion, an electro active portion, a piezoelectric structure, a piezoelectric composite layer, a piezoelectric composite, or a piezoelectric ceramic composite, or the like, but embodiments of the present disclosure are not limited thereto. The vibration part 231 may be formed of a transparent, semitransparent, or opaque piezoelectric material, and thus, the vibration part 231 may be transparent, semitransparent, or opaque.

The vibration part 231 may be configured as an inorganic material portion. The inorganic material portion may be a piezoelectric material, a composite piezoelectric material, or an electroactive material which includes a piezoelectric effect.

The vibration part 231 according to an aspect of the present disclosure may be configured as a ceramic-based material capable of implementing a relatively strong vibration, or may be configured as a piezoelectric ceramic having a perovskite-based crystalline structure. The perovskite crystalline structure may have a piezoelectric effect and/or an inverse piezoelectric effect, and may be a plate-shaped structure having orientation. The perovskite crystalline structure may be represented by a chemical formula “ABO₃”, in the chemical formula “ABO₃”, the “A” may include a divalent metal element, and the “B” may include a tetravalent metal element. As an aspect of the present disclosure, in the chemical formula “ABO₃”, the “A” and the “B” may be cations, and the “O” may be anions. For example, the vibration part 231 may include at least one or more of lead (II) titanate (PbTiO₃), lead zirconate (PbZrO₃), lead zirconate titanate (PbZrTiO₃), barium titanate (BaTiO₃), and strontium titanate (SrTiO₃), but embodiments of the present disclosure are not limited thereto

The piezoelectric ceramic may be configured as a single crystalline ceramic having a crystalline structure, or may be configured as a ceramic material having a polycrystalline structure or polycrystalline ceramic. A piezoelectric material including the single crystalline ceramic may include α-AlPO₄, α-SiO₂, LiNbO₃, Tb₂(MoO₄)₃, Li₂B₄O₇, or ZnO, but embodiments of the present disclosure are not limited thereto. A piezoelectric material including the polycrystalline ceramic may include a lead zirconate titanate (PZT)-based material, including lead (Pb), zirconium (Zr), and titanium (Ti), or may include a lead zirconate nickel niobate (PZNN)-based material, including lead (Pb), zirconium (Zr), nickel (Ni), and niobium (Nb), but embodiments of the present disclosure are not limited thereto.

For another example, the vibration part 231 may include at least one or more of calcium titanate (CaTiO₃), barium titanate (BaTiO₃), and strontium titanate (SrTiO₃), without lead (Pb), but embodiments of the present disclosure are not limited thereto.

The first electrode part 233 may be disposed at a first surface (or an upper surface) of the vibration part 231. The first electrode part 233 may have one electrode type (or single-body electrode type) which is disposed at an entire first surface of the vibration part 231. For example, the first electrode part 233 may have substantially a same shape as that of the vibration part 231, but embodiments of the present disclosure are not limited thereto.

The second electrode part 235 may be disposed at a second surface (or a rear surface) different from (or opposite to) the first surface of the vibration part 231. For example, the second electrode part 235 may be one electrode type (or single-body electrode type) which is disposed at an entire second surface of the vibration part 231. For example, the second electrode part 235 may have a same shape as the vibration part 231, but embodiments of the present disclosure are not limited thereto. For example, the second electrode part 235 may be made of a same material as the first electrode part 233, but embodiments of the present disclosure are not limited thereto. As another example, the second electrode part 235 may be configured in a different material from the first electrode part 233.

One or more of the first electrode part 233 and the second electrode part 235 according to an aspect of the present disclosure may be formed of a transparent conductive material, a semitransparent conductive material, or an opaque conductive material. For example, the transparent conductive material or the semitransparent conductive material may include indium tin oxide (ITO) or indium zinc oxide (IZO), but embodiments of the present disclosure are not limited thereto. The opaque conductive material may include gold (Au), silver (Ag), platinum (Pt), palladium (Pd), molybdenum (Mo), magnesium (Mg), carbon, or silver (Ag) including glass frit, or the like, or may be made of an alloy thereof, but embodiments of the present disclosure are not limited thereto. For example, to enhance an electrical characteristic and/or a vibration characteristic of the vibration part 231, each of the first electrode part 233 and the second electrode part 235 may include silver (Ag) having a low resistivity. For example, carbon may include carbon black, ketjen black, carbon nanotube, and a carbon material including graphite, but embodiments of the present disclosure are not limited thereto.

In the first electrode part 233 and the second electrode part 235 including silver (Ag) containing the glass frit, a content of glass frit may be about 1 wt % to about 12 wt %, but embodiments of the present disclosure are not limited thereto. The glass frit may include PbO or Bi₂O₃-based material, but embodiments of the present disclosure are not limited thereto.

The vibration part 231 may be polarized (or poling) by a certain voltage applied to the first electrode part 233 and the second electrode part 235 from an outside in a certain temperature atmosphere, or a temperature atmosphere that may be changed from a high temperature to a room temperature, but embodiments of the present disclosure are not limited thereto. The vibration part 231 may alternately and repeatedly contract and/or expand based on an inverse piezoelectric effect according to a sound signal (or a voice signal) applied to the first electrode part 233 and the second electrode part 235 from the outside to vibrate. The vibration part 231 may vibrate based on a vertical-direction vibration and a planar direction vibration by the sound signal applied to the first electrode part 233 and the second electrode part 235. The vibration part 231 may increase the displacement (or vibration or driving) of the vibration member (or the vibration plate or the vibration object) 100 by contraction and/or expansion of the planar direction, thereby further improving the vibration of the vibration apparatus 200.

The vibration apparatus 200 or the vibration device 230 according to an aspect of the present disclosure may further include a first protection member 220 and a second protection member 240.

The first protection member 220 may be disposed at a first surface of the vibration device 230. The first protection member 220 may be at the first electrode part 233. The first protection member 220 may be configured to cover the first electrode part 233. The first protection member 220 may be configured to have a larger size than the vibration device 230. Therefore, the first protection member 220 may protect the first surface of the vibration device 230 and the first electrode part 233. The first protection member 220 may be a first cover member, but embodiments of the present disclosure are not limited thereto.

The second protection member 240 may be disposed at a second surface different from (or opposite to) the first surface of the vibration device 230. The second protection member 240 may be at the second electrode part 235. The second protection member 240 may be configured to cover the second electrode part 235. The second protection member 240 may be configured to have a larger size than the vibration device 230 and have a same size as the first protection member 220. Therefore, the second protection member 240 may protect the second surface of the vibration device 230 and the second electrode part 235. The second protection member 240 may be a second cover member, but embodiments of the present disclosure are not limited thereto.

Each of the first protection member 220 and the second protection member 240 according to an aspect of the present disclosure may include one or more materials of plastic, fiber, carbon, and wood, but embodiments of the present disclosure are not limited thereto. Each of the first protection member 220 and the second protection member 240 may include a same material or a different material. In one example, each of the first protection member 220 and the second protection member 240 may be a polyimide film, a polyethylene terephthalate film, or polyethylene naphthalate, but embodiments of the present disclosure are not limited thereto.

The first protection member 220 according to an aspect of the present disclosure may be connected or coupled to the first electrode part 233 by a first adhesive layer 223. For example, the first protection member 220 may be connected or coupled to the first surface of the vibration device 230 or the first electrode part 233 by a film laminating process by the first adhesive layer 223.

The second protection member 240 according to an aspect of the present disclosure may be connected or coupled to the second electrode part 235 by a second adhesive layer 224. For example, the second protection member 240 may be connected or coupled to the second surface of the vibration device 230 or the second electrode part 235 by a film laminating process by the second adhesive layer 224.

The first adhesive layer 223 may be disposed between the first electrode part 233 and the first protection member 220. The second adhesive layer 224 may be disposed between the second electrode part 235 and the second protection member 240. The first adhesive layer 223 and second adhesive layer 224 may be configured between the first protection member 220 and the second protection member 240 to surround the vibration device 230. In one example, the first adhesive layer 223 and second adhesive layer 224 may be an adhesive layer which are configured between the first protection member 220 and the second protection member 240 to surround the vibration device 230. For example, one or more of the first adhesive layer 223 and second adhesive layer 224 may be configured to surround the vibration device 230. In another example, the first adhesive layer 223 and second adhesive layer 224 may be configured between the first protection member 220 and the second protection member 240 to completely surround the vibration part 231, the first electrode part 233, and the second electrode part 235. For example, the vibration part 231, the first electrode part 233, and the second electrode part 235 may be embedded or built-in between the first adhesive layer 223 and the second adhesive layer 224.

Each of the first adhesive layer 223 and second adhesive layer 224 according to an aspect of the present disclosure may include an electrically insulating material which has adhesiveness and is capable of compression and decompression. For example, each of the first adhesive layer 223 and the second adhesive layer 224 may include an epoxy resin, an acrylic resin, a silicone resin, or a urethane resin, but embodiments of the present disclosure are not limited thereto.

A vibration apparatus may be difficult to have a directivity when a vibration part 231 has a planar structure. Aspects of the present disclosure provide a vibration apparatus which may have a directivity. This will be further described below.

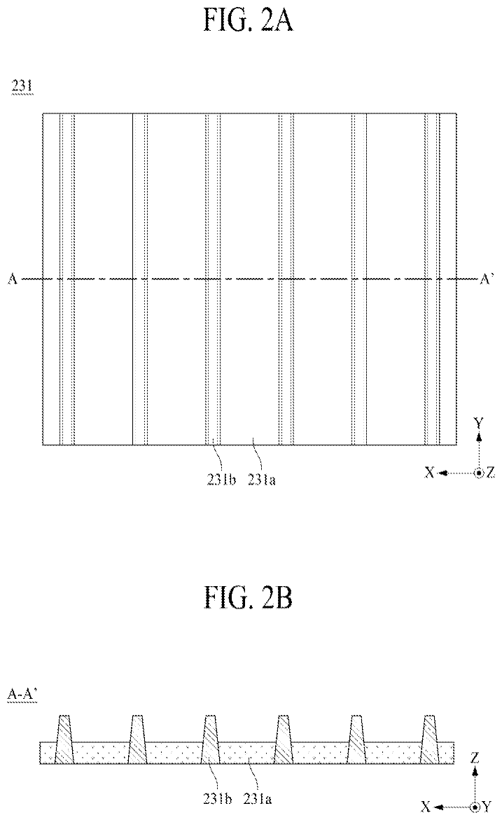

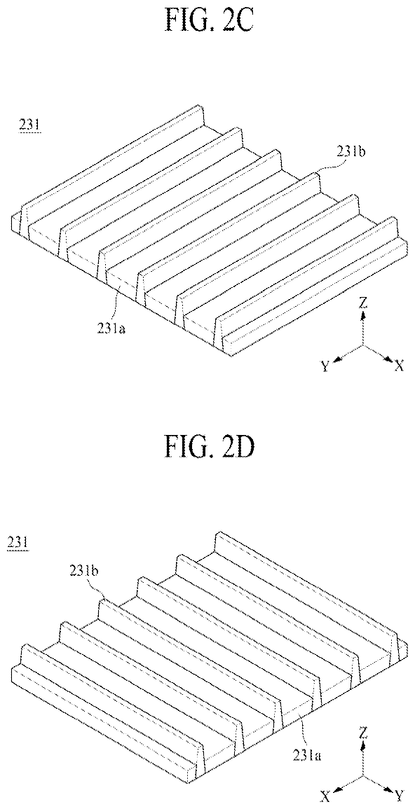

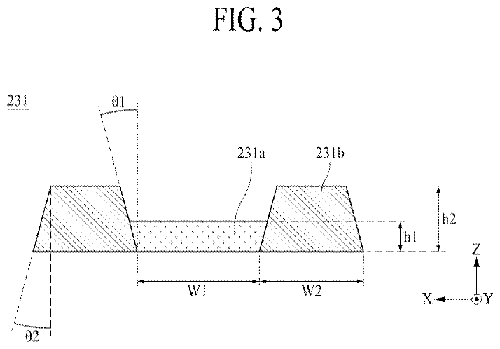

FIG. 2A is a plan view illustrated a vibration part according to an aspect of the present disclosure. FIG. 2B is a cross-sectional view taken along line A-A′ illustrated in FIG. 2A according to an aspect of the present disclosure. FIGS. 2C and 2D are a lateral view illustrated a vibration part according to an aspect of the present disclosure. FIG. 3 illustrates a vibration part according to an aspect of the present disclosure.

With reference to FIGS. 2A to 2D, one or more vibration devices 230 according to another aspect of the present disclosure may be configured to have flexibility. For example, the one or more vibration devices 230 may be configured to be bent in a non-planar shape including a curved surface. For example, the one or more vibration devices 230 according to an aspect of the present disclosure may be referred to as a flexible vibration structure, a flexible vibrator, a flexible vibration generating device, a flexible vibration generator, a flexible sounder, a flexible sound device, a flexible sound generating device, a flexible sound generator, a flexible actuator, a flexible speaker, a flexible piezoelectric speaker, a film actuator, a film-type piezoelectric composite actuator, a film speaker, a film-type piezoelectric speaker, or a film-type piezoelectric composite speaker, or the like, but embodiments of the present disclosure are not limited thereto.

The one or more vibration devices 230 according to an aspect of the present disclosure may include a vibration part 231.

The vibration part 231 may include a piezoelectric portion 231a and a supporting portion 231b. For example, the vibration part 231 may include a plurality of piezoelectric portions 231a and a plurality of supporting portions 231b. For example, the plurality of piezoelectric portions 231a and the plurality of supporting portions 231b may be alternately and repeatedly arranged in a first direction X (or a second direction Y). For example, the first direction X may be a widthwise direction of the vibration part 231, the second direction Y may be a lengthwise direction of the vibration part 231, but embodiments of the present disclosure are not limited thereto. For example, the first direction X may be the lengthwise direction of the vibration part 231, and the second direction Y may be the widthwise direction of the vibration part 231.

Each of the plurality of piezoelectric portions 231a may be configured as an inorganic material portion. The inorganic material portion may include a piezoelectric material, a composite piezoelectric material, or an electroactive material which includes a piezoelectric effect.

Each of the plurality of piezoelectric portions 231a may be configured as a ceramic-based material for generating a relatively strong vibration, or may be configured as a piezoelectric ceramic having a perovskite-based crystalline structure. The perovskite crystalline structure may have a piezoelectric effect and an inverse piezoelectric effect, and may be a plate-shaped structure having orientation. The perovskite crystalline structure may be represented by a chemical formula “ABO₃”, in the chemical formula “ABO₃”, the “A” may include a divalent metal element, and the “B” may include a tetravalent metal element. As an aspect of the present disclosure, in the chemical formula “ABO₃”, the “A”, and the “B” may be cations, and the “O” may be anions. For example, each of the plurality of piezoelectric portions 231a may include at least one or more of lead titanate (PbTiO₃), lead zirconate (PbZrO₃), lead zirconate titanate (PbZrTiO₃), barium titanate (BaTiO₃), and strontium titanate (SrTiO₃), but embodiments of the present disclosure are not limited thereto.

The piezoelectric ceramic may be configured as a single crystalline ceramic having a crystalline structure, or may be configured as a ceramic material having a polycrystalline structure or polycrystalline ceramic. A piezoelectric material including the single crystalline ceramic may include α-AlPO₄, α-SiO₂, LiNbO₃, Tb₂(MoO₄)₃, Li₂B₄O₇, or ZnO, but embodiments of the present disclosure are not limited thereto. A piezoelectric material including the polycrystalline ceramic may include a lead zirconate titanate (PZT)-based material, including lead (Pb), zirconium (Zr), and titanium (Ti), or may include a lead zirconate nickel niobate (PZNN)-based material, including lead (Pb), zirconium (Zr), nickel (Ni), and niobium (Nb), but embodiments of the present disclosure are not limited thereto.

Each of the plurality of supporting portions 231b may be disposed between the plurality of piezoelectric portions 231a. For example, the supporting portion 231b may be connected to the piezoelectric portion 231a. Therefore, in the vibration part 231 or the vibration device 230, vibration energy by a link in a unit lattice of each piezoelectric portions 231a may increase by a corresponding supporting portion 231b, and thus, a vibration characteristic may increase, and a piezoelectric characteristic and flexibility may be secured.

Each of the plurality of supporting portions 231b according to an aspect of the present disclosure may be configured as an organic material portion. For example, the organic material portion may be disposed between the inorganic material portions, and thus, may absorb an impact applied to the inorganic material portion (or the piezoelectric portion), may release a stress concentrating on the inorganic material portion to enhance the total durability of the vibration part 231 or the vibration device 230, and may provide flexibility to the vibration part 231 or the vibration device 230.

The plurality of supporting portions 231b according to an aspect of the present disclosure may have a modulus (or Young's modulus) and viscoelasticity that are lower than those of each piezoelectric portion 231a, and thus, the supporting portion 231b may enhance the reliability of each piezoelectric portion 231a vulnerable to an impact due to a fragile characteristic. For example, the supporting portion 231b may be configured as a material having a loss coefficient of about 0.01 to about 1 and modulus (or Young's modulus) of about 0.1 GPa (Giga pascal) to about 10 GPa (Giga pascal).

The organic material portion configured at the supporting portion 231b may include one or more of an organic material, an organic polymer, an organic piezoelectric material, or an organic non-piezoelectric material that has a flexible characteristic in comparison with the inorganic material portion of the piezoelectric portions 231a. For example, the supporting portion 231b may be an adhesive portion, an elastic portion, a bending portion, a damping portion, or a flexible portion or the like which have flexibility, but embodiments of the present disclosure are not limited thereto. For example, the vibration part 231 may be vibrated in a vertical direction with respect to the vibrating member 100 by the piezoelectric portion 231a having a vibration characteristic and may be bent in a curved shape by the supporting portion 231b having flexibility.

According to an aspect of the present disclosure, the plurality of piezoelectric portions 231a and the plurality of supporting portions 231b may be disposed (or connected) on a same plane, and thus, the vibration part 231 may have a single thin film type. However, there may be a problem where a directivity is not good due to a planar structure.

According to an aspect of the present disclosure, the plurality of piezoelectric portions 231a and the plurality of supporting portions 231b may be configured to have different shapes, and thus, may not be disposed on a same plane, thereby implementing a vibration apparatus having a directivity.

According to an aspect of the present disclosure, a shape of the supporting portion 231b may be configured to be different from that of the piezoelectric portion 231a. A shape of the supporting portion 231b may perform the horn guide or sound guide of the vibration apparatus for enhancing a directivity. For example, the supporting portion 231b may contact the piezoelectric portion 231a and may be a damper (or buffer) for independent driving. For example, the supporting portion 231b may include a material having a modulus (or a Young's modulus) of 106 Pa (Pascal) or more, but embodiments of the present disclosure are not limited thereto. For example, the supporting portion 231b may include one or more of a urethane-based polymer, an epoxy-based polymer, an acrylic-based polymer, and a silicone-based polymer, but embodiments of the present disclosure are not limited thereto. For example, the supporting portion 231b may be a partition wall, a supporter, or an adhesive member, but embodiments of the present disclosure are not limited thereto.

A vibration apparatus (a sound apparatus) having a directivity may modulate an ultrasound to generate a directivity of a sound in a specific direction. According to an aspect of the present disclosure, the piezoelectric portion 231a may be configured to generate an ultrasound and may drive an ultrasound region. For example, the piezoelectric portion 231a may include a material having a chemical quality factor Qm of 400 or more, to generate an ultrasound. For example, as a mechanical quality factor increases, an ultrasound vibration may be easily performed. For example, the piezoelectric portion 231a may include lead zirconate titanate (PZT) (Pb (Zr, Ti) O₃), lead magnesium niobate-lead titanate (PMN-PT), lead magnesium niobate-lead zirconate titanate (PMN-PZT), lead magnesium niobate-lead nickel niobate-lead zirconate titanate (PMN-PNN-PZT), and BaTiO₃, or the like, but embodiments of the present disclosure are not limited thereto. Accordingly, a vibration apparatus 200 which may have a directivity and may drive an ultrasound region may be implemented. For example, the piezoelectric portion 231a may be a piezoelectric element, but embodiments of the present disclosure are not limited thereto.

With reference to FIGS. 2A to 3, a shape of the supporting portion 231b may be a trapezoid shape. The vibration part 231 may have a horn structure based on a shape of the supporting portion 231b, and thus, the vibration device 230 or the vibration apparatus 200 for enhancing a directivity may be implemented. For example, the vibration part 231 may have a conical horn shape.

With reference to FIG. 3, a first angle 61 may be an angle of horn guide configured by a trapezoid shape of the supporting portion 231b. Based on the horn guide or sound guide of the supporting portion 231b, a directivity of a sound may be enhanced. For example, the first angle 61 may be 10 degrees to 30 degrees, but embodiments of the present disclosure are not limited thereto. For example, the first angle 61 may be 10 degrees or more and 30 degrees or less, but embodiments of the present disclosure are not limited thereto. When the first angle 61 is 10 degrees to 30 degrees or is 10 degrees or more and 30 degrees or less, a directivity characteristic of the vibration device 230 or the vibration apparatus 200 may be more enhanced by a sound guided in the supporting portion 231b. For example, a second angle 62 may be an angle having the trapezoid shape of the supporting portion 231b. For example, the second angle 62 may be equal to or different from the first angle θ1. For example, the second angle 62 may be 10 degrees to 30 degrees, but embodiments of the present disclosure are not limited thereto. For example, the second angle 62 may be 10 degrees or more and 30 degrees or less, but embodiments of the present disclosure are not limited thereto. When the second angle 62 is 10 degrees to 30 degrees or is 10 degrees or more and 30 degrees or less, a directivity characteristic of the vibration device 230 or the vibration apparatus 200 may be more enhanced.

According to an aspect of the present disclosure, a height h2 of the supporting portion 231b may differ from a height h1 of the piezoelectric portion 231a. Therefore, the supporting portion 231b may perform horn or sound guide. For example, when the height h2 of the supporting portion 231b differs from the height h1 of the piezoelectric portion 231a, a vibration apparatus having a shape having a directivity may be implemented according to sound guide based on a height of the supporting portion 231b. For example, the height h2 of the supporting portion 231b may be higher than the height h1 of the piezoelectric portion 231a. For example, the height h1 of the piezoelectric portion 231a may be 100 μm to 1,000 μm, but embodiments of the present disclosure are not limited thereto. The height h2 of the supporting portion 231b may be 2 to 4 times the height h1 of the piezoelectric portion 231a, but embodiments of the present disclosure are not limited thereto. For example, the height h2 of the supporting portion 231b may be 200 [symbol] to 4,000 [symbol] , but embodiments of the present disclosure are not limited thereto. For example, the height h1 of the piezoelectric portion 231a may be a thickness of the piezoelectric portion 231a. For example, the height h2 of the supporting portion 231b may be a thickness of the supporting portion 231b.

According to an aspect of the present disclosure, a width W1 of the piezoelectric portion 231a may differ from a width W2 of the supporting portion 231b. For example, a width W1 of a lower surface of the piezoelectric portion 231a may differ from a width W2 of a lower surface of the supporting portion 231b. For example, the width W1 of the piezoelectric portion 231a may be greater than the width W2 of the supporting portion 231b. The width W1 of the piezoelectric portion 231a may vary based on a driving frequency. For example, in a region where the driving frequency is 100 kHz, the width W1 of the piezoelectric portion 231a may be at least 1 mm or more, but embodiments of the present disclosure are not limited thereto. The width W2 of the supporting portion 231b may be 1/10 or less of the width W1 of the piezoelectric portion 231a, but the width W1 of the piezoelectric portion 231a may vary based on a flexible characteristic of a vibration apparatus. For example, the width W1 of the piezoelectric portion 231a may be 1 mm or more and 20 mm or less, but embodiments of the present disclosure are not limited thereto. For example, the width W2 of the supporting portion 231b may be 0.1 mm or more and 2.0 mm or less, but embodiments of the present disclosure are not limited thereto.

According to an aspect of the present disclosure, because the vibration part 231 having a horn structure configured based on the trapezoid shape of the supporting portion 231b is provided, a vibration apparatus having directivity may be implemented based on the sound guide of the horn structure. For example, a vibration apparatus which is implemented by a simplified process and has an orientation may be implemented.

Because the vibration apparatus according to an aspect of the present disclosure has the horn structure based on a shape of the supporting portion 231b, the vibration apparatus may be a sound apparatus having directivity, and a carrier frequency of the sound apparatus having directivity may have 20 kHz or more and 100 kHz or less, but embodiments of the present disclosure are not limited thereto. For example, the carrier frequency may be a frequency of an ultrasound band, but embodiments of the present disclosure are not limited thereto. Accordingly, a vibration apparatus which may have directivity and may drive an ultrasound region may be provided.

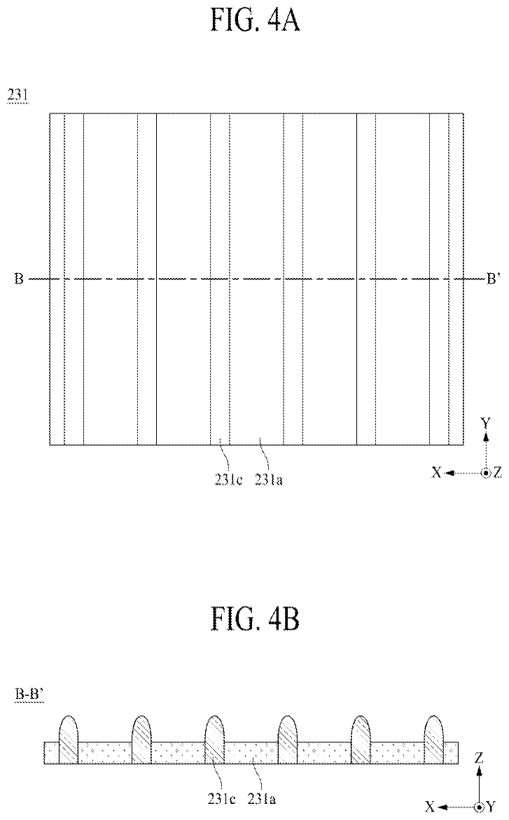

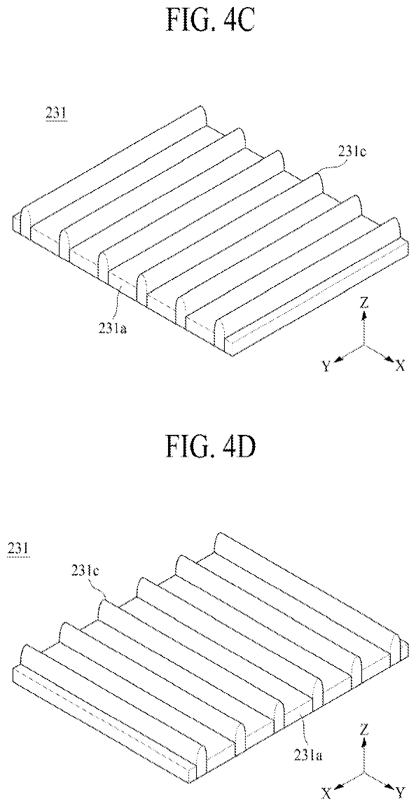

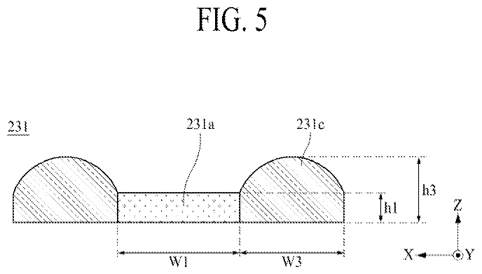

FIG. 4A is a plan view illustrating a vibration part according to another aspect of the present disclosure. FIG. 4B is a cross-sectional view taken along line B-B′ illustrated in FIG. 4A according to another aspect of the present disclosure. FIGS. 4C and 4D are a lateral view illustrating a vibration part according to another aspect of the present disclosure. FIG. 5 illustrates a vibration part according to another aspect of the present disclosure.

With reference to FIGS. 4A to 5, a vibration device 230 according to another aspect of the present disclosure may include a vibration part 231.

The vibration part 231 may include a piezoelectric portion 231a and a supporting portion 231c. For example, the vibration part 231 may include a plurality of piezoelectric portions 231a and a plurality of supporting portions 231c. Except for a shape of a supporting portion, descriptions of the piezoelectric portion 231a and the supporting portion 231c may be a same as the descriptions of FIGS. 2A to 3, and thus, may be omitted or may be briefly given.

With reference to FIGS. 4A to 5, a shape of the piezoelectric portion 231a may differ from that of the supporting portion 231c. For example, a shape of the supporting portion 231c may be a convex shape. The vibration part 231 may have a horn structure based on a shape of the supporting portion 231c, and thus, a vibration device 230 or a vibration apparatus 200 for enhancing directivity may be implemented. For example, the vibration part 231 may have an exponential horn shape.

With reference to FIG. 5, a height h3 of the supporting portion 231c may differ from a height h1 of the piezoelectric portion 231a. Therefore, the supporting portion 231c may perform horn or sound guide. For example, when the height h3 of the supporting portion 231c differs from the height h1 of the piezoelectric portion 231a, a vibration apparatus having a shape having a directivity may be implemented according to sound guide based on a height of the supporting portion 231c. For example, the height h3 of the supporting portion 231c may be higher than the height h1 of the piezoelectric portion 231a. For example, the height h1 of the piezoelectric portion 231a may be 100 [symbol] to 1,000 [symbol] , but embodiments of the present disclosure are not limited thereto. The height h3 of the supporting portion 231c may be 2 to 4 times the height h1 of the piezoelectric portion 231a, but embodiments of the present disclosure are not limited thereto. For example, the height h3 of the supporting portion 231c may be 200 [symbol] to 4,000 [symbol] , but embodiments of the present disclosure are not limited thereto. For example, the height h1 of the piezoelectric portion 231a may be a thickness of the piezoelectric portion 231a. For example, the height h3 of the supporting portion 231c may be a thickness of the supporting portion 231c.

According to an aspect of the present disclosure, a width W1 of the piezoelectric portion 231a may differ from a width W3 of the supporting portion 231c. For example, a width W1 of a lower surface of the piezoelectric portion 231a may differ from a width W3 of a lower surface of the supporting portion 231c. For example, the width W1 of the piezoelectric portion 231a may be greater than the width W3 of the supporting portion 231c. The width W1 of the piezoelectric portion 231a may vary based on a driving frequency. For example, in a region where the driving frequency is 100 kHz, the width W1 of the piezoelectric portion 231a may be at least 1 mm or more, but embodiments of the present disclosure are not limited thereto. The width W3 of the supporting portion 231c may be 1/10 or less of the width W1 of the piezoelectric portion 231a, but the width W1 of the piezoelectric portion 231a may vary based on a flexible characteristic of a vibration apparatus. For example, the width W1 of the piezoelectric portion 231a may be 1 mm or more and 20 mm or less, but embodiments of the present disclosure are not limited thereto. For example, the width W3 of the supporting portion 231c may be 0.1 mm or more and 2.0 mm or less, but embodiments of the present disclosure are not limited thereto.

According to an aspect of the present disclosure, because the vibration part 231 having a horn structure configured based on the convex shape of the supporting portion 231b is provided, a vibration apparatus having directivity may be implemented based on the sound guide of the horn structure. For example, a vibration apparatus which is implemented by a simplified process and has directivity may be implemented.

Because the vibration apparatus according to an aspect of the present disclosure has the horn structure based on a shape of the supporting portion 231c, the vibration apparatus may be a sound apparatus having directivity, and a carrier frequency of the sound apparatus having directivity may have 20 kHz or more and 100 kHz or less, but embodiments of the present disclosure are not limited thereto. For example, the carrier frequency may be a frequency of an ultrasound band, but embodiments of the present disclosure are not limited thereto. Accordingly, a vibration apparatus which may have directivity and may drive an ultrasound region may be provided.

The following Table 1 illustrates a result obtained by measuring an equivalent mass in a forward direction of the vibration apparatus according to an aspect of the present disclosure.

TABLE 1

| Division | Equivalent Mass | | | |
|---|---|---|---|---|
| Measurement Distance | 5 | cm | 30 | cm |
| Experimental Example | 30 | mg | 5 | mg |
| Aspect 1 | 40 | mg | 20 | mg |
| Aspect 2 | 45 | mg | 15 | mg |

The equivalent mass may represent a sound pressure level in a forward direction of the vibration apparatus. The equivalent mass has been measured under a condition where a driving frequency is set to a sine wave in 30 kHz, an application voltage is set to ±40 V, and a measurement distance from the vibration apparatus to an electronic scale is set to 5 cm to 30 cm. The driving frequency and the application voltage do not limit the details of the present disclosure.

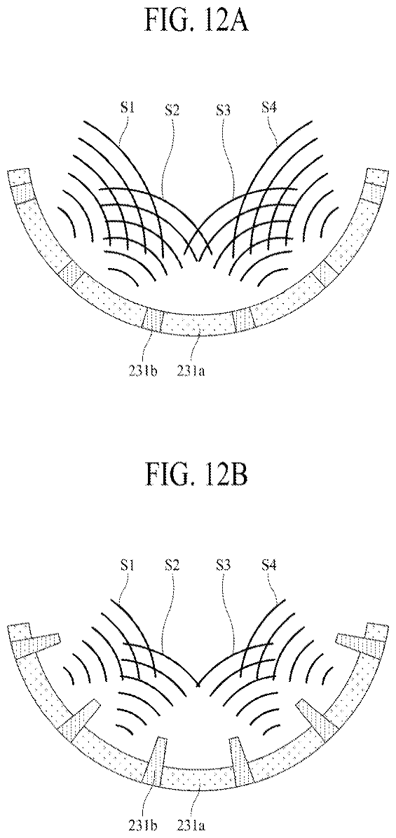

In the experimental example of Table 1, a vibration part is configured where a height of a piezoelectric portion is equal to that of a supporting portion and the piezoelectric portion and the supporting portion are disposed on the same plane, and a vibration apparatus including a first electrode part and a second electrode part is configured in FIG. 2A. For example, in FIG. 12A described below, the vibration apparatus is disposed on a plane instead of a curved shape. In the aspect 1, a vibration part is configured as in FIGS. 2A to 3, and a vibration apparatus is configured to include a first electrode part and a second electrode part. In the aspect 2, a vibration part is configured as in FIGS. 4A to 5, and a vibration apparatus is configured to include a first electrode part and a second electrode part.

For the measurement distance of 5 cm, the equivalent mass of the experimental example has been measured to be 30 mg, the equivalent mass of the aspect 1 has been measured to be 40 mg, and the equivalent mass of the aspect 2 has been measured to be 45 mg. In the measurement distance of 30 cm, the equivalent mass of the experimental example has been measured to be 5 mg, the equivalent mass of the aspect 1 has been measured to be 20 mg, and the equivalent mass of the aspect 2 has been measured to be 15 mg.

Comparing with the experimental example, in the aspect 1 and the aspect 2 of the present disclosure, it may be seen that an equivalent mass increases. For example, comparing with the experimental example, in the aspect 1 and the aspect 2 of the present disclosure, it may be seen that a sound collection effect and directivity are enhanced. For example, comparing with the experimental example having a planar structure, in the aspect 1 where a vibration part has a conical horn structure and the aspect 2 where a vibration part has an exponential structure, it may be seen that a sound collection effect and directivity are enhanced. According to an aspect of the present disclosure, because a vibration part having the horn structure may be configured, and thus, directivity for collecting a sound in one place may be enhanced by the sound guide of the horn structure.

For the measurement distance of 30 cm, the aspect 1 of the present disclosure has increased more in equivalent mass than the aspect 2, and thus, it may be seen that the aspect 1 is better sound collection properties than the aspect 2 in a long distance. For example, in the aspect 1, it may be seen that the vibration apparatus including the vibration part having the conical horn structure has better sound collection properties in a long distance.

For the measurement distance of 5 cm, the aspect 2 of the present disclosure has increased more in equivalent mass than the aspect 1, and thus, it may be seen that the aspect 2 is better sound collection properties than the aspect 1 in a short distance. For example, in the aspect 2, it may be seen that the vibration apparatus including the vibration part having the exponential horn structure has better sound collection properties in a relatively short distance.

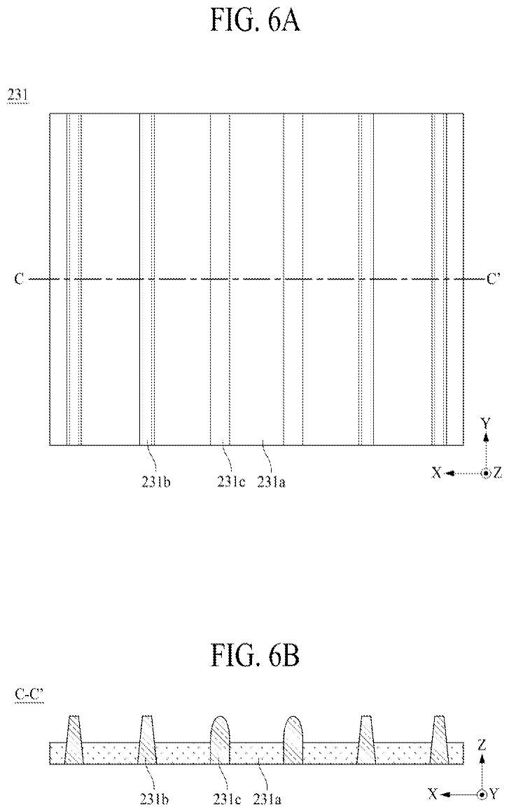

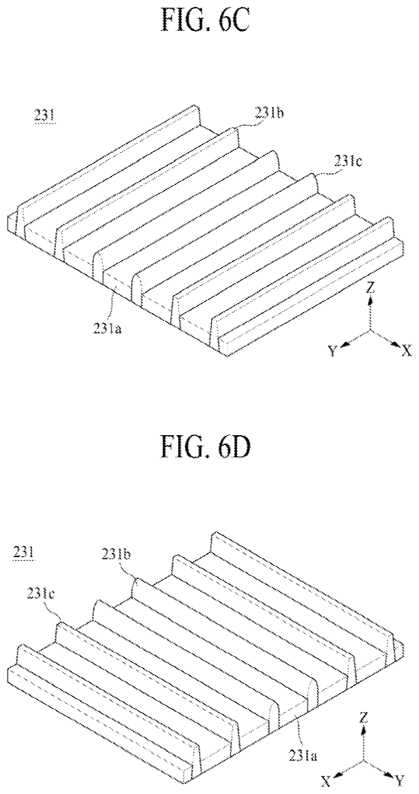

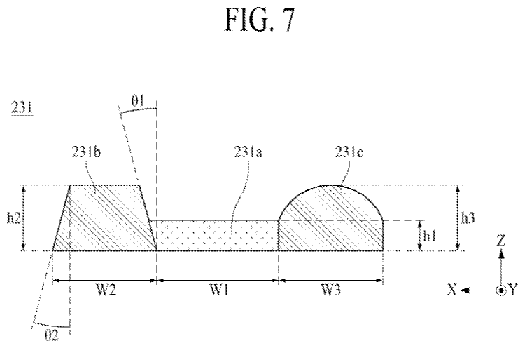

FIG. 6A is a plan view illustrating a vibration part according to another aspect of the present disclosure. FIG. 6B is a cross-sectional view taken along line C-C′ illustrated in FIG. 6A according to another aspect of the present disclosure. FIGS. 6C and 6D are a lateral view illustrating a vibration part according to another aspect of the present disclosure. FIG. 7 illustrates a vibration part according to another aspect of the present disclosure.

With reference to FIGS. 6A to 7, a vibration device 230 according to another aspect of the present disclosure may include a vibration part 231.

The vibration part 231 may include a plurality of piezoelectric portions 231a and a plurality of supporting portions 231b and 231c. For example, the vibration part 231 may include a plurality of piezoelectric portions 231a, a first supporting portion 231b, and a second supporting portion 231c. Except for a shape of a supporting portion, descriptions of the piezoelectric portion 231a and the supporting portions 231b and 231c may be a same as the descriptions of FIGS. 2A to 3, and thus, may be omitted or may be briefly given.

With reference to FIGS. 6A to 7, the supporting portion may include a plurality of first supporting portions 231b and a plurality of second supporting portions 231c. For example, the plurality of first supporting portions 231b may be disposed in parallel with a piezoelectric portion 231a therebetween. The plurality of second supporting portions 231c may be disposed in parallel with the piezoelectric portion 231a therebetween.

According to an aspect of the present disclosure, a shape of the piezoelectric portion 231a may differ from that of the first supporting portion 231b and/or that of the second supporting portion 231c. For example, a shape of each of the plurality of first supporting portions 231b may differ from that of each of the plurality of second supporting portions 231c. For example, the first supporting portion 231b and the second supporting portion 231c may be configured to a ratio of 50:50, but embodiments of the present disclosure are not limited thereto. For example, each of the plurality of first supporting portions 231b may include a slope surface which protrudes from the piezoelectric portion 231a. For example, each of the plurality of second supporting portions 231c may include a curved surface which protrudes from the piezoelectric portion 231a. For example, a shape of each of the plurality of first and second supporting portions 231b and 231c may be a combination of a trapezoid shape and a convex shape. For example, a shape of the first supporting portion 231b may be a trapezoid shape. For example, a shape of the second supporting portion 231c may be a convex shape. For example, shapes of the supporting portions 231b and 231c at a center of the vibration part 231 and a periphery of the vibration part 231 may differ. For example, the first supporting portion 231b may be provided at the periphery of the vibration part 231, and the second supporting portion 231c may be provided at the center of the vibration part 231. For example, the first supporting portion 231b may be configured to have a trapezoid shape at the periphery of the vibration part 231, and the second supporting portion 231c may be configured to have a convex shape at the center of the vibration part 231. Accordingly, a directivity may increase toward both peripheries of the vibration part 231 rather than the center of the vibration part 231. For example, when the first supporting portion 231b is at a left periphery and/or a right periphery of the vibration apparatus, a sound guided by the first supporting portion 231b may increase, and thus, a directivity may increase toward the both peripheries of the vibration part 231. For example, the vibration part 231 may have a horn structure based on a shape of the first supporting portion 231b and a shape of the second supporting portion 231c, and thus, the vibration device 230 or the vibration apparatus 200 for enhancing a directivity may be implemented. For example, the vibration part 231 may have a conical horn shape and an exponential horn shape. For example, the vibration part 231 may have a hybrid shape having the conical horn shape and the exponential horn shape.

With reference to FIG. 7, a first angle θ1 may be an angle of horn guide configured by a trapezoid shape of the first supporting portion 231b. Based on the horn guide or sound guide of the first supporting portion 231b, a directivity of a sound may be enhanced. For example, the first angle θ1 may be 10 degrees to 30 degrees, but embodiments of the present disclosure are not limited thereto. For example, the first angle θ1 may be 10 degrees or more and 30 degrees or less, but embodiments of the present disclosure are not limited thereto. When the first angle θ1 is 10 degrees to 30 degrees or is 10 degrees or more and 30 degrees or less, a directivity characteristic of the vibration device 230 or the vibration apparatus 200 may be more enhanced by a sound guided in the first supporting portion 231b. For example, a second angle θ2 may be an angle having the trapezoid shape of the first supporting portion 231b. For example, the second angle θ2 may be equal to or different from the first angle θ1. For example, the second angle θ2 may be 10 degrees to 30 degrees, but embodiments of the present disclosure are not limited thereto. For example, the second angle θ2 may be 10 degrees or more and 30 degrees or less, but embodiments of the present disclosure are not limited thereto. When the second angle θ2 is 10 degrees to 30 degrees or is 10 degrees or more and 30 degrees or less, a directivity characteristic of the vibration device 230 or the vibration apparatus 200 may be more enhanced.

With reference to FIG. 7, a height h2 of the first supporting portion 231b may differ from a height h1 of the piezoelectric portion 231a. Therefore, the first supporting portion 231b may perform horn or sound guide. For example, when the height h2 of the first supporting portion 231b differs from the height h1 of the piezoelectric portion 231a, a vibration apparatus having shape having a directivity may be implemented according to sound guide based on a height of the first supporting portion 231b. For example, the height h2 of the first supporting portion 231b may be higher than the height h1 of the piezoelectric portion 231a. For example, the height h1 of the piezoelectric portion 231a may be 100 [symbol] to 1,000 [symbol] , but embodiments of the present disclosure are not limited thereto. The height h2 of the first supporting portion 231b may be 2 to 4 times the height h1 of the piezoelectric portion 231a, but embodiments of the present disclosure are not limited thereto. For example, the height h2 of the first supporting portion 231b may be 200 [symbol] to 4,000 [symbol] , but embodiments of the present disclosure are not limited thereto. For example, the height h1 of the piezoelectric portion 231a may be a thickness of the piezoelectric portion 231a. For example, the height h2 of the first supporting portion 231b may be a thickness of the first supporting portion 231b.

A height h3 of the second supporting portion 231c may differ from a height h1 of the piezoelectric portion 231a. Therefore, the second supporting portion 231c may perform horn or sound guide. For example, when the height h3 of the second supporting portion 231c differs from the height h1 of the piezoelectric portion 231a, a vibration apparatus having shape having a directivity may be implemented according to sound guide based on a height of the second supporting portion 231c. For example, the height h3 of the second supporting portion 231c may be higher than the height h1 of the piezoelectric portion 231a. For example, the height h1 of the piezoelectric portion 231a may be 100 [symbol] to 1,000 [symbol] , but embodiments of the present disclosure are not limited thereto. The height h3 of the second supporting portion 231c may be 2 to 4 times the height h1 of the piezoelectric portion 231a, but embodiments of the present disclosure are not limited thereto. For example, the height h3 of the second supporting portion 231c may be 200 [symbol] to 4,000 [symbol] , but embodiments of the present disclosure are not limited thereto. For example, the height h3 of the second supporting portion 231c may be a thickness of the second supporting portion 231c.

According to an aspect of the present disclosure, a height h2 of the first supporting portion 231b may be configured to be equal to or different from a height h3 of the second supporting portion 231c. For example, when the height h2 of the first supporting portion 231b differs from the height h3 of the second supporting portion 231c, a vibration apparatus having a desired shape having a directivity may be implemented. For example, when the height h2 of the first supporting portion 231b differs from the height h3 of the second supporting portion 231c, a vibration apparatus having a directivity may be implemented according to sound guide based on the heights of the first supporting portion 231b and the second supporting portion 231c. For example, when the height h2 of the first supporting portion 231b is equal to the height h3 of the second supporting portion 231c, a vibration apparatus having a circular or oval shape having a directivity may be implemented. For example, when the height h2 of the first supporting portion 231b differs from the height h3 of the second supporting portion 231c, a vibration apparatus having a directivity having a complicated shape or a multi-slit shape may be implemented.

According to an aspect of the present disclosure, a width W1 of the piezoelectric portion 231a may differ from a width W2 of the first supporting portion 231b. For example, a width W1 of a lower surface of the piezoelectric portion 231a may differ from a width W2 of a lower surface of the first supporting portion 231b. For example, the width W1 of the piezoelectric portion 231a may be greater than the width W2 of the first supporting portion 231b. The width W1 of the piezoelectric portion 231a may vary based on a driving frequency. For example, in a region where the driving frequency is 100 kHz, the width W1 of the piezoelectric portion 231a may be at least 1 mm or more, but embodiments of the present disclosure are not limited thereto. The width W2 of the first supporting portion 231b may be 1/10 or less of the width W1 of the piezoelectric portion 231a, but the width W1 of the piezoelectric portion 231a may vary based on a flexible characteristic of a vibration apparatus. For example, the width W1 of the piezoelectric portion 231a may be 1 mm or more and 20 mm or less, but embodiments of the present disclosure are not limited thereto. For example, the width W2 of the first supporting portion 231b may be 0.1 mm or more and 2.0 mm or less, but embodiments of the present disclosure are not limited thereto.

According to an aspect of the present disclosure, a width W1 of the piezoelectric portion 231a may differ from a width W3 of the second supporting portion 231c. For example, a width W1 of a lower surface of the piezoelectric portion 231a may differ from a width W3 of a lower surface of the second supporting portion 231c. For example, the width W1 of the piezoelectric portion 231a may be greater than the width W3 of the second supporting portion 231c. The width W1 of the piezoelectric portion 231a may vary based on a driving frequency. For example, in a region where the driving frequency is 100 kHz, the width W1 of the piezoelectric portion 231a may be at least 1 mm or more, but embodiments of the present disclosure are not limited thereto. The width W3 of the second supporting portion 231c may be 1/10 or less of the width W1 of the piezoelectric portion 231a, but the width W1 of the piezoelectric portion 231a may vary based on a flexible characteristic of a vibration apparatus. For example, the width W1 of the piezoelectric portion 231a may be 1 mm or more and 20 mm or less, but embodiments of the present disclosure are not limited thereto. For example, the width W3 of the second supporting portion 231c may be 0.1 mm or more and 2.0 mm or less, but embodiments of the present disclosure are not limited thereto.

According to an aspect of the present disclosure, a width W2 of the first supporting portion 231b may be configured to be equal to or different from a width W3 of the second supporting portion 231c. For example, when the width W2 of the first supporting portion 231b differs from the width W3 of the second supporting portion 231c, a directivity angle and/or vibration intensity may be adjusted at a desired position. The width W2 of the first supporting portion 231b and/or the width W3 of the second supporting portion 231c may be configured to be different from each other based on a shape of a directivity which is to be implemented. Accordingly, a vibration apparatus having a shape of a directivity to implement may be implemented.

Because the vibration apparatus according to an aspect of the present disclosure has the horn structure based on a shape of the first supporting portion 231b and a shape of the second supporting portion 231c, the vibration apparatus may be a sound apparatus having a directivity, and a carrier frequency of the sound apparatus having a directivity may have 20 kHz or more and 100 kHz or less, but embodiments of the present disclosure are not limited thereto. For example, the carrier frequency may be a frequency of an ultrasound band, but embodiments of the present disclosure are not limited thereto. Accordingly, a vibration apparatus which may have a directivity and may drive an ultrasound region may be provided.

According to an aspect of the present disclosure, the vibration part 231 having a horn structure configured based on a trapezoid shape of the first supporting portion 231b and a convex shape of the second supporting portion 231c may be configured, and thus, a vibration apparatus having a directivity may be implemented by the sound guide of the horn structure. For example, a vibration apparatus which has a directivity and is implemented through a simplified process may be implemented. In the vibration apparatus according to an aspect of the present disclosure, a trapezoid shape of the first supporting portion 231b may be provided at a periphery of the vibration part 231, and thus, a directivity may be enhanced toward a periphery of the vibration apparatus.

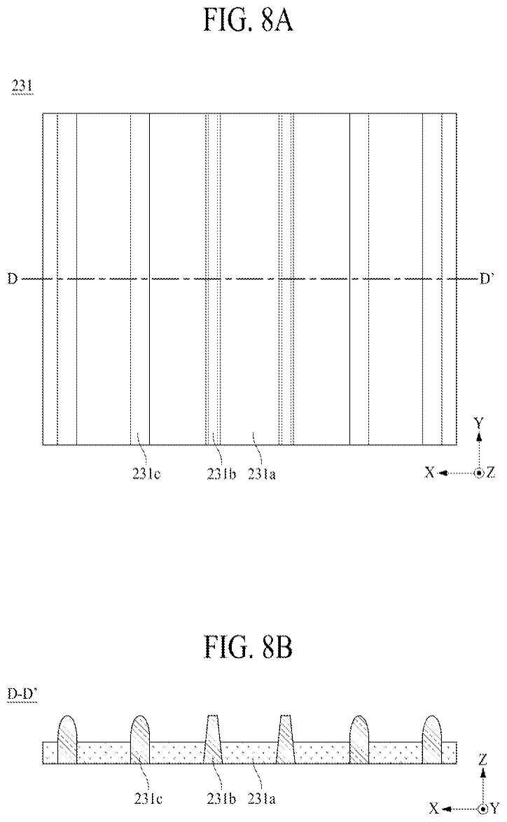

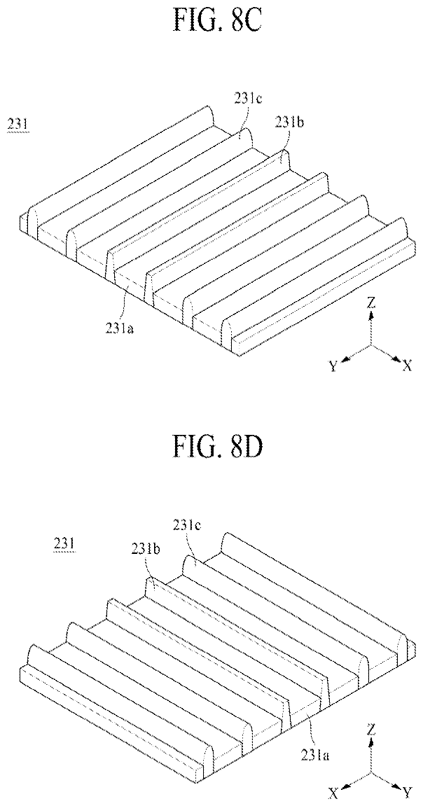

FIG. 8A is a plan view illustrating a vibration part according to another aspect of the present disclosure. FIG. 8B is a cross-sectional view taken along line D-D′ illustrated in FIG. 8A according to another aspect of the present disclosure. FIGS. 8C and 8D are a lateral view illustrating a vibration part according to another aspect of the present disclosure.

The vibration part 231 may include a plurality of piezoelectric portions 231a and a plurality of supporting portions 231b and 231c. For example, the vibration part 231 may include a piezoelectric portion 231a, a first supporting portion 231b, and a second supporting portion 231c. Except for a shape of a supporting portion, descriptions of the piezoelectric portion 231a and the supporting portions 231b and 231c may be a same as the descriptions of FIGS. 2A to 3, and thus, may be omitted or may be briefly given.

With reference to FIGS. 8A to 8D, a shape of the piezoelectric portion 231a may differ from that of the first supporting portion 231b and/or that of the second supporting portion 231c. For example, a shape of the first supporting portion 231b may differ from that of the second supporting portion 231c. For example, the shape of a first supporting portion 231b may be a trapezoid shape. For example, the shape of the second supporting portion 231c may be a convex shape. For example, each of the plurality of first supporting portions 231b may include a slope surface which protrudes from the piezoelectric portion 231a. For example, each of the plurality of second supporting portions 231c may include a curved surface which protrudes from the piezoelectric portion 231a. For example, a shape of each of the plurality of supporting portions 231b and 231c may be a combination of a trapezoid shape and a convex shape. For example, the first supporting portion 231b and the second supporting portion 231c may be configured to a ratio of 50:50, but embodiments of the present disclosure are not limited thereto. For example, shapes of the supporting portions 231b and 231c at a center of a vibration part 231 and a periphery of the vibration part 231 may differ. For example, the first supporting portion 231b may be provided at the center of the vibration part 231, and the second supporting portion 231c may be provided at the periphery of the vibration part 231. For example, the first supporting portion 231b may be configured to have a trapezoid shape at the center of the vibration part 231, and the second supporting portion 231c may be configured to have a convex shape at the periphery of the vibration part 231. Accordingly, a directivity may increase toward the center of the vibration part 231 rather than the periphery of the vibration part 231. For example, when the first supporting portion 231b is at a center of a vibration apparatus, a sound guided by the first supporting portion 231b may increase, and thus, a directivity may increase toward the center of the vibration part 231. For example, the vibration part 231 may have a horn structure based on a shape of the first supporting portion 231b and a shape of the second supporting portion 231c, and thus, the vibration device 230 or the vibration apparatus 200 for enhancing a directivity may be implemented. For example, the vibration part 231 may have a conical horn shape and an exponential horn shape. For example, the vibration part 231 may have a hybrid shape having the conical horn shape and the exponential horn shape.

The height h1 of a piezoelectric portion 231a, the height h2 of the first supporting portion 231b, and the height h3 of the second supporting portion 231c may be a same as the descriptions of FIG. 7, and thus, repeated descriptions thereof are omitted.

The width W1 of a piezoelectric portion 231a, the width W2 of the first supporting portion 231b, and the width W3 of the second supporting portion 231c may be a same as the descriptions of FIG. 7, and thus, repeated descriptions thereof are omitted.

Because the vibration apparatus according to an aspect of the present disclosure has the horn structure based on a shape of the first supporting portion 231b and a shape of the second supporting portion 231c, the vibration apparatus may be a sound apparatus having a directivity, and a carrier frequency of the sound apparatus having a directivity may have 20 kHz or more and 100 kHz or less, but embodiments of the present disclosure are not limited thereto. For example, the carrier frequency may be a frequency of an ultrasound band, but embodiments of the present disclosure are not limited thereto. Accordingly, a vibration apparatus which may have a directivity and may drive an ultrasound region may be provided.

According to an aspect of the present disclosure, the vibration part 231 having a horn structure configured based on a trapezoid shape of the first supporting portion 231b and a convex shape of the second supporting portion 231c may be configured, and thus, a vibration apparatus having a directivity may be implemented by the sound guide of the horn structure. In a vibration apparatus according to an aspect of the present disclosure, a trapezoid shape of the first supporting portion 231b may be provided at the center of the vibration part 231, and thus, a directivity may be enhanced toward a center of the vibration apparatus.

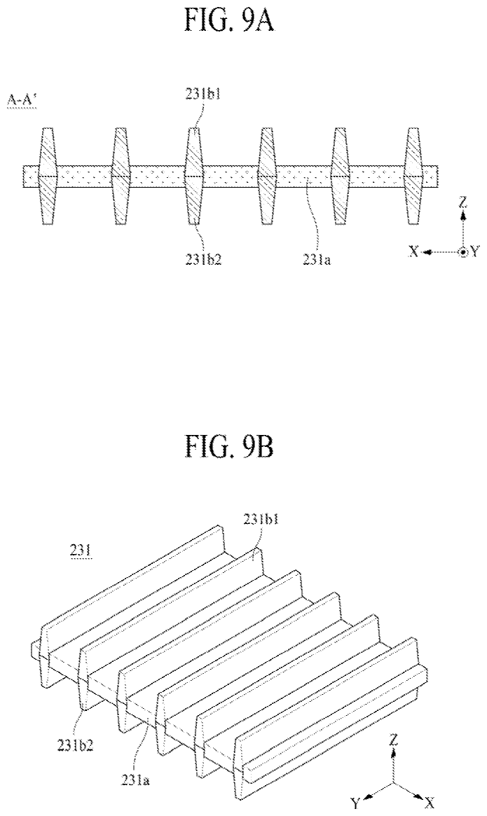

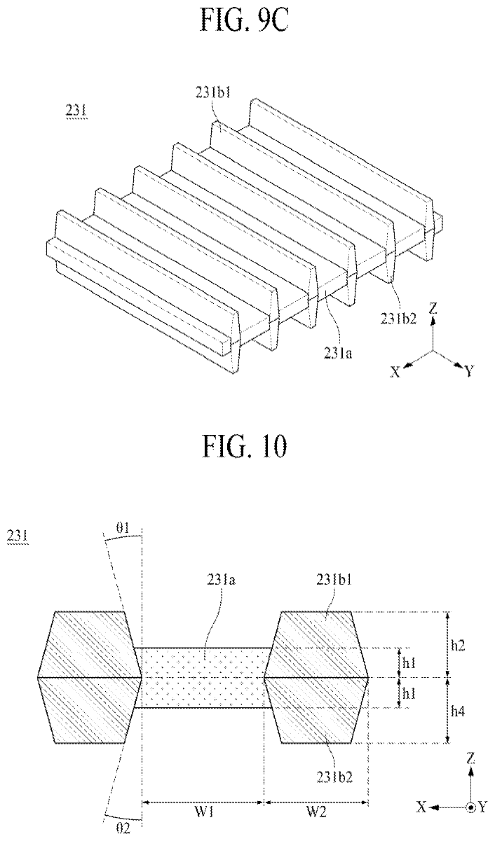

FIG. 9A is a plan view illustrating a vibration part according to another aspect of the present disclosure. FIG. 9B is another cross-sectional view taken along line A-A′ illustrated in FIG. 2A according to another aspect of the present disclosure. FIG. 9C is a lateral view illustrating a vibration part according to another aspect of the present disclosure. FIG. 10 illustrates a vibration part according to another aspect of the present disclosure.

The vibration part 231 may include a plurality of piezoelectric portions 231a and a plurality of supporting portions 231b and 231c. For example, the vibration part 231 may include a piezoelectric portion 231a, a first supporting portion 231b, and a second supporting portion 231c. Except for a shape of a supporting portion, descriptions of the piezoelectric portion 231a and the supporting portions 231b and 231c may be a same as the descriptions of FIGS. 2A to 3, and thus, may be omitted or may be briefly given.

With reference to FIGS. 8A to 8D, the piezoelectric portion 231a may include a first surface and a second surface which differs from the first surface. A first supporting portion 231b1 may be at the first surface of the piezoelectric portion 231a. A second supporting portion 231b2 may be at the second surface different from the first surface of the piezoelectric portion 231a. For example, with respect to a center of the piezoelectric portion 231a, the first supporting portion 231b1 may be at the first surface of the piezoelectric portion 231a, and the second supporting portion 231b2 may be at the second surface different from the first surface of the piezoelectric portion 231a. For example, with respect to the center of the piezoelectric portion 231a, the first supporting portion 231b1 may be symmetrical with the second supporting portion 231b2.

According to an aspect of the present disclosure, the vibration part 231 may include a plurality of regions. For example, the plurality of regions may be three regions. For example, the vibration part 231 may include a first region, a second region, and a third region between the first region and the second region. A plurality of first supporting portions 231b1 may be at one region or two regions of first to third regions. A plurality of second supporting portions 231b2 may be at one region or two regions of the first to third regions.

According to an aspect of the present disclosure, a shape of the piezoelectric portion 231a may differ from that of the first supporting portion 231b1 and/or that of the second supporting portion 231b2. For example, the shape of the first supporting portion 231b1 may be a same as that of the second supporting portion 231b2. For example, the shape of the first supporting portion 231b1 may be symmetrical with that of the second supporting portion 231b2 with respect to the center of the piezoelectric portion 231a. For example, the shape of the first supporting portion 231b1 and the shape of the second supporting portion 231b2 may each be a trapezoid shape. The vibration part 231 may have a horn structure at both sides of the vibration part 231 based on a shape of the first supporting portion 231b1 and the shape of the second supporting portion 231b2, and thus, a vibration device 230 or a vibration apparatus 200 for enhancing a directivity may be implemented. Because the vibration part 231 has the horn structure at the both sides of the vibration part 231 based on a shape of the first supporting portion 231b1 and a shape of the second supporting portion 231b2, and thus, the vibration device 230 or the vibration apparatus 200 where a directivity is high at the both sides of the vibration part 231 may be implemented. For example, the vibration part 231 may have a double side conical horn shape.

With reference to FIG. 10, a first angle θ1 may be an angle of horn guide configured by a trapezoid shape of the first supporting portion 231b1. Based on the horn guide or sound guide of the first supporting portion 231b1, a directivity of a sound may be enhanced. For example, the first angle θ1 may be 10 degrees to 30 degrees, but embodiments of the present disclosure are not limited thereto. For example, the first angle θ1 may be 10 degrees or more and 30 degrees or less, but embodiments of the present disclosure are not limited thereto. When the first angle θ1 is 10 degrees to 30 degrees or is 10 degrees or more and 30 degrees or less, a directivity characteristic of the vibration device 230 or the vibration apparatus 200 may be more enhanced by a sound guided in the first supporting portion 231b1. a first angle θ1 may be an angle of horn guide configured by a trapezoid shape of the second supporting portion 231b2. Based on the horn guide or sound guide of the second supporting portion 231b2, a directivity of a sound may be enhanced. For example, the second angle θ2 may be a same as that of the first angle θ1. For example, the second angle θ2 may be 10 degrees to 30 degrees, but embodiments of the present disclosure are not limited thereto. For example, the second angle θ2 may be 10 degrees or more and 30 degrees or less, but embodiments of the present disclosure are not limited thereto. When the second angle θ2 is 10 degrees to 30 degrees or is 10 degrees or more and 30 degrees or less, a directivity characteristic of the vibration device 230 or the vibration apparatus 200 may be more enhanced by a sound guided in the second supporting portion 231b2.

According to an aspect of the present disclosure, a height h2 of the first supporting portion 231b1 may differ from a height h1 of the piezoelectric portion 231a. Therefore, the first supporting portion 231b1 may perform horn or sound guide. For example, when the height h2 of the first supporting portion 231b1 differs from the height h1 of the piezoelectric portion 231a, a vibration apparatus having a shape having a directivity may be implemented according to sound guide based on the height of the first supporting portion 231b1. For example, the height h2 of the first supporting portion 231b1 may be higher than a height h1 of a first surface of the piezoelectric portion 231a with respect to a center of the piezoelectric portion 231a. For example, the height h2 of the first supporting portion 231b1 may be higher than the height h1 of the first surface of the piezoelectric portion 231a. For example, the height h1 of the first surface of the piezoelectric portion 231a may be 100 [symbol] to 1,000 [symbol] , but embodiments of the present disclosure are not limited thereto. The height h2 of the first supporting portion 231b1 may be 2 to 4 times the height h1 of the first surface of the piezoelectric portion 231a, but embodiments of the present disclosure are not limited thereto. For example, the height h2 of the first supporting portion 231b1 may be 200 [symbol] to 4,000 [symbol] , but embodiments of the present disclosure are not limited thereto. For example, the height h1 of the first surface of the piezoelectric portion 231a may be a thickness of the first surface of the piezoelectric portion 231a. For example, the height h2 of the first supporting portion 231b1 may be a thickness of the first supporting portion 231b1.

According to an aspect of the present disclosure, a height h4 of the second supporting portion 231b2 may differ from the height h1 of the piezoelectric portion 231a. Therefore, the second supporting portion 231b2 may perform horn or sound guide. For example, when the height h4 of the second supporting portion 231b2 differs from the height h1 of the piezoelectric portion 231a, a vibration apparatus having a shape having a directivity may be implemented according to sound guide based on a height of the second supporting portion 231b2. For example, the height h4 of the second supporting portion 231b2 may differ from a height h1 of a second surface of the piezoelectric portion 231a. For example, the second surface of the piezoelectric portion 231a may be a surface which is different from the first surface of the piezoelectric portion 231a. For example, the height h4 of the second supporting portion 231b2 may be higher than the height h1 of the second surface of the piezoelectric portion 231a. For example, the height h1 of the second surface of the piezoelectric portion 231a may be 100 [symbol] to 1,000 [symbol] , but embodiments of the present disclosure are not limited thereto. The height h4 of the second supporting portion 231b2 may be 2 to 4 times the height h1 of the second surface of the piezoelectric portion 231a, but embodiments of the present disclosure are not limited thereto. For example, the height h4 of the second supporting portion 231b2 may be 200 [symbol] to 4,000 [symbol] , but embodiments of the present disclosure are not limited thereto. For example, the height h4 of the second supporting portion 231b2 may be a thickness of the second supporting portion 231b2.

According to an aspect of the present disclosure, the piezoelectric portion 231a may include a first surface and a second surface which differs from the first surface. For example, the height of the first supporting portion 231b1 may be higher than one or more of the first surface and the second surface different from the first surface of the piezoelectric portion 231a. For example, the height of the second supporting portion 231b2 may be higher than one or more of the first surface and the second surface different from the first surface of the piezoelectric portion 231a.

According to an aspect of the present disclosure, the height h2 of the first supporting portion 231b1 may be configured to be equal to or different from the height h4 of the second supporting portion 231b2. For example, when the height h2 of the first supporting portion 231b1 differs from the height h4 of the second supporting portion 231b2, a vibration apparatus having a desired a directivity shape may be implemented. For example, when the height h2 of the first supporting portion 231b1 differs from the height h4 of the second supporting portion 231b2, a vibration apparatus having a directivity may be implemented according to sound guide based on the heights of the first supporting portion 231b1 and the second supporting portion 231b2. For example, when the height h2 of the first supporting portion 231b1 is equal to the height h4 of the second supporting portion 231b2, a vibration apparatus having a circular or oval shape having a directivity may be implemented. For example, when the height h2 of the first supporting portion 231b1 differs from the height h4 of the second supporting portion 231b2, a vibration apparatus having a directivity having a complicated shape or a multi-slit shape may be implemented.

According to an aspect of the present disclosure, a width W1 of the piezoelectric portion 231a may differ from a width W2 of the first supporting portion 231b1. For example, a width W1 of a lower surface of the piezoelectric portion 231a may differ from a width W2 of a lower surface of the first supporting portion 231b1. For example, the width W1 of the piezoelectric portion 231a may be greater than the width W2 of the first supporting portion 231b1. The width W1 of the piezoelectric portion 231a may vary based on a driving frequency. For example, in a region where the driving frequency is 100 kHz, the width W1 of the piezoelectric portion 231a may be at least 1 mm or more, but embodiments of the present disclosure are not limited thereto. The width W2 of the first supporting portion 231b1 may be 1/10 or less of the width W1 of the piezoelectric portion 231a, but the width W1 of the piezoelectric portion 231a may vary based on a flexible characteristic of a vibration apparatus. For example, the width W1 of the piezoelectric portion 231a may be 1 mm or more and 20 mm or less, but embodiments of the present disclosure are not limited thereto. For example, the width W2 of the first supporting portion 231b1 may be 0.1 mm or more and 2.0 mm or less, but embodiments of the present disclosure are not limited thereto.

According to an aspect of the present disclosure, a width W1 of the piezoelectric portion 231a may differ from a width W2 of the second supporting portion 231b2. For example, a width W1 of a lower surface of the piezoelectric portion 231a may differ from a width W2 of a lower surface of the second supporting portion 231b2. For example, the width W1 of the piezoelectric portion 231a may be greater than the width W2 of the second supporting portion 231b2. The width W1 of the piezoelectric portion 231a may vary based on a driving frequency. For example, in a region where the driving frequency is 100 kHz, the width W1 of the piezoelectric portion 231a may be at least 1 mm or more, but embodiments of the present disclosure are not limited thereto. The width W2 of the second supporting portion 231b2 may be 1/10 or less of the width W1 of the piezoelectric portion 231a, but the width W1 of the piezoelectric portion 231a may vary based on a flexible characteristic of a vibration apparatus. For example, the width W1 of the piezoelectric portion 231a may be 1 mm or more and 20 mm or less, but embodiments of the present disclosure are not limited thereto. For example, the width W2 of the second supporting portion 231b2 may be 0.1 mm or more and 2.0 mm or less, but embodiments of the present disclosure are not limited thereto.

According to an aspect of the present disclosure, a width W2 of the first supporting portion 231b1 may be configured to be equal to or different from a width W3 of the second supporting portion 231b2. For example, when the width W2 of the first supporting portion 231b1 differs from the width W3 of the second supporting portion 231b2, a directivity angle and/or vibration intensity may be adjusted at a desired position. The width W2 of the first supporting portion 231b1 and/or the width W3 of the second supporting portion 231b2 may be configured to be different from each other based on a shape of a directivity which is to be implemented. Accordingly, a vibration apparatus having a shape of a directivity to implement may be implemented.

Because the vibration apparatus according to an aspect of the present disclosure has the horn structure based on a shape of the first supporting portion 231b1 and a shape of the second supporting portion 231b2, the vibration apparatus may be a sound apparatus having a directivity, and a carrier frequency of the sound apparatus having a directivity may have 20 kHz or more and 100 kHz or less, but embodiments of the present disclosure are not limited thereto. For example, the carrier frequency may be a frequency of an ultrasound band, but embodiments of the present disclosure are not limited thereto. Accordingly, a vibration apparatus which may have a directivity and may drive an ultrasound region may be provided.

According to an aspect of the present disclosure, a vibration apparatus having a directivity may be implemented by first and second supporting portions 231b1 and 231b2 respectively formed at the first surface and the second surface different from the first surface of the piezoelectric portion 231a. For example, a vibration part 231 having a horn structure configured by a trapezoid shape of the first and second supporting portions 231b1 and 231b2 respectively formed at the first surface and the second surface different from the first surface of the piezoelectric portion 231a may be configured, and thus, a vibration apparatus having a directivity may be implemented by the sound guide of the horn structure. According to an aspect of the present disclosure, a vibration apparatus which has a directivity and is implemented through a simplified process may be implemented.

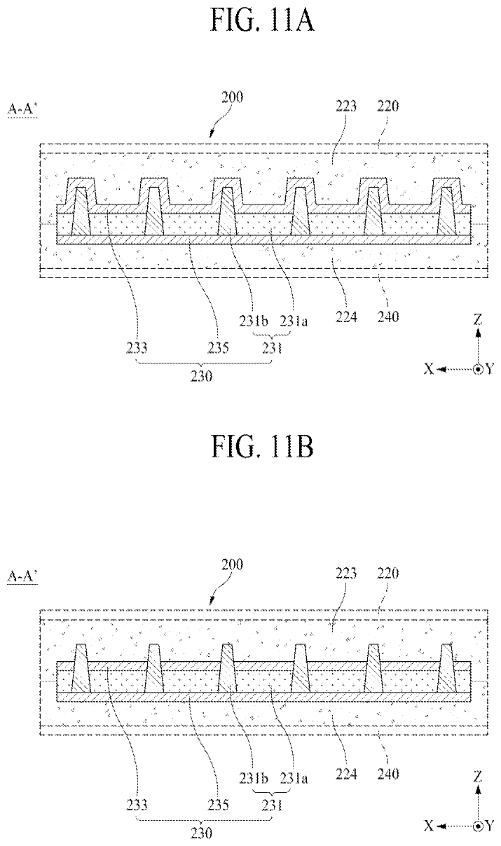

FIG. 11A is a cross-sectional view taken along line A-A′ illustrated in FIG. 2A according to an aspect of the present disclosure. FIG. 11B is another cross-sectional view taken along line A-A′ illustrated in FIG. 2A according to another aspect of the present disclosure.

Descriptions of a first electrode part 233 and a second electrode part 235 given with reference to FIGS. 11A and 11B may be identically applied to FIGS. 4A to 10.

With reference to FIGS. 11A and 11B, a vibration apparatus 200 according to an aspect of the present disclosure may include a vibration device 230. The vibration device 230 may include a vibration part 231, a first electrode part 233, and a second electrode part 235. The vibration part 231 may include a plurality of piezoelectric portions 231a and a plurality of supporting portions 231b.

With reference to FIG. 11A, the first electrode part 233 may be disposed at a first surface of each of the piezoelectric portion 231a and the supporting portion 231b. For example, the first electrode part 233 may be configured as one electrode at the first surface of each of the piezoelectric portion 231a and the supporting portion 231b. For example, the first electrode part 233 may be disposed along a shape of each of the piezoelectric portion 231a and the supporting portion 231b.

The second electrode part 235 may be disposed at a second surface different from the first surface of each of the piezoelectric portion 231a and the supporting portion 231b. For example, the second electrode part 235 may be configured as one electrode at the second surface of each of the piezoelectric portion 231a and the supporting portion 231b. For example, a same signal may be applied to the first electrode part 233 and the second electrode part 235. For example, a same signal may be simultaneously applied to the first electrode part 233 and the second electrode part 235.

According to an aspect of the present disclosure, the first electrode part 233 and the second electrode part 235 may be a parameteric array structure. Because the first electrode part 233 and the second electrode part 235 have the parameteric array structure, a directivity direction may be determined based on an installation direction of a vibration apparatus. Accordingly, a line-shaped vibration apparatus having sound collection properties may be provided.

According to an aspect of the present disclosure, the first electrode part 233 and the second electrode part 235 may be configured as one electrode, and thus, the process cost for forming the first electrode part 233 and the second electrode part 235 may be low.

A first adhesive layer 223 may be at the first electrode part 233. The first adhesive layer 223 may cover the first electrode part 233. A first protection member 220 may be at the first adhesive layer 223. For example, the first adhesive layer 223 may be between the first electrode part 233 and the first protection member 220. A second adhesive layer 224 may be at the second electrode part 235. The second adhesive layer 224 may cover the second electrode part 235. A second protection member 240 may be at the second adhesive layer 224. For example, the second adhesive layer 224 may be between the second electrode part 235 and the second protection member 240. For example, the vibration part 231, the first electrode part 233, and the second electrode part 235 may be embedded or built-in between the first adhesive layer 223 and the second adhesive layer 224.

With reference to FIG. 11B, the first electrode part 233 may be disposed at the first surface of each of the piezoelectric portion 231a and the supporting portion 231b. For example, the first electrode part 233 may be configured as an individual electrode at the first surface of each of the piezoelectric portion 231a and the supporting portion 231b.

The second electrode part 235 may be disposed at a second surface different from the first surface of each of the piezoelectric portion 231a and the supporting portion 231b. For example, the second electrode part 235 may be configured as one electrode at the second surface of each of the piezoelectric portion 231a and the supporting portion 231b. For example, frequencies of different signals may be applied to the first electrode part 233 and the second electrode part 235. For example, signals having different phases may be applied to the first electrode part 233 and the second electrode part 235.

According to an aspect of the present disclosure, the first electrode part 233 and the second electrode part 235 may be a phase array structure. Because the first electrode part 233 and the second electrode part 235 have the phase array structure, a direction of the directivity may be changed based on a signal applied to the first electrode part 233 and the second electrode part 235. Accordingly, a vibration apparatus having sound collection properties at a specific spot instead of a line shape may be provided.

A first adhesive layer 223 may be at the first electrode part 233. The first adhesive layer 223 may cover the first electrode part 233. A first protection member 220 may be at the first adhesive layer 223. For example, the first adhesive layer 223 may be between the first electrode part 233 and the first protection member 220. A second adhesive layer 224 may be at the second electrode part 235. The second adhesive layer 224 may cover the second electrode part 235. A second protection member 240 may be at the second adhesive layer 224. For example, the second adhesive layer 224 may be between the second electrode part 235 and the second protection member 240. For example, the vibration part 231, the first electrode part 233, and the second electrode part 235 may be embedded or built-in between the first adhesive layer 223 and the second adhesive layer 224.

FIG. 12A illustrates a vibration apparatus according to an experimental example. FIG. 12B illustrates a vibration apparatus according to another aspect of the present disclosure.

With reference to FIG. 12A, according to the experimental example, when a vibration apparatus where a supporting portion 231b and a piezoelectric portion 231a are on a same plane is configured in a curved shape, a range of destructive interference and/or constructive interference may be enlarged, and due to this, there may be a problem where it is difficult to allow an ultrasound to concentrate on a narrow region. For example, destructive interference and/or constructive interference between a first sound S1 in a piezoelectric portion 231a at a left periphery of the vibration apparatus and a second sound S2 in a piezoelectric portion 231a at a center of the vibration apparatus may occur and destructive interference and/or constructive interference between a third sound S3 in a piezoelectric portion 231a at a right periphery of the vibration apparatus and a fourth sound S4 in the piezoelectric portion 231a at the center of the vibration apparatus may occur, and due to this, a curved vibration apparatus according to the experimental example may be difficult to allow an ultrasound to concentrate on a narrow region. Moreover, in the curved vibration apparatus according to the experimental example, stress may concentrate on a specific portion (for example, the piezoelectric portion 231a), and due to this, a problem where the vibration apparatus is broken down may occur.

With reference to FIG. 12B, a vibration apparatus according to an aspect of the present disclosure may be configured so that a supporting portion 231b is disposed on a same plane as a piezoelectric portion 231a, and thus, a range of destructive interference and/or constructive interference may narrow, thereby allowing an ultrasound to easily concentrate on a narrow region. For example, in the vibration apparatus according to an aspect of the present disclosure, the supporting portion 231b may be configured in a trapezoid shape, and thus, a directivity may be enhanced and an ultrasound may be driven (or output). For example, the supporting portion 231b may decrease stress which concentrates on a specific portion (for example, the piezoelectric portion 231a), and thus, may solve a problem where the vibration apparatus is broken down, whereby the supporting portion 231b may be easily applied to a curved vibration apparatus. For example, destructive interference and/or constructive interference between the first sound S1 guided by a supporting portion 231b provided at a left periphery of the vibration apparatus and the second sound S2 guided by a supporting portion 231b provided at a center of the vibration apparatus may not occur, and thus, an ultrasound may concentrate. For example, destructive interference and/or constructive interference between a fourth sound S4 guided by a supporting portion 231b provided at a right periphery of the vibration apparatus and a third sound S3 guided by the supporting portion 231b provided at the center of the vibration apparatus may not occur, and thus, an ultrasound may concentrate. Accordingly, a vibration apparatus which may have a directivity and may drive an ultrasound region may be implemented. Also, when the supporting portion 231b is at the left periphery of the vibration apparatus and/or the right periphery of the vibration apparatus, a directivity may be more enhanced according to sound guide based on a height of the supporting portion 231b, thereby allowing an ultrasound to easily concentrate on the ultrasound region.

The vibration apparatus according to an aspect of the present disclosure may collect a sound in a desired direction, thereby providing a higher resolution in application fields such as Mid-Air haptic (or space haptic) or three-dimensional (3D)-haptic. The Mid-Air haptic (or the space haptic) may cause a tactile sense even without direct contact, and thus, may realize an effect such as contacting. For example, the Mid-Air haptic or the 3D-haptic may be technology which implements a realistic sense of a virtual shape in air and may provide the convenience of manipulation (or use) to a user by using a hovering touch technology which manipulates a screen without directly touching the screen. The description of FIG. 12B may be identically applied to FIGS. 4A to 10.

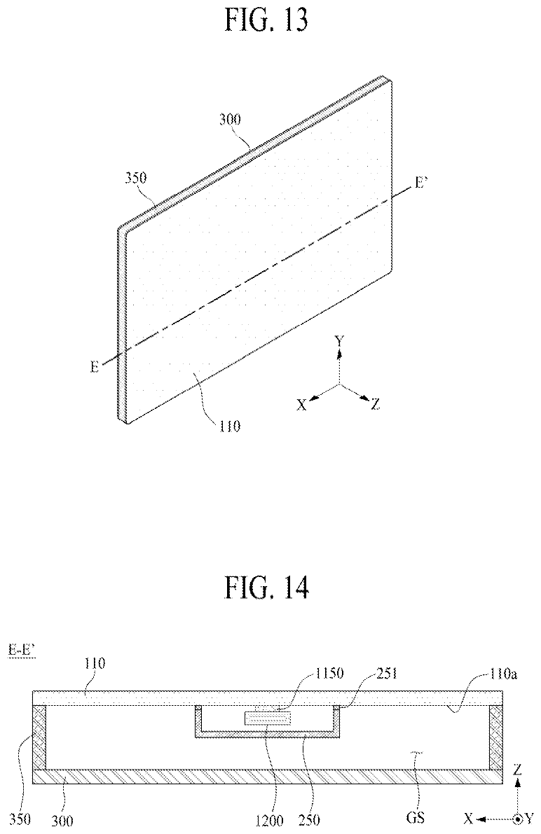

FIG. 13 illustrates an apparatus according to an aspect of the present disclosure. FIG. 14 is a cross-sectional view taken along line E-E′ illustrated in FIG. 13 according to an aspect of the present disclosure.

With reference to FIGS. 13 and 14, the apparatus according to an aspect of the present disclosure may include a passive vibration member 110 and one or more vibration generating apparatuses 1200.

The “apparatus” according to an aspect of the present disclosure may be applied to implement a display apparatus, a sound apparatus, a sound generating apparatus, a sound bar, an analog signage, or a digital signage or the like, but embodiments of the present disclosure are not limited thereto.

The display apparatus may include a display panel which includes a plurality of pixels for implementing a black/white or color image, and a driver for driving the display panel. The image according to an aspect of the present disclosure may include an electronic image, a digital image, a still image, or a video image or the like, but embodiments of the present disclosure are not limited thereto. For example, the display panel may be a liquid crystal display panel, an organic light emitting display panel, a light emitting diode display panel, an electrophoresis display panel, an electro-wetting display panel, a micro light emitting diode display panel, or a quantum dot light emitting display panel, or the like, but embodiments of the present disclosure are not limited thereto. For example, in the organic light emitting display panel, a pixel may include an organic light emitting device such as an organic light emitting layer or the like, and the pixel may be a subpixel which implements any one of a plurality of colors configuring a color image. Accordingly, the “apparatus” according to an aspect of the present disclosure may include a set electronic apparatus or a set device (or a set apparatus) such as a notebook computer, a television, a computer monitor, an equipment apparatus including an automotive apparatus or another type apparatus for vehicles, or a mobile electronic apparatus such as a smartphone or an electronic pad, or the like, which is a complete product (or a final product) including the display panel such as the liquid crystal display panel or the organic light emitting display panel, or the like. For example, the display apparatus according to an aspect of the present disclosure may be used as a display apparatus for mobile electronic devices such as mobile phones, smartphones, smart watches, tablet personal computers (PCs), or watch phones or the like, smart televisions, electronic whiteboards, bidirectional information transfer transparent displays, bidirectional digital signage, notebook computers, monitors, or refrigerators or the like, but embodiments of the present disclosure are not limited thereto.

The analog signage may be an advertising signboard, a poster, a noticeboard, or the like. The analog signage may include signage content such as a sentence, a picture, and a sign, or the like. The signage content may be disposed at the passive vibration member 110 of the apparatus to be visible. For example, the signage content may be directly attached on the passive vibration member 110 and the signage content may be printed or the like on a medium such as paper, and the medium may be attached on the passive vibration member 110.

The passive vibration member 110 may vibrate based on driving (or vibration) of the one or more vibration generating apparatuses 1200. For example, the passive vibration member 110 may generate one or more of a vibration and a sound based on driving of the one or more vibration generating apparatuses 1200.

The passive vibration member 110 according to an aspect of the present disclosure may be a display panel including a display area (or a screen) including a plurality of pixels which implement a black/white or color image. Therefore, the passive vibration member 110 may generate one or more of a vibration and a sound based on driving of the one or more vibration generating apparatuses 1200. For example, the passive vibration member 110 may vibrate based on driving of the vibration generating apparatus 1200 while displaying an image on the display area, thereby generating or outputting a sound synchronized with the image in the display area. For example, the passive vibration member 110 may be a vibration object, a display member, a display panel, a signage panel, a passive vibration plate, a front cover, a front member, a vibration panel, a sound panel, a passive vibration panel, a sound output plate, a sound vibration plate, or an image screen or the like, but embodiments of the present disclosure are not limited thereto.

The passive vibration member 110 according to another aspect of the present disclosure may be a vibration plate which includes a metal material or a nonmetal material or a composite nonmetal material having a material characteristic suitable to output sound. For example, the passive vibration member 110 may be a vibration plate which includes a metal material or a nonmetal material or a composite nonmetal material having a material characteristic suitable for being vibrated by the one or more vibration generating apparatuses 1200 to output sound. For example, the passive vibration member 110 may include one or more materials of metal, wood, rubber, plastic, glass, fiber, cloth, paper, a mirror, leather, and carbon. For example, the paper may be cone paper for speakers. For example, the cone paper may be pulp or foamed plastic, or the like, but embodiments of the present disclosure are not limited thereto.

The passive vibration member 110 according to another aspect of the present disclosure may include a display panel including a pixel which displays an image, or may include a non-display panel. For example, the passive vibration member 110 may include one or more among a display panel including a pixel displaying an image, a screen panel on which an image is projected from a display apparatus, a lighting panel, a signage panel, a vehicular interior material, a vehicular exterior material, a vehicular glass window, a vehicular seat interior material, a building ceiling material, a building interior material, a building glass window, an aircraft interior material, an aircraft glass window, and a mirror, but embodiments of the present disclosure are not limited thereto. For example, the non-display panel may be a light emitting diode lighting panel (or apparatus), an organic light emitting lighting panel (or apparatus), or an inorganic light emitting lighting panel (or apparatus), but embodiments of the present disclosure are not limited thereto.

The one or more vibration generating apparatuses 1200 may be configured to vibrate the passive vibration member 110. The one or more vibration generating apparatuses 1200 may be configured to be connected to a rear surface 110a of the passive vibration member 110 by a connection member 1150. Accordingly, the one or more vibration generating apparatuses 1200 may vibrate the passive vibration member 110 to generate or output one or more of a vibration and a sound based on a vibration of the passive vibration member 110. The rear surface 110a of the passive vibration member 110 may be a rearward surface, a backside surface, a backward surface, a bottom surface, or a lower surface, but embodiments of the present disclosure are not limited thereto

The one or more vibration generating apparatuses 1200 may include one or more of the vibration apparatus described above with reference to FIGS. 1 to 12B. Accordingly, descriptions of the vibration apparatus described above with reference to FIGS. 1 to 12B may be included in descriptions of the vibration generating apparatus 1200 illustrated in FIGS. 13 and 14, and thus, like reference numerals refer to like elements, and repeated descriptions may be omitted.

The connection member 1150 may be disposed between the vibration generating apparatus 1200 and the passive vibration member 110. The connection member 1150 may be disposed between at least a portion of the vibration generating apparatus 1200 and the passive vibration member 110. The connection member 1150 according to an aspect of the present disclosure may be connected between the passive vibration member 110 and a center portion, except a periphery portion, of the vibration generating apparatus 1200. For example, the connection member 1150 may be connected between the passive vibration member 110 and the center portion of the vibration generating apparatus 1200 based on a partial attachment scheme (or a local bonding scheme). The center portion (or a central portion) of the vibration generating apparatus 1200 may be a center of a vibration, and thus, a vibration of the vibration generating apparatus 1200 may be effectively transferred to the passive vibration member 110 through the connection member 1150. A periphery portion of the vibration generating apparatus 200 may be spaced apart from each of the connection member 1150 and the passive vibration member 110 and lifted without being connected to the connection member 1150 and/or the passive vibration member 110, and thus, in a flexural vibration (or a bending vibration) of the vibration generating apparatus 1200, a vibration of a periphery portion of the vibration generating apparatus 1200 may be prevented (or reduced) by the connection member 1150 and/or the passive vibration member 110, whereby a vibration amplitude (or a displacement amplitude) of the vibration generating apparatus 1200 may increase. Accordingly, a vibration amplitude (or a displacement amplitude) of the passive vibration member 110 based on a vibration of the vibration generating apparatus 1200 may increase, and thus, a sound characteristic and/or a sound pressure level characteristic of a low-pitched sound band generated based on a vibration of the passive vibration member 110 may be more enhanced.

The connection member 1150 according to another aspect of the present disclosure may be connected to or attached on an entire front surface of each of the one or more vibration generating apparatuses 1200 and the rear surface 110a of the passive vibration member 110 based on an entire surface attachment scheme (or an entire surface bonding scheme).

The connection member 1150 according to an aspect of the present disclosure may be configured as a material including an adhesive layer which is good in adhesive force or attaching force with respect to each of the one or more vibration generating apparatuses 1200 and a rear surface of the display panel or a rear surface 110a of the passive vibration member 110. For example, the connection member 1150 may include an adhesive, a double-sided tape, a single-sided tape, a double-sided adhesive, a single-sided adhesive, a double-sided foam tape, a single-sided foam tape, a single-sided cushion tape, a double-sided cushion tape, a double-sided adhesive foam pad, or a single-sided adhesive foam pad, or the like, but embodiments of the present disclosure are limited thereto. For example, the adhesive layer of the connection member 1150 may include epoxy, acrylic, silicone, or urethane, but embodiments of the present disclosure are not limited thereto. For example, the adhesive layer of the connection member 1150 may include an acrylic-based a material (or a substance) having a characteristic where an adhesive force is relatively better and hardness is higher than the urethane material. Accordingly, the transmission efficiency of a vibration transmitted from the one or more vibration generating apparatuses 1200 to the passive vibration member 110 may be increased.

The apparatus according to an aspect of the present disclosure may further include a supporting member 300 and a coupling member 350.

The supporting member 300 may be disposed at the rear surface 110a of the passive vibration member 110. The supporting member 300 may be disposed at the rear surface 110a of the passive vibration member 110 to cover the one or more vibration generating apparatuses 1200. The supporting member 300 may be disposed at the rear surface 110a of the passive vibration member 110 to cover all of the rear surface 110a of the passive vibration member 110 and the one or more vibration generating apparatuses 1200. For example, the supporting member 300 may have a same size as the passive vibration member 110. For example, the supporting member 300 may cover the rear surface of the passive vibration member 110 with a gap space GS and the one or more vibration generating apparatuses 1200 therebetween. For example, the supporting member 300 may cover an entire rear surface of the passive vibration member 110 with a gap space GS and the one or more vibration generating apparatuses 1200 therebetween. The gap space GS may be provided by the coupling member 350 disposed between the passive vibration member 110 and the supporting member 300 facing each other. The gap space GS may be referred to as an air gap, an accommodating space, a vibration space, or a sound sounding box, but embodiments of the present disclosure are not limited thereto.

The supporting member 300 may include any one material of a glass material, a metal material, and a plastic material, but embodiments of the present disclosure are not limited thereto. For example, the supporting member 300 may include a stacked structure in which one or more of a glass material, a plastic material, and a metal material is stacked thereof, but embodiments of the present disclosure are not limited thereto.

Each of the passive vibration member 110 and the supporting member 300 may have a square shape or a rectangular shape, but embodiments of the present disclosure are not limited thereto. For example, each of the passive vibration member 110 and the supporting member 300 may have a polygonal shape, a non-polygonal shape, a circular shape, or an oval shape. For example, when the apparatus according to an aspect of the present disclosure is applied to a sound apparatus or a sound bar, each of the passive vibration member 110 and the supporting member 300 may have a rectangular shape where a length of a long side is twice or more times longer than a short side, but embodiments of the present disclosure are not limited thereto.

The coupling member 350 may be configured to be connected between a rear periphery portion of the passive vibration member 100 and a front periphery portion of the supporting member 300, and thus, the gap space GS may be provided between the passive vibration member 100 and the supporting member 300 facing each other.

The coupling member 350 according to an aspect of the present disclosure may include an elastic material which has adhesive properties and is capable of compression and decompression. For example, the coupling member 350 may include an adhesive, a double-sided tape, a single-sided tape, a double-sided adhesive, a single-sided adhesive, a double-sided foam tape, a single-sided foam tape, a single-sided cushion tape, a double-sided cushion tape, a double-sided adhesive foam pad, or a single-sided adhesive foam pad, or the like, but embodiments of the present disclosure are limited thereto. For example, the coupling member 350 may include an elastic pad such as a rubber pad or a silicone pad, or the like, which has adhesive properties and is capable of compression and decompression. For example, the coupling member 350 may be formed by elastomer.

According to another aspect of the present disclosure, the supporting member 300 may further include a sidewall part which supports a rear periphery portion of the passive vibration member 100. The sidewall part of the supporting member 300 may protrude or be bent toward the rear periphery portion of the passive vibration member 110 from the front periphery portion of the supporting member 300, and thus, the gap space GS may be provided between the passive vibration member 110 and the supporting member 300. For example, the coupling member 350 may be configured to be connected between the sidewall part of the supporting member 300 and the rear periphery portion of the passive vibration member 100. Accordingly, the supporting member 300 may cover the one or more vibration generating apparatuses 1200 and may support the rear surface 110a of the passive vibration member 110. For example, the supporting member 300 may cover the one or more vibration generating apparatuses 1200 and may support the rear periphery portion of the passive vibration member 110.

Another for example, the passive vibration member 100 may further include a sidewall part which is connected to a front periphery portion of the supporting member 300. The sidewall part of the passive vibration member 100 may protrude or be bent toward the front periphery portion of the supporting member 300 from the rear periphery portion of the passive vibration member 100, and thus, the gap space GS may be provided between the passive vibration member 100 and the supporting member 300. A stiffness of the passive vibration member 100 may be increased based on the sidewall part. For example, the coupling member 350 may be configured to be connected between the sidewall part of the passive vibration member 100 and the front periphery portion of the supporting member 300. Accordingly, the supporting member 300 may cover the one or more vibration generating apparatuses 200 and may support the rear surface 100a of the passive vibration member 100. For example, the supporting member 300 may cover the one or more vibration generating apparatuses 200 and may support the rear periphery portion of the passive vibration member 100.

The apparatus according to an aspect of the present disclosure may further include one or more enclosure 250.

The enclosure 250 may be disposed at the rear surface 110a of the passive vibration member 110. The enclosure 250 may cover the one or more vibration generating apparatuses 200. For example, the enclosure 250 may be connected or coupled to the rear periphery portion of the passive vibration member 110 to individually cover the one or more vibration generating apparatuses 200. For example, the enclosure 250 may be connected or coupled to the rear surface 110a of the passive vibration member 110 by a coupling member 251. The enclosure 250 may configure a closed space which covers or surrounds the one or more vibration generating apparatuses 1200 at the rear surface 100a of the passive vibration member 110. For example, the enclosure 250 may be a case, an outer case, a case member, a housing member, a cabinet, a closed member, a closed cap, a closed box, or a sound box, but embodiments of the present disclosure are not limited thereto. The closed space may be an air gap, a vibration space, a sound space, or a sound sounding box, but embodiments of the present disclosure are not limited thereto.

The coupling member 251 according to an aspect of the present disclosure may be configured as a material including an adhesive layer which is good in adhesive force or attaching force with respect to each of the enclosure 250 and a rear surface of the display panel or a rear surface 110a of the passive vibration member 110. For example, the coupling member 251 may include an adhesive, a double-sided tape, a single-sided tape, a double-sided adhesive, a single-sided adhesive, a double-sided foam tape, a single-sided foam tape, a single-sided cushion tape, a double-sided cushion tape, a double-sided adhesive foam pad, or a single-sided adhesive foam pad, or the like, but embodiments of the present disclosure are limited thereto. For example, the adhesive layer of the coupling member 251 may include epoxy, acrylic, silicone, or urethane, but embodiments of the present disclosure are not limited thereto.

The enclosure 250 may include one or more materials of a metal material, a nonmetal material, and a composite nonmetal material. For example, the enclosure 250 may include one or more materials of a metal, plastic, carbon, and wood, but embodiments of the present disclosure are not limited thereto.

The enclosure 250 according to an aspect of the present disclosure may maintain an impedance component based on air acting on the passive vibration member 110 when the passive vibration member 110 or the vibration generating apparatus 1200 is vibrating. For example, air around the passive vibration member 110 may resist a vibration of the passive vibration member 110 and may act as an impedance component having a reactance component and a resistance based on a frequency. Therefore, the enclosure 250 may configure a closed space which surrounds the one or more vibration generating apparatuses 200, in the rear surface 110a of the passive vibration member 110, and thus, may maintain an impedance component (or an air impedance or an elastic impedance) acting on the passive vibration member 110 based on air, thereby enhancing a sound characteristic and/or a sound pressure level characteristic of the low-pitched sound band and enhancing the quality of a sound of a high-pitched sound band.

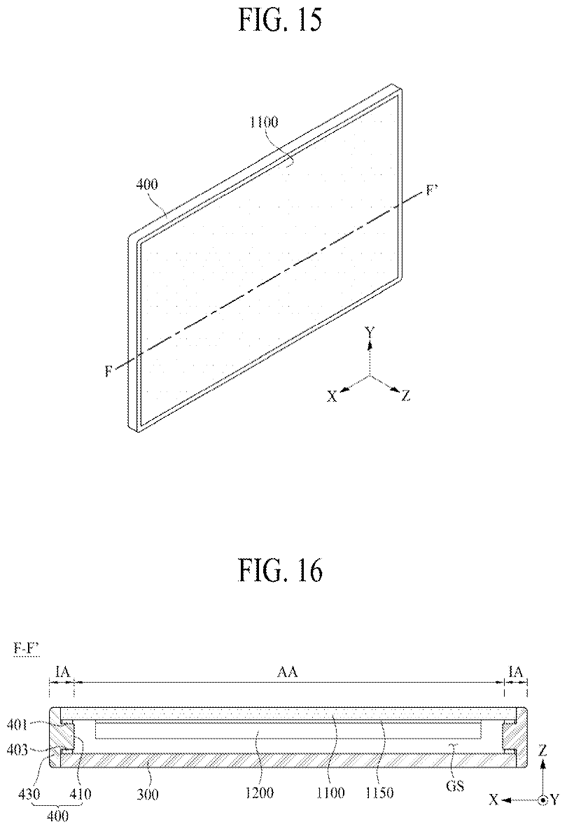

FIG. 15 illustrates an apparatus according to another aspect of the present disclosure. FIG. 16 is a cross-sectional view taken along line F-F′ illustrated in FIG. 15 according to another aspect of the present disclosure.

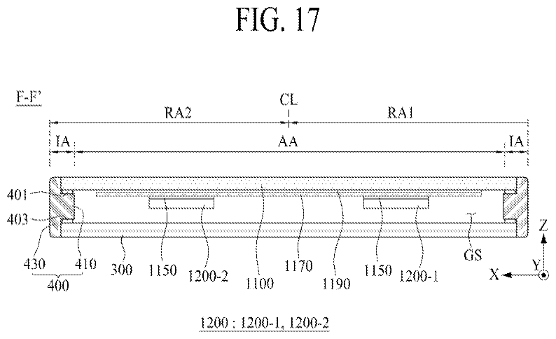

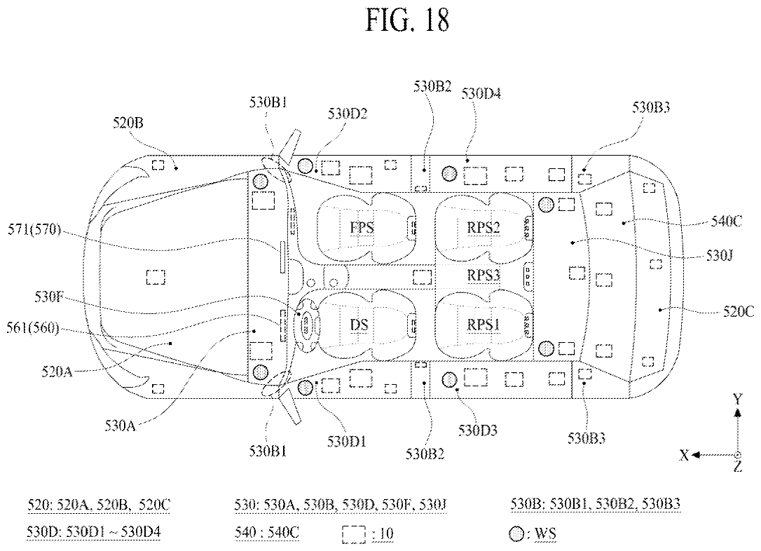

With reference to FIGS. 17 and 18, an apparatus (or a display apparatus) according to an aspect of the present disclosure may include a display panel (or a vibration object) 1100 to display an image, and a vibration generating apparatus 1200 which vibrates the display panel 1100 at a rear surface (or a backside surface) of the display panel 1100.

The display panel 1100 may display an image, for example, an electronic image, a digital image, a still image, or a video image, or the like, but embodiments of the present disclosure are not limited thereto. For example, the display panel 1100 may output light to display an image. The display panel 1100 may be a curved display panel, or may be any type of display panel, such as a liquid crystal display panel, an organic light-emitting display panel, a quantum dot light-emitting display panel, a micro light-emitting diode display panel, and an electrophoresis display panel, or the like. The display panel 1100 may be a flexible display panel. For example, the display panel 1100 may be a flexible light emitting display panel, a flexible electrophoretic display panel, a flexible electro-wetting display panel, a flexible micro light emitting diode display panel, or a flexible quantum dot light emitting display panel, but embodiments of the present disclosure are not limited thereto.

The display panel 1100 according to an aspect of the present disclosure may include a display area AA for displaying an image according to driving of the plurality of pixels. The display panel 1100 may include a non-display area IA surrounding the display area AA, but embodiments of the present disclosure are not limited thereto.

The display panel 1100 according to an aspect of the present disclosure may include a pixel array part disposed on the display area AA of a substrate. The pixel array part may include a plurality of pixels which display an image based on a signal supplied through signal lines. The signal lines may include a gate line, a data line, a pixel driving power line, or the like, but embodiments of the present disclosure are not limited thereto.

Each of the plurality of pixels may include a pixel circuit layer including a driving thin film transistor (TFT) provided at a pixel area configured by a plurality of gate lines and/or a plurality of data lines, a first electrode (or a pixel electrode) electrically connected to the driving TFT, a light emitting device formed over the first electrode, and a second electrode (or a common electrode) electrically connected to the light emitting device.

The light emitting device according to an aspect may include an organic light emitting device layer formed over the first electrode. The organic light emitting device layer may be implemented to emit light having the same color (for example, white light or blue light) for each pixel, or may be implemented to emit light having a different color (for example, red light, green light, or blue light) for each pixel. Another for example, the light emitting device may be an inorganic light emitting layer (for example, a nano-sized material layer) and/or a quantum dot light emitting layer, or the like, but embodiments of the present disclosure are not limited thereto.

The light emitting device according to another aspect of the present disclosure may include a micro light emitting diode device electrically connected to each of the first electrode and the second electrode. The micro light emitting diode device may be a light emitting diode implemented as an integrated circuit (IC) or chip type. The micro light emitting diode device may include a first terminal electrically connected to the first electrode of the light emitting device and a second terminal electrically connected to the second electrode of the light emitting device.

The display panel 1100 according to an aspect of the present disclosure may include a first substrate, a second substrate, and a liquid crystal layer. The first substrate may be an upper substrate or a thin film transistor (TFT) array substrate. For example, the first substrate may include a pixel array including a plurality of pixels which are respectively provided in a plurality of pixel areas defined by intersections between a plurality of gate lines and/or a plurality of data lines. Each of the plurality of pixels may include a TFT connected to a gate line and/or a data line, a pixel electrode connected to the TFT, and a common electrode which is provided adjacent to the pixel electrode and is supplied with a common voltage. The second substrate may be a lower substrate or a color filter array substrate. For example, the second substrate may include a pixel opening pattern including an opening area overlapping with the pixel area formed at the first substrate, and a color filter layer formed at the opening area. The liquid crystal layer may be disposed between the first substrate and the second substrate. The liquid crystal layer may include a liquid crystal including liquid crystal molecules where an alignment direction thereof is changed based on an electric field generated by the common voltage and a data voltage applied to a pixel electrode for each pixel.

The vibration generating apparatus 1200 may vibrate the display panel 1100 at the rear surface of the display panel 1100, thereby providing a sound and/or a haptic feedback based on the vibration of the display panel 1100 to a user. The vibration generating apparatus 1200 may be implemented at the rear surface of the display panel 1100 to directly vibrate the display panel 1100.

According to an aspect of the present disclosure, the vibration generating apparatus 1200 may vibrate according to a vibration driving signal synchronized with an image displayed on the display panel 1100 to vibrate the display panel 1100. As another aspect of the present disclosure, the vibration generating apparatus 1200 may vibrate according to a haptic feedback signal (or a tactile feedback signal) synchronized with a user touch applied to a touch panel (or a touch sensor layer) which is disposed over the display panel 1100 or embedded into the display panel 1100 and may vibrate the display panel 1100. Accordingly, the display panel 1100 may vibrate based on a vibration of the vibration generating apparatus 1200 to provide a user (or a viewer) with at least one or more of a sound and a haptic feedback.

The vibration generating apparatus 1200 according to an aspect of the present disclosure may be implemented to have a size corresponding to the display area AA of the display panel 1100. A size of the vibration generating apparatus 1200 may be 0.9 to 1.1 times a size of the display area AA, but embodiments of the present disclosure are not limited thereto. For example, a size of the vibration generating apparatus 1200 may be a same as or smaller than the size of the display area AA. For example, a size of the vibration generating apparatus 1200 may be a same as or approximately a same as the display area AA of the display panel 1100, and thus, the vibration generating apparatus 1200 may cover a most region of the display panel 1100 and a vibration generated by the vibration generating apparatus 1200 may vibrate a whole portion of the display panel 1100, and thus, localization of a sound may be high, and satisfaction of a user may be improved. Moreover, a contact area (or panel coverage) between the display panel 1100 and the vibration generating apparatus 1200 may increase, and thus, a vibration region of the display panel 1100 may increase, thereby improving a sound of a middle-low-pitched sound band generated based on a vibration of the display panel 1100. Furthermore, a vibration generating apparatus 1200 applied to a large-sized display apparatus may vibrate the whole display panel 1100 having a large size (or a large area), and thus, localization of a sound based on a vibration of the display panel 1100 may be further enhanced, thereby realizing an improved sound effect.

The vibration generating apparatus 1200 according to an aspect of the present disclosure may include one or more of the vibration apparatus described above with reference to FIGS. 1 to 12B, and thus, repeated descriptions are omitted.

The apparatus according to an aspect of the present disclosure may further include a connection member 1150 disposed between the display panel 1100 and the vibration generating apparatus 1200.

The connection member 1150 may be disposed between the display panel 1100 and the vibration generating apparatus 1200, and thus, may connect or couple the vibration generating apparatus 1200 to the rear surface of the display panel 1100. For example, the vibration generating apparatus 1200 may be directly connected or coupled to the rear surface of the display panel 1100 by using the connection member 1150, and thus, may be supported by or disposed at the rear surface of the display panel 1100.

The connection member 1150 according to an aspect of the present disclosure may be configured as a material including an adhesive layer which is good in adhesive force or attaching force with respect to each of the vibration generating apparatus 1200 and a rear surface of the display panel. For example, the connection member 1150 may include an adhesive, a double-sided tape, a single-sided tape, a double-sided adhesive, a single-sided adhesive, a double-sided foam tape, a single-sided foam tape, a single-sided cushion tape, a double-sided cushion tape, a double-sided adhesive foam pad, or a single-sided adhesive foam pad, or the like, but embodiments of the present disclosure are limited thereto. For example, the adhesive layer of the connection member 1150 may include epoxy, acrylic, silicone, or urethane, but embodiments of the present disclosure are not limited thereto. For example, the adhesive layer of the connection member 1150 may include an acrylic-based a material (or a substance) having a characteristic where an adhesive force is relatively better and hardness is higher than the urethane material. Accordingly, the transmission efficiency of a vibration transmitted from the vibration generating apparatus 1200 to the display panel 1100 may be increased.

The connection member 1150 according to another aspect of the present disclosure may further include a hollow portion provided between the display panel 1100 and the vibration generating apparatus 1200. The hollow portion of the connection member 1150 may provide an air gap between the display panel 1100 and the vibration generating apparatus 1200. Due to the air gap, a sound wave (or a sound pressure) based on a vibration of the vibration generating apparatus 1200 may not be dispersed by the connection member 1150, and may concentrate on the display panel 1100. Thus, the loss of a vibration caused by the connection member 1150 may be minimized, thereby increasing a sound pressure level characteristic of a sound generated based on a vibration of the display panel 1100.

The apparatus according to an aspect of the present disclosure may further include a supporting member 300 disposed at a rear surface of the display panel 1100.

The supporting member 300 may cover a rear surface of the display panel 1100. For example, the supporting member 300 may cover an entire rear surface of the display panel 1100 with a gap space GS therebetween. For example, the supporting member 300 may include at least one or more material of a glass material, a metal material, and a plastic material, but embodiments of the present disclosure are not limited thereto. For example, the supporting member 300 may be a rear surface structure, a set structure, a cover bottom, or a back cover, but embodiments of the present disclosure are not limited thereto.

The apparatus according to an aspect of the present disclosure may further include a middle frame 400.

The middle frame 400 may be disposed between a rear periphery portion of display panel 1100 and a front periphery portion of the supporting member 300. The middle frame 400 may support one or more of the rear periphery portion of the display panel 1100 and the front periphery portion of the supporting member 300 and may surround one or more of side surfaces of each of the display panel 1100 and the supporting member 300. The middle frame 400 may provide a gap space GS between the display panel 1100 and the supporting member 300. The middle frame 400 may be a middle cabinet, a middle cover, or a middle chassis, or the like, but embodiments of the present disclosure are not limited thereto.

The middle frame 400 according to an aspect of the present disclosure may include a first supporting portion 410 and a second supporting portion 430.

The first supporting portion 410 may be disposed between the rear periphery portion of the display panel 1100 and the front periphery portion of the supporting member 300, and thus, may provide the gap space GS between the display panel 1100 and the supporting member 300. A front surface of the first supporting portion 410 may be coupled or connected to the rear periphery portion of the display panel 1100 by a first connection member 401. A rear surface of the first supporting portion 410 may be coupled or connected to the front periphery portion of the supporting member 300 by a second connection member 403. For example, the first supporting portion 410 may have a single picture frame structure having a square shape or a frame structure having a plurality of divided bar shapes.

The second supporting portion 430 may be vertically coupled to an outer surface of the first supporting portion 410 in parallel with a thickness direction Z of the apparatus. The second supporting portion 430 may surround one or more of an outer surface of the display panel 1100 and an outer surface of the supporting member 300, thereby protecting the outer surface of each of the display panel 1100 and the supporting member 300. The first supporting portion 410 may protrude from an inner surface of the second supporting portion 430 toward the gap space GS between the display panel 100 and the support member 300.

According to an aspect of the present disclosure, the middle frame 400 may be coupled or connected to the rear periphery portion of the display panel 1100 by the first connection member 401. The middle frame 400 may be coupled or connected to the front periphery portion of the supporting member 300 by the second connection member 403.

The apparatus according to an aspect of the present disclosure may include a connection member (or a panel connection member) instead of the middle frame 400. The connection member may be disposed between the rear periphery portion of the display panel 1100 and the front periphery portion of the supporting member 300 and may provide the gap space GS between the display panel 1100 and the supporting member 300. The connection member may be disposed between the rear periphery portion of the display panel 1100 and the front periphery portion of the supporting member 300 to adhere the display panel 1100 and the support member 300. For example, the connection member (or the panel connection member) may be implemented as an adhesive, a double-sided adhesive, a single-sided adhesive, a double-sided tape, a single-sided tape, a double-sided foam tape, a single-sided foam tape, a single-sided cushion tape, a double-sided cushion tape, a single-sided adhesive foam pad, or a double-sided adhesive foam pad, but embodiments of the present disclosure are limited thereto. For example, an adhesive layer of the connection member may include epoxy, acrylic, silicone, or urethane, but embodiments of the present disclosure are not limited thereto.

In the apparatus according to an aspect of the present disclosure, when the apparatus includes the connection member (or the panel connection member) instead of a middle frame 400, the supporting member 300 may include a bending sidewall which surrounds an outer surface (or an outer sidewall) of the display panel 1100. The bending sidewall may be bent from an end (or an end portion) of the supporting member 300 to surround an outer surface (or an outer sidewall) of the display panel 1100 and the connection member (or the panel connection member). The bending sidewall according to an aspect of the present disclosure may have a single sidewall structure or a hemming structure. The hemming structure may be a structure where end portions of an arbitrary member are bent in a curve shape and overlap each other or are spaced apart from each other in parallel. For example, to enhance a sense of beauty in design, the bending sidewall may include a first bending sidewall, bent from one side (or an end) of the supporting member 300, and a second bending sidewall bent from the first bending sidewall to a region between the first bending sidewall and an outer surface of the display panel 1100. The second bending sidewall may be spaced apart from an inner surface of the first bending sidewall. Therefore, the second bending sidewall may prevent (or minimize) the outer surface of the display panel 1100 from contacting an inner surface of the first bending sidewall or may prevent a lateral-direction external impact from being transferred to the outer surface of the display panel 1100.

The apparatus (or the display apparatus) according to an aspect of the present disclosure may output a sound, generated by a vibration of the display panel 1100 based on a vibration of the vibration generating apparatus 1200 which is disposed at the rear of the display panel 1100, in a forward region in front of the display panel 1100.

In FIGS. 15 and 16, although it has been described that the vibration generating apparatus 1200 vibrates the display panel 1100 to generate or output sound, the embodiments of the present disclosure are not limited thereto. For example, the vibration generating apparatus 1200 may vibrate other vibration member (or other vibration object) other than the display panel 1100 of the vibration member (or vibration object) described above, to generate or output a sound.

FIG. 17 is another cross-sectional view taken along line F-F′ illustrated in FIG. 15 according to another aspect of the present disclosure. FIG. 17 illustrates an aspect implemented by modifying a vibration generating apparatus illustrated in FIG. 15. Therefore, in the following description, repeated descriptions of elements other than the vibration generating apparatus and elements relevant thereto may be omitted or will be briefly given.

With reference to FIGS. 15 and 17, in the apparatus according to another aspect of the present disclosure, a display panel 1100 may include a first rear region RA1 and a second rear region RA2. For example, the first rear region RA1 may be a right rear region of the display panel 1100, and the second rear region RA2 may be a left rear region of the display panel 1100. The first and second rear regions RA1 and RA2 may be a left-right symmetrical in a center line CL of the display panel 1100 with respect to a first direction X, but embodiments of the present disclosure are not limited thereto. For example, each of the first and second rear regions RA1 and RA2 may overlap the display area AA of the display panel 1100.

The vibration generating apparatus 1200 according to another aspect of the present disclosure may include a first vibration generating apparatus 1200-1 and a second vibration generating apparatus 1200-2.

The first vibration generating apparatus 1200-1 may be disposed at the first rear region RA1 of the display panel 1100. The first vibration generating apparatus 1200-1 may have a same size as the first rear area RA1 of the display panel 1100 or may have a size smaller than the first rear area RA1 of the display panel 1100 based on a characteristic of a first sound or a sound characteristic needed for the apparatus. For example, the first vibration generating apparatus 1200-1 may be disposed close to a center or a periphery within the first rear region RA1 of the display panel 1100 with respect to the first direction X.

According to an aspect of the present disclosure, the first vibration generating apparatus 1200-1 may vibrate the first rear region RA1 of the display panel 1100, and thus, may generate the first sound of at least one of a first vibration sound, a first directivity vibration sound, and a first haptic feedback at the first rear region RA1 of the display panel 1100. For example, the first vibration generating apparatus 1200-1 may directly vibrate the first rear region RA1 of the display panel 1100, and thus, may generate the first sound in the first rear region RA1 of the display panel 1100. For example, the first sound may be a right sound.

The second vibration generating apparatus 1200-2 may be disposed at the second rear region RA2 of the display panel 1100. The second vibration generating apparatus 1200-2 may have a same size as the second rear area RA2 of the display panel 1100 or may have a size smaller than the second rear area RA2 of the display panel 1100 based on a characteristic of the second sound or the sound characteristic needed for the apparatus. For example, the second vibration generating apparatus 1200-2 may be disposed close to a center or a periphery within the second rear region RA2 of the display panel 1100 with respect to the first direction X.

According to an aspect of the present disclosure, the second vibration generating apparatus 1200-2 may vibrate the second rear region RA2 of the display panel 1100, and thus, may generate the second sound of at least one of a second vibration sound, a second directivity vibration sound, and a second haptic feedback at the second rear region RA2 of the display panel 1100. For example, the second vibration generating apparatus 1200-2 may directly vibrate the second rear region RA2 of the display panel 1100, and thus, may generate the second sound in the second rear region RA2 of the display panel 1100. For example, the second sound may be a left sound.

The first and second vibration generating apparatuses 1200-1 and 1200-2 may have a same size or different sizes to each other based on a sound characteristic of left and right sounds and/or a sound characteristic of the apparatus. Moreover, the first and second vibration generating apparatuses 1200-1 and 1200-2 may be disposed in a left-right symmetrical structure or a left-right asymmetrical structure with respect to the center line CL of the display panel 1100.

Each of the first vibration generating apparatus 1200-1 and the second vibration generating apparatus 1200-2 may include one or more of the vibration apparatus described above with reference to FIGS. 1 to 12B, and thus, repeated descriptions may be omitted.

Each of the first vibration generating apparatus 1200-1 and the second vibration generating apparatus 1200-2 may disposed at the rear surface of the display panel 1100 by the connection member 1150. The connection member 1150 may be substantially the same as the connection member 1150 described above with reference to FIG. 16, and thus, repeated descriptions may be omitted.

The apparatus (or a display apparatus) according to another aspect of the present disclosure may output a left sound and a right sound to a forward region in front of the display panel 1100 through the first vibration generating apparatus 1200-1 and the second vibration generating apparatus 1200-2.

The apparatus according to another aspect of the present disclosure may further include a plate 1170 which is disposed between the display panel 1100 and the vibration generating apparatus 1200.

The plate 1170 may have the same shape and size as the rear surface of the display panel 1100, or may have a same shape and size as the vibration generating apparatus 1200. As another aspect of the present disclosure, the size of the plate 1170 may have a size different from the display panel 1100. For example, the plate 1170 may be smaller than the size of the display panel 1100. As another aspect of the present disclosure, the plate 1170 may have a size different from the vibration generating apparatus 1200. For example, the size of the plate 1170 may be greater or smaller than the size of the vibration generating apparatus 1200. The size of the vibration generating apparatus 1200 may be a same as or smaller than the size of the display panel 1100.

The plate 1170 may be connected or coupled to rear surface of the display panel 1100 by a plate coupling member (or a coupling member) 1190. Thus, the vibration generating apparatus 1200 may be connected or coupled to a rear surface of the plate 1170 by the connection member 1150, and thus, may be supported by or hung at the rear surface of the plate 1170.

The plate 1170 according to an aspect of the present disclosure may include a plurality of opening portions. The plurality of opening portions may be configured to have a predetermined size and a predetermined interval. For example, the plurality of opening portions may be formed along a first direction X and a second direction Y to have a predetermined size and a predetermined interval. Due to the plurality of opening portions, a sound wave (or a sound pressure level) based on a vibration of the vibration generating apparatus 1200 may not be dispersed by the plate 1170, and may concentrate on the display panel 1100. Thus, the loss of a vibration caused by the plate 1170 may be minimized, thereby increasing a sound pressure level characteristic of a sound generated based on a vibration of the display panel 1100. For example, the plate 1170 including the plurality of openings may have a mesh shape. For example, the plate 1170 including the plurality of openings may be a mesh plate.

The plate 1170 according to an aspect of the present disclosure may include a metal material. For example, the plate 1170 may include any one or more materials of stainless steel, a magnesium (Mg), aluminum (Al), a magnesium (Mg) alloy, a magnesium-lithium (Mg—Li) alloy, and an Al alloy, but embodiments of the present disclosure are not limited thereto. Another for example, the plate 1170 may be a heat plate that dissipates heat occurring in the display panel 1100. Another for example, the plate 1170 may be a heat plate that dissipates heat occurring when the vibration generating device 1200 is driven.

According to an aspect of the present disclosure, the plate 1170 including a metal material may reinforce a mass of the vibration generating apparatus 1200 which is disposed at or hung from the rear surface of the display panel 1100. Thus, the plate 1170 may decrease a resonance frequency of the vibration generating apparatus 1200 based on an increase in mass of the vibration generating apparatus 1200. Therefore, the plate 1170 may increase a sound characteristic and a sound pressure level characteristic of the low-pitched sound band generated based on a vibration of the vibration generating apparatus 1200 and may enhance the flatness of a sound pressure level characteristic. For example, the flatness of the sound pressure level characteristic may be a magnitude of a deviation between a highest sound pressure level and a lowest sound pressure level. For example, the plate 1170 may be a weight member, a mass member, or a sound planarization member, or the like, but embodiments of the present disclosure are not limited thereto.

FIG. 18 illustrates a vehicular apparatus according to an aspect of the present disclosure.

With reference to FIG. 18, a vehicular apparatus according to an aspect of the present disclosure may include one or more sound generating apparatuses 10 configured to output a sound at one or more of an exterior material 520 and an interior material 530. For example, one or more of the exterior material 520 and the interior material 530 may output a sound based on vibrations of one or more sound generating apparatuses 10. A portion illustrated by a dotted line in FIG. 18 indicates a portion where one or more sound generating apparatuses 10 may be disposed.

The one or more sound generating apparatuses 10 may be disposed at the exterior material 520, the interior material 530, or between the exterior material 520 and the interior material 530 to output a sound. For example, the one or more sound generating apparatuses 10 may be disposed at one or more of the exterior material 520, the interior material 530, and between the exterior material 520 and the interior material 530 to output a sound.

The interior material 530 may include one or more material (or substance) of metal, wood, rubber, plastic, glass, fiber, cloth, paper, a mirror, leather, and carbon, but embodiments of the present disclosure are not limited thereto. For example, the paper may be cone paper for speakers. For example, the cone paper may be pulp or foamed plastic, or the like, but embodiments of the present disclosure are not limited thereto.

The interior material 530 according to an aspect of the present disclosure may include at least one or more of a dashboard 530A, a pillar interior material (or a pillar trim) 530B, a roof interior material (or a headliner), a door interior material (or a door trim) 530D, a seat interior material, a handle interior material (or a steering cover) 530F, a floor interior material (or a floor carpet), and a rear package interior material (or a back seat shelf) 530J. The one or more sound generating apparatuses 10 may vibrate at least one or more of the dashboard 530A, the pillar interior material 530B, the roof interior material, the door interior material 530D, the seat interior material, the handle interior material 530F, the floor interior material, and the rear package interior material 530J. The one or more sound generating apparatuses 10 may be disposed between the exterior material 520 and at least one or more of the dashboard 530A, the pillar interior material 530B, the roof interior material, the door interior material 530D, the seat interior material, the handle interior material 530F, and the floor interior material. Accordingly, the one or more sound generating apparatuses 10 may output a sound or sounds of one or more channels.

For example, at least one or more of the one or more sound generating apparatuses 10 may be configured to be transparent or semitransparent. For example, when a window is totally transparent, at least one or more of the one or more sound generating apparatuses 10 may be configured to be transparent and may be disposed at a center region or a peripheral region of the window. When the window includes a semitransparent portion or an opaque portion, at least one or more of the one or more sound generating apparatuses 10 may be configured to be semitransparent or opaque and may be disposed at the semitransparent portion or the opaque portion of the window. For example, at least one or more of the one or more sound generating apparatuses 10 may be a transparent vibration generator, a transparent vibration generating apparatus, or a transparent sound generating apparatus and or the like, but embodiments of the present disclosure are not limited thereto.

With reference to FIG. 18, the one or more sound generating apparatuses 10 according to an aspect of the present disclosure may be disposed between a dash panel and the dashboard 530A and may be configured to indirectly or directly vibrate the dashboard 530A to output a sound. For example, the one or more sound generating apparatuses 10 may include the vibration apparatus 200 described above with reference to FIGS. 1 to 12B, and thus, repeated descriptions may be omitted. For example, the one or more sound generating apparatuses 10 may be a dashboard speaker or a first speaker, or the like, but embodiments of the present disclosure are not limited thereto.

According to an aspect of the present disclosure, at least one or more of the dash panel and the dashboard 530A may include a first region corresponding to a driver seat DS, a second region corresponding to a passenger seat FPS, and a third region (or a middle region) between the first region and the second region. At least one or more of the dash panel and the dashboard 530A may further include a fourth region which is inclined to face the passenger seat FPS. According to an aspect of the present disclosure, the one or more sound generating apparatuses 10 may be configured to vibrate at least one or more among the first to fourth regions of the dashboard 530A. For example, the one or more sound generating apparatuses 10 may be disposed at each of the first and second regions of the dashboard 530A, or may be disposed at each of the first to fourth regions of the dashboard 530A. For example, the one or more sound generating apparatuses 10 may be disposed at each of the first and second regions of the dashboard 530A, or may be disposed in at least one or more of the first to fourth regions of the dashboard 530A. For example, the one or more sound generating apparatuses 10 may be configured to output a sound of about 150 Hz to about 20 kHz. For example, the one or more sound generating apparatuses 10 configured to vibrate at least one or more among the first to fourth regions of the dashboard 530A may have a same sound output characteristic or different sound output characteristics. For example, the one or more sound generating apparatuses 10 configured to vibrate each of the first to fourth regions of the dashboard 530A may have a same sound output characteristic or different sound output characteristics.

The one or more sound generating apparatuses 10 according to an aspect of the present disclosure may be disposed between pillar panel and the pillar interior material 530B and may be configured to indirectly or directly vibrate the pillar interior material 530B to output a sound. For example, the one or more sound generating apparatuses 10 may include the vibration apparatus 200 described above with reference to FIGS. 1 to 12B, and thus, repeated descriptions may be omitted. The one or more sound generating apparatuses 10 may be a pillar speaker, a tweeter speaker, or a second speaker, or the like, but embodiments of the present disclosure are not limited thereto.

According to an aspect of the present disclosure, the pillar panel may include a first pillar (or an A pillar) disposed at both sides of a front glass window, a second pillar (or a B pillar) disposed at both sides of a center of a vehicle body, and a third pillar (or a C pillar) disposed at both sides of a rear portion of the vehicle body. The pillar interior material 530B may include a first pillar interior material 530B1 covering the first pillar, a second pillar interior material 530B2 covering the second pillar, and a third pillar interior material 530B3 covering the third pillar. According to an aspect of the present disclosure, the one or more sound generating apparatuses 10 may be disposed in at least one or more of a region between the first pillar and the first pillar interior material 530B1, a region between the second pillar and the second pillar interior material 530B2, and a region between the third pillar and the third pillar interior material 530B3, and thus, may vibrate at least one or more of the first to third pillar interior materials 530B1, 530B2, and 530B3. For example, the one or more sound generating apparatuses 10 may be configured to output a sound at about 2 kHz to about 20 kHz, but embodiments of the present disclosure are not limited thereto. For example, the one or more sound generating apparatuses 10 may be configured to output a sound at about 150 Hz to about 20 kHz. For example, the one or more sound generating apparatuses 10 configured to vibrate at least one or more of the first to third pillar interior materials 530B1, 530B2, and 530B3 may have a same sound output characteristic or different sound output characteristics.

The one or more sound generating apparatuses 10 according to an aspect of the present disclosure may be disposed between a roof panel and a roof interior material and may be configured to directly or indirectly vibrate the roof interior material 530C to output a sound. For example, the one or more sound generating apparatuses 10 may be configured to be transparent or semitransparent. For example, the one or more sound generating apparatuses 10 may include the vibration apparatus 200 described above with reference to FIGS. 1 to 12B, and thus, repeated descriptions may be omitted. For example, the one or more sound generating apparatuses 10 may be a roof speaker or a third speaker, and or the like, but embodiments of the present disclosure are not limited thereto.

According to an aspect of the present disclosure, at least one or more of the roof panel and the roof interior material covering the roof panel may include the first region corresponding to the driver seat DS, the second region corresponding to the passenger seat FPS, a third region corresponding to a region between the driver seat DS and the passenger seat FPS, a fourth region corresponding to a first rear seat RPS1 behind the driver seat DS, a fifth region corresponding to a second rear seat RPS2 behind the passenger seat FPS, a sixth region corresponding to a region between the first rear seat RPS1 and the second rear seat RPS2, and a seventh region between the third region and the sixth region. For example, the one or more sound generating apparatuses 10 may be configured to vibrate at least one or more among the first to seventh regions of the roof interior material. For example, the one or more sound generating apparatuses 10 may be configured to output a sound of about 150 Hz to about 20 kHz. For example, the one or more sound generating apparatuses 10 configured to vibrate at least one or more of the first to seventh regions of the roof interior material may have a same sound output characteristic or different sound output characteristics. For example, the one or more sound generating apparatuses 10 configured to vibrate each of the first to seventh regions of the roof interior material may have a same sound output characteristic or different sound output characteristics. For example, at least one or more of the one or more sound generating apparatuses 10 configured to vibrate at least one or more of the first to seventh regions of the roof interior material may be configured to output a sound of about 2 kHz to about 20 kHz, and the other sound generating apparatus 10 may be configured to output a sound at about 150 Hz to about 20 kHz. For example, at least one or more of the one or more sound generating apparatuses 10 configured to vibrate each of the first to seventh regions of the roof interior material may be configured to output a sound of about 2 kHz to about 20 kHz, and the other sound generating apparatus 10 may be configured to output a sound at about 150 Hz to about 20 kHz.

According to an aspect of the present disclosure, the one or more sound generating apparatuses 10 may be disposed between the door frame and the door interior material 530D and may be configured to indirectly or directly vibrate the door interior material 530D to output a sound. For example, the one or more sound generating apparatuses 10 may include the vibration apparatus 200 described above with reference to FIGS. 1 to 12B, and thus, repeated descriptions may be omitted. For example, the one or more sound generating apparatuses 10 may be a door speaker or a fourth speaker, or the like, but embodiments of the present disclosure are not limited thereto.

According to an aspect of the present disclosure, at least one or more of the door frame and the door interior material 530D may include an upper region, a middle region, and a lower region with respect to a height direction Z of the vehicular apparatus. For example, the one or more sound generating apparatuses 10 may be disposed in at least one or more of an upper region, a middle region, and a lower region between the door frame and the door interior material 530D, and thus, may vibrate at least one or more of an upper region, a middle region, and a lower region of the door interior material 530D.

According to an aspect of the present disclosure, the upper region of a door interior material 530D may include a curved portion having a curvature radius which is relatively small. The one or more sound generating apparatuses 10 for vibrating the upper region of the door interior material 530D may have the supporting portion 231b, 231c, 231b1, and 231b2 having flexibility of the vibration device 2311 illustrated in one or more of the vibration apparatus described above with reference to FIGS. 9 to 12B, and thus, may be bent in a shape (or a conformal shape) based on a shape (or a surface shape) of a curved portion of the upper region of the door interior material 530D.

According to an aspect of the present disclosure, the door frame may include a first door frame (or a left front door frame), a second door frame (or a right front door frame), a third door frame (or a left rear door frame), and a fourth door frame (or a right rear door frame). According to an aspect of the present disclosure, the door interior material 530D may include a first door interior material (or a left front door interior material) 530D1 covering the first door frame, a second door interior material (or a right front door interior material) 530D2 covering the second door frame, a third door interior material (or a left rear door interior material) 530D3 covering the third door frame, and a fourth door interior material (or a right rear door interior material) 530D4 covering the fourth door frame. For example, the one or more sound generating apparatuses 10 may be disposed in at least one or more among an upper region, a middle region, and a lower region between each of the first to fourth door frames and the first to fourth door interior materials 530D1 to 530D4 and may vibrate at least one or more among an upper region, a middle region, and a lower region of each of the first to fourth door interior materials 530D1 to 530D4.

According to an aspect of the present disclosure, the one or more sound generating apparatuses 10 configured to vibrate the upper region of each of the first to fourth door interior materials 530D1 to 530D4 may be configured to output a sound of about 2 kHz to about 20 kHz, or may be configured to output a sound of about 150 Hz to about 20 kHz. For example, the one or more sound generating apparatuses 10 configured to vibrate the upper regions of at least one or more of the first to fourth door interior materials 530D1 to 530D4 may be configured to output a sound of about 2 kHz to about 20 kHz, or may be configured to output a sound of about 150 Hz to about 20 kHz.

According to an aspect of the present disclosure, the one or more sound generating apparatuses 10 configured to vibrate the middle regions or/and the lower regions of at least one or more of the first to fourth door interior materials 530D1 to 530D4 may be configured to output a sound of about 150 Hz to about 20 kHz. The one or more sound generating apparatuses 10 configured to vibrate the middle region or/and the lower region of each of the first to fourth door interior materials 530D1 to 530D4 may be configured to output a sound of about 150 Hz to about 20 kHz. For example, the one or more sound generating apparatuses 10 configured to vibrate the middle regions or/and the lower regions of at least one or more of the first to fourth door interior materials 530D1 to 530D4 may be one or more of a woofer, a mid-woofer, and a sub-woofer. For example, the one or more sound generating apparatuses 10 configured to vibrate the middle region or/and the lower region of each of the first to fourth door interior materials 530D1 to 530D4 may be one or more of a woofer, a mid-woofer, and a sub-woofer.

Sounds, which are respectively output from the one or more sound generating apparatuses 10 disposed at the first door interior material 530D1 and the fourth sound generating apparatus 10 disposed at the second door interior material 530D2, may be combined and output. For example, sounds, which are output from at least one or more of the one or more sound generating apparatuses 10 disposed at the first door interior material 530D1 and the one or more sound generating apparatuses 10 disposed at the second door interior material 530D2, may be combined and output. Moreover, a sound output from the one or more sound generating apparatuses 10 disposed at the third door interior material 530D3 and a sound output from the one or more sound generating apparatuses 10 disposed at the fourth door interior material 530D4 may be combined and output.

According to an aspect of the present disclosure, an upper region of each of the first to fourth door interior materials 530D1 to 530D4 may include a first upper region adjacent to the dashboard 530A, a second upper region adjacent to the rear seats RPS1, RPS2, and RPS3, and a third upper region between the first upper region and the second upper region. For example, the one or more sound generating apparatuses 10 may be disposed at one or more of the first to third upper regions of each of the first to fourth door interior materials 530D1 to 530D4. For example, the one or more sound generating apparatuses 10 may be disposed at the first upper region of each of the first and second door interior materials 530D1 and 530D2 and may be disposed at one or more of the second and third upper regions of each of the first and second door interior materials 530D1 and 530D2. For example, the one or more sound generating apparatuses 10 may be disposed at one or more of the first to third upper regions of one or more among the first to fourth door interior materials 530D1 to 530D4. For example, the one or more sound generating apparatuses 10 configured to vibrate the first upper regions of one or more of the first and second door interior materials 530D1 and 530D2 may be configured to output a sound of about 2 kHz to about 20 kHz, and the one or more sound generating apparatuses 10 configured to vibrate one or more among the second and third upper regions of each of the first and second door interior materials 530D1 and 530D2 may be configured to output a sound of about 2 kHz to about 20 kHz, or may be configured to output a sound of about 150 Hz to about 20 kHz. For example, the one or more sound generating apparatuses 10 configured to vibrate one or more of the second and third upper regions of one or more among the first and second door interior materials 530D1 and 530D2 may be configured to output a sound of about 2 kHz to about 20 kHz, or may be configured to output a sound of about 150 Hz to about 20 kHz.

According to an aspect of the present disclosure, the one or more sound generating apparatuses 10 may be disposed between a seat frame and the seat interior material and may be configured to indirectly or directly vibrate the seat interior material to output a sound. For example, the one or more sound generating apparatuses 10 may include the vibration apparatus 200 described above with reference to FIGS. 1 to 12B, and thus, repeated descriptions may be omitted. For example, the one or more sound generating apparatuses 10 may be a sheet speaker, a headrest speaker, or a fifth speaker, or the like, but embodiments of the present disclosure are not limited thereto.

According to an aspect of the present disclosure, the seat frame may include a first seat frame (or a driver seat frame), a second seat frame (or a passenger seat frame), a third seat frame (or a first rear seat frame), a fourth seat frame (or a second rear seat frame), and a fifth seat frame (or a third rear seat frame). According to an aspect of the present disclosure, the seat interior material may include a first seat interior material surrounding the first seat frame, a second seat interior material surrounding the second seat frame, a third seat interior material surrounding the third seat frame, a fourth seat interior material surrounding the fourth seat frame, and a fifth seat interior material surrounding the fifth seat frame.

According to an aspect of the present disclosure, at least one or more of the first to fifth seat frames may include a seat bottom frame, a seat back frame, and a headrest frame. The seat interior material may include a seat bottom interior material surrounding the seat bottom frame, a seat back interior material surrounding the seat back frame, and a headrest interior material surrounding the headrest frame. At least one or more of the seat bottom interior material, the seat back interior material, and the headrest interior material may include a seat inner interior material and a seat outer interior material. The seat inner interior material may include a foam layer. The seat outer interior material may include a surface layer including a fiber or leather. The outer seat interior material may further include a base layer including a plastic material which supports the surface layer.

According to an aspect of the present disclosure, the one or more sound generating apparatuses 10 may be disposed in at least one or more of a region between the seat back frame and the seat back interior material and a region between the headrest frame and the headrest interior material, and thus, may vibrate at least one or more of the seat outer interior material of the seat back interior material and the seat outer interior material of the headrest interior material.

According to an aspect of the present disclosure, the one or more sound generating apparatuses 10 disposed in at least one or more of the driver seat DS and the passenger seat FPS may be disposed in at least one or more of the region between the seat back frame and the seat back interior material and the region between the headrest frame and the headrest interior material.

According to an aspect of the present disclosure, the one or more sound generating apparatuses 10 disposed in at least one or more of the first to third rear seats RPS1, RPS2, and RPS3 may be disposed a region between the headrest frame and the headrest interior material. For example, at least one or more of the first to third rear seats RPS1, RPS2, and RPS3 may include the one or more sound generating apparatuses 10 disposed between the headrest frame and the headrest interior material.

According to an aspect of the present disclosure, the one or more sound generating apparatuses 10 vibrating the seat back interior materials of at least one or more of the driver seat DS and the passenger seat FPS may be configured to output a sound of about 150 Hz to about 20 kHz.

According to an aspect of the present disclosure, the one or more sound generating apparatuses 10 vibrating the headrest interior materials of at least one or more of the driver seat DS, the passenger seat FPS, and the first to third rear seats RPS1, RPS2, and RPS3 may be configured to output a sound of about 2 kHz to about 20 kHz, or may be configured to output a sound of about 150 Hz to about 20 kHz.

With reference to FIG. 18, the one or more sound generating apparatuses 10 according to an aspect of the present disclosure may be disposed between a handle frame and the handle interior material 530F and may be configured to indirectly or directly vibrate the handle interior material 530F to output a sound. For example, the one or more sound generating apparatuses 10 may include the vibration apparatus 200 described above with reference to FIGS. 1 to 1B, and thus, repeated descriptions mat be omitted. For example, the one or more sound generating apparatuses 10 may be a handle speaker, a steering speaker, or a sixth speaker, or the like, but embodiments of the present disclosure are not limited thereto.

According to an aspect of the present disclosure, the one or more sound generating apparatuses 10 may be configured to indirectly or directly vibrate the handle interior material 530F to provide a driver with a sound. A sound output by the one or more sound generating apparatuses 10 at the handle interior material 530F may be a sound which is a same as or different from a sound output from each of the one or more sound generating devices 10 at a region between the dash panel and the dashboard 530A, the one or more sound generating devices 10 at a region between the filler panel and the filler interior material 530B, the one or more sound generating devices 10 at a region between the roof panel and the roof interior material, the one or more sound generating devices 10 at a region between the door frame and the door interior material 530D, and the one or more sound generating devices 10 at a region between the seat frame and the seat interior material. For example, the sound output by the one or more sound generating apparatuses 10 at the handle interior material 530F may be a sound which is a same as or different from a sound output from at least one or more of the one or more sound generating devices 10 at a region between the dash panel and the dashboard 530A, the one or more sound generating devices 10 at a region between the filler panel and the filler interior material 530B, the one or more sound generating devices 10 at a region between the roof panel and the roof interior material, the one or more sound generating devices 10 at a region between the door frame and the door interior material 530D, and the one or more sound generating devices 10 at a region between the seat frame and the seat interior material.

As an aspect of the present disclosure, the one or more sound generating apparatuses 10 at the handle interior material 530F may output a sound which is to be provided to only the driver. As another aspect of the present disclosure, the sound output by the one or more sound generating apparatuses 10 at the handle interior material 530F and the sound output from each of the one or more sound generating devices 10 at a region between the dash panel and the dashboard 530A, the one or more sound generating devices 10 at a region between the filler panel and the filler interior material 530B, the one or more sound generating devices 10 at a region between the roof panel and the roof interior, the one or more sound generating devices 10 at a region between the door frame and the door interior material 530D, and the one or more sound generating devices 10 at a region between the seat frame and the seat interior material may be combined and output. For example, the sound output by the one or more sound generating apparatuses 10 at the handle interior material 530F and the sound output from at least one or more of the one or more sound generating devices 10 at a region between the dash panel and the dashboard 530A, the one or more sound generating devices 10 at a region between the filler panel and the filler interior material 530B, the one or more sound generating devices 10 at a region between the roof panel and the roof interior material, the one or more sound generating devices 10 at a region between the door frame and the door interior material 530D, and the one or more sound generating devices 10 at a region between the seat frame and the seat interior material may be combined and output.

According to an aspect of the present disclosure, the one or more sound generating apparatuses 10 may be disposed between the floor panel and the floor interior material and may be configured to indirectly or directly vibrate the floor internal material to output a sound. The one or more sound generating apparatuses 10 may be disposed between the floor interior material and the floor panel disposed between the front seats DS and FPS and the third rear seat RPS3. For example, the one or more sound generating apparatuses 10 may include the vibration apparatus 200 described above with reference to FIGS. 1 to 12B, and thus, repeated descriptions may be omitted. For example, the one or more sound generating apparatuses 10 may be configured to output a sound of about 150 Hz to about 20 kHz. For example, the one or more sound generating apparatuses 10 may be a floor speaker, a bottom speaker, an under speaker, or a seventh speaker, or the like, but embodiments of the present disclosure are not limited thereto.

The vehicular apparatus according to an aspect of the present disclosure may further include one or more sound generating apparatuses 10 which is disposed in the interior material 530 exposed at an indoor space. For example, the vehicular apparatus according to an aspect of the present disclosure may include only the one or more sound generating apparatuses 10 which is disposed in the interior material 530 exposed at an indoor space instead of the one or more sound generating apparatuses 10 which is disposed in the interior material 530, or may include all of the one or more sound generating apparatuses 10 which is disposed in the interior material 530 exposed at an indoor space instead of the one or more sound generating apparatuses 10 which is disposed in the interior material 530. For example, the one or more sound generating apparatuses 10 which is disposed in the interior material 530 and/or the one or more sound generating apparatuses 10 which is disposed in the interior material 530 exposed at an indoor space may be disposed in the interior material 530 to output a sound. For example, the interior material 530 may output a sound based on vibrations of the one or more sound generating apparatuses (or vibration apparatuses).

According to an aspect of the present disclosure, the interior material 530 may further include a rear view mirror, an overhead console, a rear package interior material 530J, a glove box, and a sun visor, or the like.

The one or more sound generating apparatuses 10 according to an aspect of the present disclosure may be disposed in at least one or more of the rear view mirror, the overhead console, the rear package interior material 530J, the glove box, and the sun visor. For example, the one or more sound generating apparatuses 10 may output a sound and/or sounds of one or more channels.

The one or more sound generating apparatuses 10 may be disposed at the rear view mirror and may be configured to indirectly or directly vibrate the rear view mirror to output a sound. The one or more sound generating apparatuses 10 may be disposed between a mirror housing and the rear view mirror supported by the mirror housing. For example, the one or more sound generating apparatuses 10 may include the vibration apparatus 200 described above with reference to FIGS. 1 to 12B, and thus, repetitive description thereof may be omitted. For example, the one or more sound generating apparatuses 10 may be configured to output a sound of about 150 Hz to about 20 kHz. For example, the one or more sound generating apparatuses 10 may be a mirror speaker or an eighth speaker, or the like, but embodiments of the present disclosure are not limited thereto.

The one or more sound generating apparatuses 10 according to an aspect of the present disclosure may be disposed at the overhead console and may be configured to indirectly or directly vibrate a console cover of the overhead console to output a sound. According to an aspect of the present disclosure, the overhead console may include a console box buried (or embedded) into the roof panel, a lighting device disposed at the console box, and a console cover covering the lighting device and the console box.

The one or more sound generating apparatuses 10 may be disposed between the console box of the overhead console and the console cover and may vibrate the console cover. For example, the one or more sound generating apparatuses 10 may be disposed between the console box of the overhead console and the console cover and may directly vibrate the console cover. For example, the one or more sound generating apparatuses 10 may include the vibration apparatus 200 described above with reference to FIGS. 1 to 12B, and thus, repeated descriptions may be omitted. For example, the ninth sound generating apparatus 10 may be configured to output a sound of about 150 Hz to about 20 kHz. For example, the one or more sound generating apparatuses 10 may be a console speaker, a lighting speaker, or a ninth speaker, or the like, but embodiments of the present disclosure are not limited thereto.

The vehicular apparatus according to an aspect of the present disclosure may further include a center lighting box disposed at a center region of the roof interior material, a center lighting device disposed at the center lighting box, and a center lighting cover covering the center lighting device. In this case, the one or more sound generating apparatuses 10 may be further disposed between the center lighting box and the center lighting cover of the center lighting device and may additionally vibrate the center lighting cover.

With reference to FIG. 18, the one or more sound generating apparatuses 10 may be disposed at the rear package interior material 530J and may be configured to indirectly or directly vibrate the rear package interior material 530J to output a sound. The rear package interior material 530J may be disposed behind (or back portion) the first to third rear seats RPS1, RPS2, and RPS3. For example, a portion of the rear package interior material 530J may be disposed under a rear glass window.

The one or more sound generating apparatuses 10 may be disposed at a rear surface of the rear package interior material 530J and may vibrate the rear package interior material 530J. For example, the one or more sound generating apparatuses 10 may include the vibration apparatus 200 described above with reference to FIGS. 1 to 12B, and thus, repeated descriptions may be omitted. For example, the one or more sound generating apparatuses 10 may be a rear speaker or a tenth speaker, or the like, but embodiments of the present disclosure are not limited thereto.

According to an aspect of the present disclosure, the rear package interior material 530J may include a first region corresponding to a rear portion of the first rear seat RPS1, a second region corresponding to a rear portion of the second rear seat RPS2, and a third region corresponding to a rear portion of the third passenger seat RPS3. According to an aspect of the present disclosure, the one or more sound generating apparatuses 10 may be disposed to vibrate at least one or more of the first to third regions of the rear package interior material 530J. For example, the one or more sound generating apparatuses 10 may be disposed at each of the first and second regions of the rear package interior material 530J, or may be disposed at each of the first to third regions of the rear package interior material 530J. For example, the one or more sound generating apparatuses 10 may be disposed in at least one or more of the first and second regions of the rear package interior material 530J, or may be disposed in at least one or more of the first to third regions of the rear package interior material 530J. For example, the one or more sound generating apparatuses 10 may be configured to output a sound at about 150 Hz to about 20 kHz. For example, the one or more sound generating apparatuses 10 configured to vibrate each of the first to third regions of the rear package interior material 530J may have a same sound output characteristic or different sound output characteristics. For example, the one or more sound generating apparatuses 10 configured to vibrate at least one or more of the first to third regions of the rear package interior material 530J may have a same sound output characteristic or different sound output characteristics.

According to an aspect of the present disclosure, the one or more sound generating apparatuses 10 may be disposed at a glove box and may be configured to indirectly or directly vibrate the glove box to output a sound. The glove box may be disposed at a dashboard 530A corresponding to a front portion of the passenger seat FPS.

The one or more sound generating apparatuses 10 may be disposed at an inner surface of the glove box and may vibrate the glove box. For example, the one or more sound generating apparatuses 10 may include the vibration apparatus 200 described above with reference to FIGS. 1 to 14, and thus, repeated descriptions may be omitted. For example, the one or more sound generating apparatuses 10 may be configured to output a sound of about 150 Hz to about 20 kHz, or may be one or more of a woofer, a mid-woofer, and a sub-woofer. For example, the one or more sound generating apparatuses 10 may be a glove box speaker or an eleventh speaker, or the like, but embodiments of the present disclosure are not limited thereto.

According to an aspect of the present disclosure, the one or more sound generating apparatuses 10 may be disposed at the sun visor and may configured to indirectly or directly vibrate the sun visor to output a sound. The sun visor may include a first sun visor corresponding to the driver seat DS and a second sun visor corresponding to the passenger seat FPS.

The one or more sound generating apparatuses 10 may be disposed in at least one or more of the first sun visor and the second sun visor and may indirectly or directly vibrate at least one or more among the first sun visor and the second sun visor. For example, the one or more sound generating apparatuses 10 may include the vibration apparatus 200 described above with reference to FIGS. 1 to 12B, and thus, repeated descriptions may be omitted. For example, the one or more sound generating apparatuses 10 may be configured to output a sound of about 150 Hz to about 20 kHz. For example, the one or more sound generating apparatuses 10 may be a sun visor speaker or a twelfth speaker, or the like, but embodiments of the present disclosure are not limited thereto.

According to an aspect of the present disclosure, at least one or more of the first sun visor and the second sun visor may further include a sun visor mirror. For example, the one or more sound generating apparatuses 10 may be configured to indirectly or directly vibrate a sun visor mirror of at least one or more among the first sun visor and the second sun visor. The one or more sound generating apparatuses 10 vibrating the sun visor mirror may include the vibration apparatus 200 described above with reference to FIGS. 1 to 12B, and thus, repeated descriptions may be omitted.

With reference to FIG. 18, the vehicular apparatus according to an aspect of the present disclosure may further include one or more sound generating apparatuses 10 disposed at the glass window 540. For example, the one or more sound generating apparatuses 10 may be disposed in the glass window 540 to output a sound. For example, the glass window 540 may output a sound on based vibrations of one or more sound generating apparatuses (or vibration apparatuses). For example, the one or more sound generating apparatuses 10 may be a window speaker, a transparent sound generating apparatus, a transparent speaker, or an opaque speaker, or the like, but embodiments of the present disclosure are not limited thereto.

The one or more sound generating apparatuses 10 according to an aspect of the present disclosure may be configured to indirectly or directly vibrate the glass window 540. For example, the one or more sound generating apparatuses 10 may include the vibration apparatus 200 described above with reference to FIGS. 1 to 12B, may be configured to be transparent, semitransparent, or opaque.

According to an aspect of the present disclosure, the glass window 540 may include at least one or more of a front glass window, a side glass window, and a rear glass window 540C. For example, the one or more sound generating apparatuses 10 may be configured as a transparent vibration apparatus. For example, the transparent vibration apparatus may vibrate at least one or more of a front glass window, a side glass window, and a rear glass window 540C. According to an aspect of the present disclosure, the glass window 540 may further include a roof glass window. For example, the transparent vibration apparatus may vibrate at least one or more of a front glass window, a side glass window, a rear glass window 540C, and the roof glass window. For example, when the transparent vibration apparatus includes the roof glass window, a portion of a region of the roof frame and the roof interior material may be replaced with the roof glass window. For example, when the vehicular apparatus includes the roof glass window, the one or more sound generating apparatuses 10 may be configured to indirectly or directly vibrate a periphery portion of the roof interior material surrounding the roof glass window to output a sound.

According to an aspect of the present disclosure, the one or more sound generating apparatuses 10 may be disposed at the front glass window and may be configured to output a sound by vibrating itself or may be configured to indirectly or directly vibrate the front glass window to output a sound.

According to an aspect of the present disclosure, the front glass window may include a first region corresponding to the driver seat DS, a second region corresponding to the passenger seat FPS, and a third region (or a middle region) between the first region and the second region. For example, the one or more sound generating apparatuses 10 may be disposed in at least one or more of the first to third regions of the front glass window. For example, the one or more sound generating apparatuses 10 may be disposed at each of the first and second regions of the front glass window, or may be disposed at each of the first to third regions of the front glass window. For example, the one or more sound generating apparatuses 10 may be disposed in at least one or more of the first and second regions of the front glass window, or may be disposed in at least one or more of the first to third regions of the front glass window. For example, the one or more sound generating apparatuses 10 disposed at each of the first to third regions of the front glass window may have a same sound output characteristic or different sound output characteristics. For example, the one or more sound generating apparatuses 10 disposed in at least one or more of the first to third regions of the front glass window may have a same sound output characteristic or different sound output characteristics. For example, the one or more sound generating apparatuses 10 may be configured to output a sound of about 150 Hz to about 20 kHz. For example, the one or more sound generating apparatuses 10 may be a front window speaker or a thirteenth speaker, or the like, but embodiments of the present disclosure are not limited thereto.

With reference to FIG. 18, the one or more sound generating apparatuses 10 according to an aspect of the present disclosure may be disposed at the side glass window and may be configured to output a sound by vibrating itself or may be configured to indirectly or directly vibrate the side glass window to output a sound.

According to an aspect of the present disclosure, the side glass window may include a first side glass window (or a left front window), a second side glass window (or a right front window), a third side glass window (or a left rear window), and a fourth side glass window (or a right rear window).

According to an aspect of the present disclosure, the one or more sound generating apparatuses 10 may be disposed in at least one or more of the first to fourth side glass windows. For example, at least one or more among the first to fourth side glass windows may include one or more sound generating apparatuses 10.

According to an aspect of the present disclosure, the one or more sound generating apparatuses 10 may be disposed in at least one or more of the first to fourth side glass windows and may be configured to output a sound by vibrating itself or may be configured to indirectly or directly vibrate a corresponding side glass window to output the sound. For example, the one or more sound generating apparatuses 10 may be configured to output a sound of about 150 Hz to about 20 kHz. For example, the one or more sound generating apparatuses 10 disposed in at least one or more of the first to fourth side glass windows have the same sound output characteristic or different sound output characteristics. For example, the one or more sound generating apparatuses 10 may be configured to output a sound of about 150 Hz to about 20 kHz. For example, the one or more sound generating apparatuses 10 may be a side window speaker or a fourteenth speaker, or the like, but embodiments of the present disclosure are not limited thereto.

With reference to FIG. 18, the one or more sound generating apparatuses 10 according to an aspect of the present disclosure may be disposed at the rear glass window 540C and may be configured to output a sound by vibrating itself or may be configured to indirectly or directly vibrate the rear glass window 540C to output a sound.

According to an aspect of the present disclosure, the rear glass window 540C may include a first region corresponding to a rear portion of the first rear seat RPS1, a second region corresponding to a rear portion of the second rear seat RPS2, and a third region corresponding to a rear portion of the third rear seat RPS3. According to an aspect of the present disclosure, the one or more sound generating apparatuses 10 may be disposed at each of first to third regions of the rear glass window 540C. For example, the one or more sound generating apparatuses 10 may be disposed in at least one or more of the first to third regions of the rear glass window 540C. For example, the one or more sound generating apparatuses 10 may be disposed at each of the first and second regions of the rear glass window 540C, or may be disposed at each of the first to third regions of the rear glass window 540C. For example, the one or more sound generating apparatuses 10 may be disposed in at least one or more of the first and second regions of the rear glass window 540C, or may be disposed in at least one or more of the first to third regions of the rear glass window 540C. For example, the one or more sound generating apparatuses 10 may be configured to output a sound of about 150 Hz to about 20 kHz. For example, the one or more sound generating apparatuses 10 disposed at each of the first to third regions of the rear glass window 540C may have a same sound output characteristic or different sound output characteristics. For example, the one or more sound generating apparatuses 10 disposed in at least one or more of the first to third regions of the rear glass window 540C may have a same sound output characteristic or different sound output characteristics. For example, the one or more sound generating apparatuses 10 disposed in at least one or more of the first and second regions of the rear glass window 540C may be configured to output a sound of about 150 Hz to about 20 kHz, or may be any one or more of a woofer, a mid-woofer, and a sub-woofer. For example, the one or more sound generating apparatuses 10 may be a rear window speaker or a fifteenth speaker, or the like, but embodiments of the present disclosure are not limited thereto.

According to an aspect of the present disclosure, the one or more sound generating apparatuses 10 may be disposed at the roof glass window and may output a sound by vibrating itself or may be configured to indirectly or directly vibrate the roof glass window to output a sound.

The roof glass window according to an aspect of the present disclosure may be disposed over the front seats DS and FPS. For example, the one or more sound generating apparatuses 10 may be disposed at a middle region of the roof glass window. For example, the one or more sound generating apparatuses 10 may be configured to output a sound of about 150 Hz to about 20 kHz. For example, the one or more sound generating apparatuses 10 may be a roof window speaker or a sixteenth speaker, or the like, but embodiments of the present disclosure are not limited thereto.

The roof glass window according to another aspect of the present disclosure may be disposed over the front seats DS and FPS or may be disposed over the rear seats RPS1, RPS2, and RPS3. For example, the roof glass window may include a first region corresponding to the front seats DS and FPS and a second region corresponding to the rear seats RPS1, RPS2, and RPS3. Moreover, the roof glass window may include a third region between the first region and the second region. For example, the one or more sound generating apparatuses 10 may be disposed in at least one or more of the first and second regions of the roof glass window or may be disposed in at least one or more of the first to third regions of the roof glass window. For example, the one or more sound generating apparatuses 10 may be configured to output a sound of about 150 Hz to about 20 kHz. For example, the one or more sound generating apparatuses 10 disposed in at least one or more of the first to third regions of the roof glass window may have a same sound output characteristic or different sound output characteristics.

With reference to FIG. 18, the vehicular apparatus according to an aspect of the present disclosure may further include a woofer speaker WS which is disposed in at least one or more of a dashboard 530A, a door frame, and a rear package interior material 530J.

The woofer speaker WS according to an aspect of the present disclosure may include one or more of a woofer, a mid-woofer, and a sub-woofer. For example, the woofer speaker WS may be a speaker or the like which outputs a sound of about 60 Hz to about 150 Hz, but embodiments of the present disclosure are not limited thereto.

Therefore, the woofer speaker WS may output a sound of about 60 Hz to about 150 Hz, and thus, may enhance a low-pitched sound band characteristic of a sound which is output to an indoor space.

According to an aspect of the present disclosure, the woofer speaker WS may be disposed in at least one or more of first and second regions of the dashboard 530A. According to an aspect of the present disclosure, the woofer speaker WS may be disposed at each of first to fourth door frames of the door interior material 530D and may be exposed at a lower region of each of the first to fourth door interior materials 530D1 to 530D4 of the door interior material 530D. For example, the woofer speaker WS may be disposed in at least one or more of the first to fourth door frames of the door interior material 530D and may be exposed at the lower regions of at least one or more of the first to fourth door interior materials 530D1 to 530D4 of the door interior material 530D. According to an aspect of the present disclosure, the woofer speaker WS may be disposed in at least one or more of the first and second regions of the rear package interior material 530J. For example, the one or more sound generating apparatuses 10 disposed at the lower region of each of the first to fourth door interior materials 530D1 to 530D4 may be replaced by the woofer speaker WS. For example, the one or more sound generating apparatuses 10 disposed at the lower regions of at least one or more of the first to fourth door interior materials 530D1 to 530D4 may be replaced by the woofer speaker WS.

The vehicular apparatus according to an aspect of the present disclosure may further include a garnish member which covers a portion of the interior material 530 exposed at the indoor space and one or more sound generating apparatuses 10 disposed at the interior material 530. For example, the one or more sound generating apparatuses 10 may be disposed at a garnish member and the interior material 530 to output a sound. For example, at least one or more of the garnish member and the interior material 530 may output a sound based on vibrations of one or more sound generating apparatuses (or vibration apparatuses).

The garnish member may be configured to cover a portion of the door interior material 530D exposed at an indoor space, but embodiments of the present disclosure are not limited thereto. For example, the garnish member may be configured to cover a portion of one or more among the dashboard 530A, the filler interior material 530B, and the roof interior material, which are exposed at the indoor space.

The garnish member according to an aspect of the present disclosure may include a metal material or a nonmetal material (or a composite nonmetal material) having a material characteristic suitable for generating a sound based on a vibration. For example, a metal material of the garnish member may include any one or more materials of stainless steel, aluminum (Al), an Al alloy, a magnesium (Mg), a Mg alloy, and a magnesium-lithium (Mg—Li) alloy, but embodiments of the present disclosure are not limited thereto. The nonmetal material (or the composite nonmetal material) of the garnish member may include one or more of wood, plastic, glass, metal, cloth, fiber, rubber, paper, carbon, and leather, but embodiments of the present disclosure are not limited thereto. For example, the garnish member may include a metal material having a material characteristic suitable for generating a sound of a high-pitched sound band, but embodiments of the present disclosure are not limited thereto. For example, the high-pitched sound band may have a frequency of 1 kHz or more or 3 kHz or more, but embodiments of the present disclosure are not limited thereto.

The one or more sound generating apparatuses 10 may be disposed between the garnish member and the interior material 530. For example, the one or more sound generating apparatuses 10 may be a garnish speaker or a seventeenth speaker, or the like, but embodiments of the present disclosure are not limited thereto.

The one or more sound generating apparatuses 10 according to an aspect of the present disclosure may include one or more of the vibration apparatus 200 described above with reference to FIGS. 1 to 12B. The one or more sound generating apparatuses 10 may be disposed at a main interior material and a garnish member and may be connected or coupled to the garnish member.

The one or more sound generating apparatuses 10 according to an aspect of the present disclosure may be configured to indirectly or directly vibrate the garnish member to output a sound into the indoor space of the vehicular apparatus. For example, the one or more sound generating apparatuses 10 may be configured to output a sound of a high-pitched sound band, but embodiments of the present disclosure are not limited thereto.

With reference to FIG. 18, the vehicular apparatus according to an aspect of the present disclosure may further include one or more sound generating apparatuses 10 disposed at an inner surface of the exterior material 520. For example, the one or more sound generating apparatuses 10 may be disposed at the exterior material 520 to output a sound. For example, the exterior material 520 may output a sound based on vibrations of one or more sound generating apparatuses (or vibration apparatuses).

The exterior material 520 according to the aspect of the present disclosure may include at least one of a hood panel 520A, a front fender panel 520B, a door frame, a roof panel, a filler panel, a trunk panel 520C, a front bumper, a rear bumper, a spoiler, a headlight, a taillight, a fog light or a vehicle body bottom. The one or more sound generating apparatuses 10 may vibrate at least one of the hood panel 520A, the front fender panel 520B, the door frame, the roof panel, the filler panel, the trunk panel 520C, the front bumper, the rear bumper, the spoiler, the headlight, the taillight, the fog light or the vehicle body bottom at the outside or the inside.

The one or more sound generating apparatuses 10 may be disposed at one or more of the hood panel 520A, the front fender panel 520B, and the trunk panel 520C. Therefore, the one or more sound generating apparatuses 10 may output sounds of one or more channels.

The one or more sound generating apparatuses 10 according to the aspect of the present disclosure may be connected or coupled to the inner side of the hood panel 520A, and may be configured to output sound to an external space of the vehicular apparatus by indirectly or directly vibrating the hood panel 520A. For example, the one or more sound generating apparatuses 10 may be configured to be connected or coupled to one or more of a central portion and a periphery portion of the inner side of the hood panel 520A.

The one or more sound generating apparatuses 10 according to an aspect of the present disclosure may include one or more of the vibration apparatus 200 described above with reference to FIGS. 1 to 12B. The one or more sound generating apparatuses 10 may be connected or coupled to an inner surface of a hood panel 520A. For example, the one or more sound generating apparatuses 10 may be configured to output a sound of 150 Hz to 20 kHz. For example, the one or more sound generating apparatuses 10 may be a hood panel speaker or an eighteenth speaker, or the like, but embodiments of the present disclosure are not limited thereto.

The one or more sound generating apparatuses 10 according to an aspect of the present disclosure may be connected or coupled to an inner surface of the front fender panel 520B and may be configured to indirectly or directly vibrate the front fender panel 520B to output a sound to the outdoor space of the vehicular apparatus. For example, the one or more sound generating apparatuses 10 may be disposed to have a certain interval at the inner surface of the front fender panel 520B.

The one or more sound generating apparatuses 10 according to an aspect of the present disclosure may include one or more of the vibration apparatus 200 described above with reference to FIGS. 1 to 12B. The one or more sound generating apparatuses 10 may be connected or coupled to the inner surface of the front fender panel 520B. For example, the one or more sound generating apparatuses 10 may be configured to output a sound of about 150 Hz to about 20 kHz. For example, the one or more sound generating apparatuses 10 may be a fender panel speaker or a nineteenth speaker, or the like, but embodiments of the present disclosure are not limited thereto.

The one or more sound generating apparatuses 10 according to an aspect of the present disclosure may be connected or coupled to an inner surface of the trunk panel 520C and may be configured to indirectly or directly vibrate the trunk panel 520C to output a sound to the outdoor space of the vehicular apparatus. For example, the one or more sound generating apparatuses 10 may be configured to be connected or coupled to one or more among a center portion and a periphery portion of the trunk panel 520C.

The one or more sound generating apparatuses 10 according to an aspect of the present disclosure may include one or more of the vibration apparatus 200 described above with reference to FIGS. 1 to 12B. The one or more sound generating apparatuses 10 may be connected or coupled to the inner surface of the trunk panel 520C. For example, the one or more sound generating apparatuses 10 may be configured to output a sound of about 150 Hz to about 20 kHz. For example, the one or more sound generating apparatuses 10 may be a trunk panel speaker or a twentieth speaker, or the like, but embodiments of the present disclosure are not limited thereto.

With reference to FIG. 18, the vehicular apparatus according to an aspect of the present disclosure may further include an instrument panel apparatus 560, an infotainment apparatus 570, a center fascia apparatus, and a curvature variation device.

The instrument panel apparatus 560 according to an aspect of the present disclosure may be disposed at a first region of the dashboard 530A to face the driver seat DS. The instrument panel apparatus 560 may include a first display 561 which is disposed at the first region of the dashboard 530A to face the driver seat DS.

The first display 561 may include any one of the apparatuses described above with reference to FIGS. 13 to 17, and thus, repeated descriptions may be omitted. For example, the instrument panel apparatus 560 may output a sound, generated by a vibration of a vibration member (or a display panel) 100 based on a vibration of one or more vibration generating apparatuses 1200 included at the first display 561, toward the driver seat DS. For example, the vibration generating apparatuses 1200 disposed at the first display 561 of the instrument panel apparatus 560 may be configured to output a sound of about 150 Hz to about 20 kHz. For example, the first display 561 may be an organic light-emitting display panel, an inorganic light-emitting display panel, a quantum dot light-emitting display panel, or a liquid crystal display panel, or the like, but embodiments of the present disclosure are not limited thereto. For example, the vibration generating apparatuses 1200 may be disposed at a rear surface of the first display 561 and may output a sound according to a vibration of a display panel of the first display 561 based on a vibration of the vibration generating apparatuses 1200.

The infotainment apparatus 570 may be disposed at a third region of the dashboard 530A.

The infotainment apparatus 570 according to an aspect of the present disclosure may be fixed on the third region of the dashboard 530A in an upright state.

The infotainment apparatus 570 according to another aspect of the present disclosure may be installed to be raised and lowered at the third region of the dashboard 530A. For example, the infotainment apparatus 570 may be received or accommodated into the dashboard 530A based on the power turn-off of the vehicular apparatus or the manipulation of a vehicle passenger and may protrude to a region on the dashboard 530A based on the power turn-on of the vehicular apparatus or the manipulation of the vehicle passenger.

The infotainment apparatus 570 according to an aspect of the present disclosure may include a display (or a second display) 571 disposed at the third region of the dashboard 530A, and a display elevation device.

The second display 571 may include any one of the apparatuses described above with reference to FIGS. 13 to 17, and thus, repeated descriptions may be omitted. For example, the infotainment apparatus 570 may output a sound, generated by a vibration of a display panel based on a vibration of one or more vibration generating apparatuses 1200 included at the second display 571, toward the driver seat DS. For example, the one or more vibration generating apparatuses 1200 disposed at the second display 571 of the infotainment apparatus 570 may be configured to output a sound of about 150 Hz to about 20 kHz. For example, the second display 571 may be an organic light-emitting display panel, an inorganic light-emitting display panel, a quantum dot light-emitting display panel, or a liquid crystal display panel, or the like, but embodiments of the present disclosure are not limited thereto. For example, the vibration generating apparatuses 1200 may be disposed at a rear surface of the second display 571 and may output a sound according to a vibration of a display panel of the second display 571 based on a vibration of the vibration generator 1200.

The display elevation device may be disposed into the third region of the dashboard 530A and may support the second display 571 to be raised and lowered. For example, the display elevation device may raise the second display 571 based on the power turn-on of the vehicular apparatus or the manipulation of the vehicle passenger, thereby allowing the second display 571 to protrude to a region on the dashboard 530A. Also, the display elevation device may lower the second display 571 based on the power turn-off of the vehicular apparatus or the manipulation of the vehicle passenger, thereby allowing the second display 571 to be received or accommodated into the dashboard 530A.

The center fascia apparatus according to an aspect of the present disclosure may include a third display.

The third display may include any one of the apparatuses described above with reference to FIGS. 13 to 17, and thus, repeated descriptions may be omitted. For example, the center fascia apparatus may output a sound, generated by a vibration of a display panel based on a vibration of one or more vibration generating apparatuses 1200 included at the third display, toward a driver seat DS or a passenger seat FPS. For example, the third display may be an organic light-emitting display panel, an inorganic light-emitting display panel, a quantum dot light-emitting display panel, or a liquid crystal display panel, or the like, but embodiments of the present disclosure are not limited thereto. For example, the vibration generating apparatuses 1200 may be disposed at a rear surface of the third display and may output a sound according to a vibration of a display panel of the third display based on a vibration of the vibration generator 1200.

The curvature variation device according to an aspect of the present disclosure may include a fourth display.

The fourth display may include any one of the apparatuses described above with reference to FIGS. 9 to 11D and 14, and thus, repeated descriptions may be omitted. For example, the curvature variation device may output a sound, generated by a vibration of a display panel based on a vibration of one or more vibration generating apparatuses 1200 included at the fourth display, toward a driver seat DS or a passenger seat FPS. For example, the fourth display may be an organic light-emitting display panel, an inorganic light-emitting display panel, a quantum dot light-emitting display panel, or a liquid crystal display panel, or the like, but embodiments of the present disclosure are not limited thereto. For example, the vibration generating apparatuses 1200 may be disposed at a rear surface of the fourth display and may output a sound according to a vibration of a display panel of the fourth display based on a vibration of the vibration generator 1200.

The vehicular apparatus according to an aspect of the present disclosure may output a sound to one or more of an indoor space and an external space by at least one or more of the first sound generating apparatus disposed at the interior material 530, the second sound generating apparatus disposed at the interior material 530 exposed at the indoor space, the third sound generating apparatus disposed at the window 540, the fourth sound generating apparatus disposed at the garnish member, and the fifth sound generating apparatus disposed at the exterior material 520, and thus, may output a sound by one or more of the exterior material 520 and the interior material 530 as a sound vibration plate, thereby outputting a sound and/or a multi-channel surround stereo sound. Moreover, the vehicular apparatus according to an aspect of the present disclosure may output a sound by using, as a sound vibration plate, at least one or more display panels among at least one or more displays 561 and 571 of the instrument panel apparatus 560 and the infotainment apparatus 570, and may output a sound and/or a multi-channel surround stereo sound, which is more realistic, through each of the first to fourth sound generating apparatuses, the instrument panel apparatus 560, and the infotainment apparatus 570.

With reference to FIG. 1, the vibration apparatus may include an adhesive member 150. The adhesive member 150 may be between the vibration member 100 and the protection member. For example, the adhesive member 150 may be disposed at a region between the vibration member 100 and the protection member.

The adhesive member 150 may include a base member and an adhesive. For example, the adhesive member 150 may include first and second adhesives which are provided at a first surface of the base member and a second surface different from the first surface of the base member with the base member therebetween. An adhesive force of each of the first adhesive and the second adhesive may be changed based on a material of the vibration member 100.

Aspects of the present disclosure are directed to improving an adhesive force of the adhesive member 150 which in turn may enhance a sound pressure level. This will be further described below.

A factor which affects a sound pressure level of a vibration apparatus may include a material of a vibration member, a glass transition temperature of an adhesive, and a modulus of the adhesive, but embodiments of the present disclosure are not limited thereto. A glass transition temperature Tg may be a temperature which enables Brownian motion of a polymer chain to be activated. For example, when a temperature exceeds the glass transition temperature, a polymer such as stiff glass may have a feature such as soft rubber. When the glass transition temperature is low, the adhesive member 150 may be a ductile adhesive. When the vibration member 100 is a nonmetal material, the ductile adhesive may have a problem where a sound pressure level is reduced. When the vibration member 100 is a nonmetal material, the vibration member 100 may include an adhesive having a low modulus to secure an adhesive force of the adhesive member 150, but there may be a problem where a vibration transferred to the vibration member 100 is damped, and due to this, a sound pressure level is reduced.

The following Table 2 shows a result obtained by measuring a glass transition temperature of an adhesive, a modulus of the adhesive, and an adhesive force of the adhesive under a condition where the vibration member 100 includes a metal material. A sound pressure level has been measured based on the vibration apparatus of FIG. 1.

TABLE 2

| Modulus | Glass Transition | Sound Pressure | Adhesive Force |
|---|---|---|---|
| (Pa) | Temperature (° C.) | Level (dB) | (kgf/25 mm) |
| 6 × 10⁴ | −10 | 72.8 | 1.3 |
| 1 × 10⁵ | 0 | 74.7 | 1.0 |
| 2 × 10⁵ | 10 | 74.6 | 1.2 |
| 3 × 10⁵ | 5 | 75.6 | 1.9 |
| 3 × 10⁵ | 10 | 75.3 | 2.4 |
| 3 × 10⁵ | 20 | 75.1 | 0.7 |
| 5 × 10⁵ | 15 | 75.6 | 3.0 |
| 2 × 10⁶ | 30 | 74.5 | 1.3 |

In Table 2, a vibration member may be stainless steel, but embodiments of the present disclosure are not limited thereto. A glass transition temperature of an adhesive and a modulus of the adhesive may respectively be a glass transition temperature of the adhesive and a modulus of the adhesive in the adhesive member 150 of FIG. 1. The adhesive member is configured with a base member and an adhesive which is at each of a first surface and a second surface of the base member. As another example, the adhesive member may be configured with an adhesive without a base member, and an adhesive force difference caused by whether a base member is provided or not may not occur.

The adhesive force may represent an adhesive force between a vibration part and an adhesive which is an adhesive member. The adhesive force may be measured by a peel process, but embodiments of the present disclosure are not limited thereto. When peel is a force of when detached from a base material, peel may be a force per unit area. Also, 180° peel may be a method of pulling at a certain speed in a horizontal opposite direction. Furthermore, kgf/25 mm which is a unit of the adhesive force may be a numerical value which represents, as kgf (kirogram force), a force for peeling an adhesive having a width of 25 mm.

With reference to Table 2, when a modulus of the adhesive member (or the adhesive) is 6×10⁴ Pa, a sound pressure level has been measured to be 72.8 dB (decibel). When a modulus of the adhesive member (or the adhesive) is 1×10⁵ Pa, a sound pressure level has been measured to be 74.7 dB (decibel). Therefore, when a modulus of the adhesive member (or the adhesive) is 6×10⁴ Pa, it may be seen that a sound pressure level is lower than 1×10⁵ Pa. When a modulus of the adhesive member (or the adhesive) is 5×10⁵ Pa, a sound pressure level has been measured to be 75.6 dB (decibel). When a modulus of the adhesive member (or the adhesive) is 2×10⁶ Pa, a sound pressure level has been measured to be 74.5 dB (decibel). Therefore, when a modulus of the adhesive member (or the adhesive) is 2×10⁶ Pa, it may be seen that a sound pressure level is lower than 5×10⁵ Pa. For example, it may be seen that, when a modulus of the adhesive member (or the adhesive) is greater than or equal to 1×10⁵ Pa, a sound pressure level increases, and then, when a modulus of the adhesive member (or the adhesive) is greater than or equal to 2×10⁶ Pa, a sound pressure level decreases. According to an aspect of the present disclosure, when a modulus of the adhesive member (or the adhesive) is 1×10⁵ Pa or more and 5×10⁵ Pa or less, it may be seen that a sound pressure level increases. For example, when a modulus of the adhesive member (or the adhesive) is 3×10⁵ Pa or more and 5×10⁵ Pa or less, it may be seen that a sound pressure level increases.

When a glass transition temperature of the adhesive member (or the adhesive) is −10° C., a sound pressure level has been measured to be 72.8 dB. When a glass transition temperature of the adhesive member (or the adhesive) is 0° C., a sound pressure level has been measured to be 74.7 dB. When a glass transition temperature of the adhesive member (or the adhesive) is 5° C., a sound pressure level has been measured to be 75.6 dB. Therefore, when a glass transition temperature of the adhesive member (or the adhesive) is −10° C., it may be seen that a sound pressure level is lower than a glass transition temperature of 0° C. When a glass transition temperature of the adhesive member (or the adhesive) is 5° C., it may be seen that a sound pressure level is higher than a glass transition temperature of 0° C. When a glass transition temperature of the adhesive member (or the adhesive) is 15° C., a sound pressure level has been measured to be 75.6 dB. When a glass transition temperature of the adhesive member (or the adhesive) is 20° C., a sound pressure level has been measured to be 75.1 dB. When a glass transition temperature of the adhesive member (or the adhesive) is 30° C., a sound pressure level has been measured to be 74.5 dB. Therefore, when a glass transition temperature of the adhesive member (or the adhesive) is 15° C., it may be seen that a sound pressure level is higher than a glass transition temperature of 2° C. When a glass transition temperature of the adhesive member (or the adhesive) is 30° C., it may be seen that a sound pressure level is lower than a glass transition temperature of 20° C. For example, it may be seen that, when a glass transition temperature of the adhesive member (or the adhesive) is 0° C. or more, a sound pressure level increases, and then, when a glass transition temperature of the adhesive member (or the adhesive) is 30° C. or more, a sound pressure level decreases. According to an aspect of the present disclosure, when a glass transition temperature of the adhesive member (or the adhesive) is 5° C. or more and 20° C. or less, it may be seen that a sound pressure level increases. For example, when a glass transition temperature of the adhesive member (or the adhesive) is 5° C. or more and 15° C. or less, it may be seen that a sound pressure level increases.

With reference to Table 2, it may be seen that a variation of a sound pressure level based on an adhesive force is small.

According to an aspect of the present disclosure, it may be seen that, when a modulus of the adhesive member (or the adhesive) is 1×10⁵ Pa or more and 5×10⁵ Pa or less, a sound pressure level increases, and when a glass transition temperature of the adhesive member (or the adhesive) is 5° C. or more and 20° C. or less, a sound pressure level increases. For example, the adhesive member (or the adhesive) may include an acrylic or rubber-based material, but embodiments of the present disclosure are not limited thereto.

According to an aspect of the present disclosure, the adhesive layer of the connection member 1150 described above with reference to FIGS. 13 to 17 may include a material where a modulus is 1×10⁵ Pa or more and 5×10⁵ Pa or less and a glass transition temperature is 5° C. or more and 20° C. or less. For example, the adhesive member of the connection member 1150 may include an acrylic or rubber-based material, but embodiments of the present disclosure are not limited thereto. Accordingly, a vibration apparatus having an enhanced sound pressure level may be configured.

According to an aspect of the present disclosure, the adhesive layer of the connection member (or a panel connection member) described above with reference to FIGS. 16 to 17 may include a material where a modulus is 1×10⁵ Pa or more and 5×10⁵ Pa or less and a glass transition temperature is 5° C. or more and 20° C. or less. For example, the adhesive member of the connection member (or the panel connection member) may include an acrylic or rubber-based material, but embodiments of the present disclosure are not limited thereto. Accordingly, a vibration apparatus having an enhanced sound pressure level may be configured.

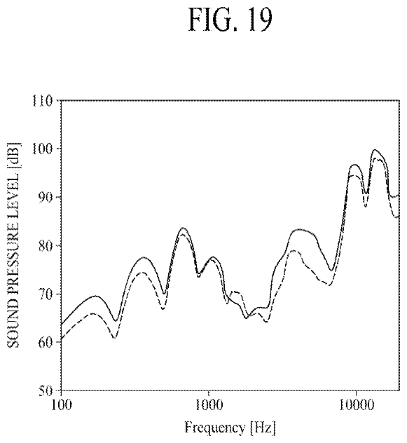

FIG. 19 illustrates a sound output characteristic according to an aspect of the present disclosure.

In FIG. 19, the abscissa axis represents a frequency in hertz (Hz), and the ordinate axis represents a sound pressure level (SPL) in decibels (dB).

A sound output characteristic of an apparatus may be measured by a sound analysis apparatus. The sound analysis apparatus may be configured to include a control personal computer (PC), a sound card that may transmit or receive sound signal to or from the control personal computer (PC), an amplifier that may amplify a sound signal generated from the sound card and transfer the amplified sound signal to a vibration apparatus, and a microphone that may collect sound generated from an apparatus based on driving of the vibration apparatus. The sound collected through the microphone may be input to the control PC through the sound card, and a control program may check the input sound to analyze the sound output characteristic of the apparatus.

The sound output characteristic has been measured in an anechoic chamber which is closed in all directions. When measuring, an applied frequency signal is applied as a sine sweep within a range of 150 Hz to 20 kHz, and ⅓ octave smoothing has been performed on a measurement result. A separation distance between the apparatus and the microphone is adjusted to be 30 cm. A measurement method may be not limited thereto.

A dotted line of FIG. 19 may represent that the vibration member 100 of FIG. 1 includes metal and the adhesive member 150 has a low modulus. A solid line may represent that the vibration member 100 of FIG. 1 includes metal and the adhesive member 150 has a low modulus. The metal may be stainless steel, but embodiments of the present disclosure are not limited thereto. A modulus of the adhesive member of the dotted line may be set to 5×10⁵ Pa, and a glass transition temperature may be set to 15° C. The adhesive member 150 of the solid line may include a material which has the modulus and the glass transition temperature described above with reference to Table 2.

With reference to FIG. 19, it may be seen that the dotted line represents 72.8 dB in a frequency of 1 kHz or less, and the solid line represents 75.6 dB. According to an aspect of the present disclosure, an adhesive member having a high modulus and/or a glass transition temperature of 5° C. or more and 20° C. or less may be provided, and thus, a vibration apparatus having an enhanced sound pressure level may be provided.

A vibration apparatus and an apparatus including the same according to an aspect of the present disclosure are described below.

A vibration apparatus according to one or more embodiments of the present disclosure may comprise a vibration part, a first electrode at a first surface of the vibration part, and a second electrode at a second surface different from the first surface of the vibration part. The vibration part may comprise a piezoelectric portion and a supporting portion connected to the piezoelectric portion. A height of the supporting portion may differ from a height of the piezoelectric portion.

According to one or more embodiments of the present disclosure, the height of the supporting portion may be higher than the height of the piezoelectric portion.

According to one or more embodiments of the present disclosure, a width of the supporting portion may differ from a width of the piezoelectric portion.

According to one or more embodiments of the present disclosure, the width of the supporting portion may be smaller than the width of the piezoelectric portion.

According to one or more embodiments of the present disclosure, a shape of the supporting portion may differ from a shape of the piezoelectric portion.

According to one or more embodiments of the present disclosure, the shape of the supporting portion may be one of a trapezoid shape, a convex shape, and a combination of a trapezoid shape and a convex shape.

According to one or more embodiments of the present disclosure, the supporting portion may be higher than one or more of a first surface of the piezoelectric portion and a second surface different from the first surface of the piezoelectric portion.

According to one or more embodiments of the present disclosure, a shape of the supporting portion may comprise a trapezoid shape.

According to one or more embodiments of the present disclosure, the first electrode may be at a first surface of each of the piezoelectric portion and the supporting portion and may be configured as one electrode.

According to one or more embodiments of the present disclosure, the first electrode may be at a first surface of each of the piezoelectric portion and the supporting portion and may be configured with an individual electrode.

According to one or more embodiments of the present disclosure, the second electrode may be at a second surface different from the first surface of each of the piezoelectric portion and the supporting portion and may be configured as one electrode.

According to one or more embodiments of the present disclosure, a signal having a frequency different from a frequency of the first electrode may be applied to the second electrode, or a signal having a phase that is different from a phase of the first electrode may be applied to the second electrode.

According to one or more embodiments of the present disclosure, the vibration apparatus may further comprise a first protection member at the first electrode, and a second protection member at the second electrode.

According to one or more embodiments of the present disclosure, the vibration apparatus may further comprise a first adhesive member between the first electrode and the first protection member, and a second adhesive member between the second electrode and the second protection member.

According to one or more embodiments of the present disclosure, the supporting portion may comprise a plurality of first supporting portions in parallel with the piezoelectric portion therebetween, and a plurality of second supporting portions in parallel with the piezoelectric portion therebetween.

According to one or more embodiments of the present disclosure, a respective shape of each of the plurality of first supporting portions may differ from a respective shape of each of the plurality of second supporting portions.

According to one or more embodiments of the present disclosure, each of the plurality of first supporting portions may comprise a slope surface protruding from the piezoelectric portion, and each of the plurality of second supporting portions may comprise a curved surface protruding from the piezoelectric portion.

According to one or more embodiments of the present disclosure, the vibration part may comprise a first region, a second region, and a third region between the first region and the second region. The plurality of first supporting portions may be at one or two of the first region, the second region, and the third region. The plurality of second supporting portions may be at one or two of the first region, the second region, the third region.

According to one or more embodiments of the present disclosure, the supporting portion may comprise an organic material having flexibility. The supporting portion may comprise a flexible organic material.

An apparatus according to one or more embodiments of the present disclosure may comprise a passive vibration member, and one or more vibration generating apparatuses configured to vibrate the passive vibration member. The one or more vibration generating apparatuses may comprise a vibration part, a first electrode at a first surface of the vibration part, and a second electrode at a second surface different from the first surface of the vibration part. The vibration part may comprise a piezoelectric portion and a supporting portion connected to the piezoelectric portion. A height of the supporting portion may differ from a height of the piezoelectric portion.

According to one or more embodiments of the present disclosure, the passive vibration member may comprise one or more of metal, wood, rubber, plastic, glass, fiber, cloth, paper, a mirror, carbon, and leather.

According to one or more embodiments of the present disclosure, the passive vibration member may comprise one or more of a display panel including a pixel configured to display an image, a light emitting diode lighting panel, an organic light emitting lighting panel, an inorganic light emitting lighting panel, a screen panel on which an image is to be projected from a display apparatus, a lighting panel, a signage panel, a vehicular interior material, a vehicular glass window, a vehicular exterior material, a vehicular seat interior material, a building ceiling material, a building interior material, a building glass window, an aircraft interior material, an aircraft glass window, and a mirror.

According to one or more embodiments of the present disclosure, the apparatus may further comprise a connection member between the passive vibration member and the vibration apparatus. A modulus of the connection member may be 1×10⁵ Pa or more and 5×10⁵ Pa or less. A modulus of the connection member may be between 1×10⁵ Pa and 5×10⁵ Pa.

An apparatus according to one or more embodiments of the present disclosure may comprise an exterior material, an interior material covering the exterior material, and one or more vibration generating apparatuses at least one or more of the exterior material, the interior material, and a region between the exterior material and the interior material. The one or more vibration generating apparatuses may comprise a vibration part, a first electrode at a first surface of the vibration part, and a second electrode at a second surface different from the first surface of the vibration part. The vibration part may comprise a piezoelectric portion and a supporting portion connected to the piezoelectric portion. A height of the supporting portion may differ from a height of the piezoelectric portion. One or more of the interior material and the exterior material may output sound based on a vibration of the one or more vibration generating apparatuses.

According to one or more embodiments of the present disclosure, the interior material may comprise one or more of metal, wood, rubber, plastic, glass, fiber, cloth, paper, carbon, a mirror, and leather.

According to one or more embodiments of the present disclosure, the interior material may comprise at least one or more of a dashboard, a pillar interior material, a roof interior material, a door interior material, a seat interior material, a handle interior material, a floor interior material, a rear view mirror, an overhead console, a glove box, a sun visor, and a rear package interior material. The one or more vibration generating apparatuses are configured to vibrate at least one or more of the dashboard, the pillar interior material, the roof interior material, the door interior material, the seat interior material, the handle interior material, the floor interior material, the rear view mirror, the overhead console, the glove box, the sun visor, and the rear package interior material.

The apparatus according to one or more embodiments of the present disclosure may further comprise a glass window, and a transparent vibration apparatus disposed at the glass window.

According to one or more embodiments of the present disclosure, the glass window may comprise at least one or more of a front glass window, a side glass window, a rear glass window, and a roof glass window. The transparent vibration apparatus may be configured to vibrate at least one or more of the front glass window, the side glass window, the rear glass window, and the roof glass window.

The apparatus according to one or more embodiments of the present disclosure may further comprise a connection member between the passive vibration member and the vibration apparatus, a modulus of the connection member may be 1×10⁵ Pa or more and 5×10⁵ Pa or less. A modulus of the connection member may be between 1×10⁵ Pa and 5×10⁵ Pa.

A vibration apparatus according to one or more embodiments of the present disclosure may be applied to or included in a vibration apparatus disposed at an apparatus. The apparatus according to an aspect of the present disclosure may be applied to or included in mobile apparatuses, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theater apparatuses, theater display apparatuses, TVs, wall paper display apparatuses, signage apparatuses, game machines, notebook computers, monitors, cameras, camcorders, and home appliances, or the like. And, a vibration apparatus according to one or more embodiments of the present disclosure may be applied to or included in an organic light-emitting lighting apparatus or an inorganic light-emitting lighting apparatus. When the vibration apparatus is applied to or included in the lighting apparatuses, the lighting apparatuses may act as lighting facility and a speaker. Moreover, when the vibration apparatus according to one or more embodiments of the present disclosure is applied to or included in the mobile apparatuses or the like, the vibration apparatus may be one or more of a speaker, a receiver, and a haptic device, but embodiments of the present disclosure are not limited thereto.

It will be apparent to those skilled in the art that various modifications and variations may be made in the present disclosure without departing from the scope of the disclosure. Thus, it is intended that the present disclosure covers the modifications and variations of this disclosure provided that within the scope of the appended claims and their equivalents.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

What is claimed is:

1. A vibration apparatus, comprising:
a vibration part;
a first electrode at a first surface of the vibration part; and
a second electrode at a second surface different from the first surface of the vibration part,
wherein the vibration part includes a piezoelectric portion and a supporting portion connected to the piezoelectric portion, and
wherein a height of the supporting portion differs from a height of the piezoelectric portion.

2. The vibration apparatus of claim 1, wherein the height of the supporting portion is higher than the height of the piezoelectric portion.

3. The vibration apparatus of claim 1, wherein a width of the supporting portion differs from a width of the piezoelectric portion.

4. The vibration apparatus of claim 1, wherein the width of the supporting portion is smaller than the width of the piezoelectric portion.

5. The vibration apparatus of claim 1, wherein a shape of the supporting portion differs from a shape of the piezoelectric portion.

6. The vibration apparatus of claim 5, wherein the shape of the supporting portion is one of a trapezoid shape, a convex shape, and a combination of a trapezoid shape and a convex shape.

7. The vibration apparatus of claim 1, wherein the supporting portion is higher than one or more of a first surface of the piezoelectric portion and a second surface different from the first surface of the piezoelectric portion.

8. The vibration apparatus of claim 7, wherein a shape of the supporting portion includes a trapezoid shape.

9. The vibration apparatus of claim 1, wherein the first electrode is at a first surface of each of the piezoelectric portion and the supporting portion and is configured as one electrode.

10. The vibration apparatus of claim 1, wherein the first electrode is at a first surface of each of the piezoelectric portion and the supporting portion and is configured with an individual electrode.

11. The vibration apparatus of claim 10, wherein the second electrode is at a second surface different from the first surface of each of the piezoelectric portion and the supporting portion and is configured as one electrode.

12. The vibration apparatus of claim 11, wherein a signal having a frequency different from a frequency of the first electrode is applied to the second electrode, or a signal having a phase that is different from a phase of the first electrode is applied to the second electrode.

13. The vibration apparatus of claim 1, further comprising:
a first protection member at the first electrode; and
a second protection member at the second electrode.

14. The vibration apparatus of claim 13, further comprising:
a first adhesive member between the first electrode and the first protection member; and
a second adhesive member between the second electrode and the second protection member.

15. The vibration apparatus of claim 1, wherein the supporting portion comprises:
a plurality of first supporting portions in parallel with the piezoelectric portion therebetween; and
a plurality of second supporting portions in parallel with the piezoelectric portion therebetween.

16. The vibration apparatus of claim 15, wherein a respective shape of each of the plurality of first supporting portions differs from a respective shape of each of the plurality of second supporting portions.

17. The vibration apparatus of claim 15, wherein each of the plurality of first supporting portions comprises a slope surface protruding from the piezoelectric portion, and
wherein each of the plurality of second supporting portions comprises a curved surface protruding from the piezoelectric portion.

18. The vibration apparatus of claim 15, wherein the vibration part comprises a first region, a second region, and a third region between the first region and the second region,
wherein the plurality of first supporting portions are at one or two of the first region, the second region, and the third region, and
wherein the plurality of second supporting portions are at one or two of the first region, the second region, and the third region.

19. The vibration apparatus of claim 1, wherein the supporting portion comprises a flexible organic material.

20. An apparatus, comprising:
a passive vibration member; and
one or more vibration generating components configured to vibrate the passive vibration member,
wherein the one or more vibration generating components include the vibration apparatus of claim 1.

21. The apparatus of claim 20, wherein the passive vibration member comprises one or more of metal, wood, rubber, plastic, glass, fiber, cloth, paper, a mirror, carbon, and leather.

22. The apparatus of claim 20, wherein the passive vibration member comprises one or more of a display panel including a pixel configured to display an image, a light emitting diode lighting panel, an organic light emitting lighting panel, an inorganic light emitting lighting panel, a screen panel on which an image is to be projected from a display apparatus, a lighting panel, a signage panel, a vehicular interior material, a vehicular glass window, a vehicular exterior material, a vehicular seat interior material, a building ceiling material, a building interior material, a building glass window, an aircraft interior material, an aircraft glass window, and a mirror.

23. The apparatus of claim 20, further comprising:
a connection member between the passive vibration member and the vibration apparatus,
wherein a modulus of the connection member is between 1×10⁵ Pa and 5×10⁵ Pa.

24. An apparatus, comprising:
an exterior material;
an interior material covering the exterior material; and
one or more vibration generating components on at least one or more of the exterior material, the interior material, and a region between the exterior material and the interior material,
wherein the one or more vibration generating components include the vibration apparatus of claim 1,
wherein one or more of the interior material and the exterior material are configured to output sound based on a vibration of the one or more vibration generating components.

25. The apparatus of claim 24, wherein the interior material comprises one or more of metal, wood, rubber, plastic, glass, fiber, cloth, paper, carbon, a mirror, and leather.

26. The apparatus of claim 24, wherein the interior material comprises at least one or more of a dashboard, a pillar interior material, a roof interior material, a door interior material, a seat interior material, a handle interior material, a floor interior material, a rear view mirror, an overhead console, a glove box, a sun visor, and a rear package interior material, and
wherein the one or more vibration generating components are configured to vibrate at least one or more of the dashboard, the pillar interior material, the roof interior material, the door interior material, the seat interior material, the handle interior material, the floor interior material, the rear view mirror, the overhead console, the glove box, the sun visor, and the rear package interior material.

27. The apparatus of claim 24, further comprising:
a glass window; and
a transparent vibration apparatus disposed at the glass window.

28. The apparatus of claim 27, wherein the glass window comprises at least one or more of a front glass window, a side glass window, a rear glass window, and a roof glass window, and
wherein the transparent vibration apparatus is configured to vibrate at least one or more of the front glass window, the side glass window, the rear glass window, and the roof glass window.

29. The apparatus of claim 24, further comprising a connection member between the passive vibration member and the vibration apparatus,
wherein a modulus of the connection member is between 1×10⁵ Pa and 5×10⁵ Pa.
